(19) United States
(12) Patent Application Publication
(10) Pub. No.: US 2018/0051373 A1
(43) Pub. Date: Feb. 22, 2018

(54) MECHANICALLY VIBRATED BASED REACTOR SYSTEMS AND METHODS

(71) Applicant: SITEC GMBH, Burghausen (DE)

(72) Inventors: Mark W. Dassel, Indianola, WA (US); Uwe Kerat, Starnberg (DE); David A. Bressler, Indianola, WA (US)

(21) Appl. No.: 15/539,603

(22) PCT Filed: Dec. 23, 2015
(86) PCT No.: PCT/US15/00241

§ 371 Date: Jun. 23, 2017

Related U.S. Application Data
(60) Provisional application No. 62/096,387, filed on Dec. 23, 2014.

(51) Int. Cl. C23C 16/442; C23C 16/24; C23C 16/52; C23C 16/44; C01B 33/029; C09D 1/00

(52) U.S. Cl. CPC C23C 16/442; C23C 16/24; C09D 1/00; C23C 16/4417; C01B 33/029; C23C 16/52

(57) ABSTRACT

Mechanically vibrated based reactor systems and processes allow for efficient, cost-effective production of silicon. Particulate may be provided to a heated tray or pan, which is oscillated or vibrated to provide a reaction surface. The particulate migrates downward in the tray or pan and the reactant product migrates upward in the tray or pan as the reactant product reaches a desired state. Exhausted gases may be recycled.

### TECHNICAL FIELD

This disclosure generally relates to mechanically fluidized bed reactors suitable for use in chemical vapor deposition.

### BACKGROUND

Silicon, specifically polysilicon, is a basic material from which a large variety of semiconductor products are made. Silicon forms the foundation of many integrated circuit technologies, as well as photovoltaic transducers. Of particular industry interest is high purity silicon.

Processes for producing polysilicon may be carried out in different types of reaction devices, including chemical vapor deposition reactors and fluidized bed reactors. Various aspects of the chemical vapor deposition (CVD) process, in particular the Siemens or “hot wire” process, have been described, for example in a variety of U.S. patents or published applications (see, e.g., U.S. Pat. Nos. 3,011,877; 3,099,534; 3,147,141; 4,150,168; 4,179,530; 4,311,545; and 5,118,485).

Silane and trichlorosilane are both used as feed materials for the production of polysilicon. Silane is more readily available as a high purity feedstock because it is easier to purify than trichlorosilane. Production of trichlorosilane introduces boron and phosphorus impurities, which are difficult to remove because they tend to have boiling points that are close to the boiling point of trichlorosilane itself. Although both silane and trichlorosilane are used as feedstock in Siemens-type chemical vapor deposition reactors, trichlorosilane is more commonly used in such reactors. Silane, on the other hand, is a more commonly used feedstock for production of polysilicon in fluidized bed reactors.

Silane has drawbacks when used as a feedstock for either chemical vapor deposition or fluidized bed reactors. Producing polysilicon from silane in a Siemens-type chemical vapor deposition reactor may require up to twice the electrical energy compared to producing polysilicon from trichlorosilane in such a reactor. Further, the capital costs are high because a Siemens-type chemical vapor deposition reactor yields only about half as much polysilicon from silane as from trichlorosilane. Thus, any advantages resulting from higher purity of silane are offset by higher capital and operating costs in producing polysilicon from silane in a Siemens-type chemical vapor deposition reactor. This has led to the common use of trichlorosilane as feed material for production of polysilicon in such reactors.

Silane as feedstock for production of polysilicon in a fluidized bed reactor has advantages regarding electrical energy usage compared to production in Siemens-type chemical vapor deposition reactors. However, there are disadvantages that offset the operating cost advantages. In using the fluidized bed reactor, the process itself may result in a lower quality polysilicon product even though the purity of the feedstock is high. For example, polysilicon produced in a fluidized bed reactor may also include metal impurities from the equipment used in providing the fluidized bed due to the typically abrasive conditions found within a fluidized bed. Further, polysilicon dust may be formed, which may interfere with operation by forming ultra-fine particulate material within the reactor and may also decrease the overall yield. Further, polysilicon produced in a fluidized bed reactor may contain residual hydrogen gas, which must be removed by subsequent processing. Thus, although high purity silane may be available, the use of high purity silane as a feedstock for the production of polysilicon in either type of reactor may be limited by the disadvantages noted.

Chemical vapor deposition reactors may be used to convert a first chemical species, present in vapor or gaseous form, to solid material. The deposition may and commonly does involve the conversion or decomposition of the first chemical species to one or more second chemical species, one of which second chemical species is a substantially non-volatile species.

Decomposition and deposition of the second chemical species on a substrate is induced by heating the substrate to a temperature at which the first chemical species decomposes on contact with the substrate to provide one or more of the aforementioned second chemical species, one of which second chemical species is a substantially non-volatile species. Solids so formed and deposited may be in the form of successive annular layers deposited on bulk forms, such as immobile rods, or deposited on mobile substrates, such as beads, grains, or other similar particulate matter chemically and structurally suitable for use as a substrate.

Beads are currently produced, or grown, in a fluidized bed reactor where an accumulation of dust, comprised of the desired product of the decomposition reaction, acting as seeds for additional growth, and pre-formed beads, also comprised of the desired product of the decomposition reaction, are suspended in a gas stream passing through the fluidized bed reactor. Due to the high gas volumes needed to fluidize the bed within a fluidized bed reactor, where the volume of the gas containing the first chemical species is insufficient to fluidize the bed within the reactor, a supplemental fluidizing gas such as an inert or marginally reactive gas is used to provide the gas volume necessary to fluidize the bed. As an inert or only marginally reactive gas, the ratio of the gas containing the first chemical species to the supplemental fluidizing gas may be used to control or otherwise limit the reaction rate within or the product matrix provided by the fluidized bed reactor.

The use of a supplemental fluidizing gas however can increase the size of process equipment and also increases separation and treatment costs to separate any unreacted or decomposed first chemical species present in the gas exiting the fluidized bed reactor from the supplemental gas used within the fluidized bed reactor.

In a conventional fluidized bed reactor, silane and one or more diluents such as hydrogen are used to fluidize the bed. Since the fluidized bed temperature is maintained at a level sufficient to thermally decompose silane, the gases used to fluidize the bed, due to intimate contact with the bed, are necessarily heated to the same bed temperature. For example, silane gas fed to a fluidized bed reactor operating at a temperature exceeding 500° C. is itself heated to its auto-decomposition temperature. This heating causes some of the silane gas to undergo spontaneous thermal decomposition which creates an extremely fine (e.g., having a particle diameter of 0.1 micron or less) silicon powder that is often referred to as “amorphous dust” or “poly-powder.” Silane forming poly-powder instead of the preferred polysilicon deposition on a substrate represents lost yield and unfavorably impacts production economics. The very fine poly-powder is electrostatic and is fairly difficult to separate from product particles for removal from the system. Additionally, if the poly-powder is not separated, off-specification polysilicon granules (i.e., polysilicon granules having a particle size less than the desired diameter of about 1.5 mm) are formed, further eroding yield and further unfavorably impacting production economics.

In some instances, a silane yield loss to poly-powder is on the order of about 10-15%, but may range from about 0.5% to about 20%. The average poly-powder particle size is typically about 0.1 micron, but can range from about 0.05 microns to about 10 microns. A 1% yield loss can therefore create around 1×10¹² to 1×10¹⁷ poly-powder particles per kilogram of polysilicon product particles. Unless these fine poly-powder particles are removed from the fluidized bed, the poly-powder will provide particles having less than 1/5,000,000^{th} of the industry desired diameter of 1.5 mm. Thus the ability to efficiently remove ultra-fine particles from the fluidized bed or from the fluid bed reactor off-gas is important. However, electrostatic forces often hinder filtering the ultra-fine poly-powder from a finished product or fluid bed reactor off-gas. Therefore, processes that minimize or ideally avoid the formation of the ultra-fine poly-powder are quite advantageous.

### BRIEF SUMMARY

A mechanically fluidized reactor system may be summarized as including a housing having a chamber therein; a pan received in the chamber of the housing, the pan having a major horizontal surface with a periphery and an upward extending peripheral wall that surrounds the periphery of the major horizontal surface that at least partially form a retainment volume to at least partially temporarily retain a plurality of particulates, at least the major horizontal surface comprising silicon; a transmission that, in operation, oscillates the pan along at least a first axis perpendicular to the major horizontal surface of the pan to mechanically fluidize the particulate in the retainment volume to produce a mechanically fluidized particulate bed in the retainment volume; and a heater that, in operation, raises the temperature of the mechanically fluidized particulate bed carried by the major horizontal surface of the pan above a thermal decomposition temperature of a first gaseous chemical species to thermally decompose the first gaseous chemical species within the mechanically fluidized particulate bed to a non-volatile second chemical species, at least a portion of which deposits on at least a portion of the plurality of particulates in the mechanically fluidized particulate bed to provide a plurality of coated particles. The major horizontal surface may be an integral, unitary, single piece insert selectively insertable into a bottom of the pan. The major horizontal surface may be an integral, unitary, single piece portion of a bottom of the pan, and not selectively removable therefrom. The major horizontal surface may be a portion of a bottom of the pan before a first use of the pan in the chamber of the housing. The major horizontal surface may include silicon having at least one of: a uniform thickness or a uniform density. The major horizontal surface may include substantially pure silicon. The peripheral wall may include silicon at least on an interior portion of the peripheral wall that is directly exposed to the plurality of particulates in the retainment volume. At least a portion of the peripheral wall of the pan may include silicon. The heater may be disposed proximate at least a portion of the major horizontal surface of the pan to heat the mechanically fluidized particulate bed in the retainment volume.

A mechanically fluidized reactor system may be summarized as including a housing having a chamber therein; a pan received in the chamber of the housing, the pan having a major horizontal surface with a periphery and an upward extending peripheral wall that surrounds the periphery of the major horizontal surface that at least partially defines a retainment volume that at least partially temporarily retains a plurality of particulates, the peripheral which terminates in a peripheral edge; a cover having an upper surface, a lower surface, and a peripheral edge, the cover disposed above the major horizontal surface of the pan, with the peripheral edge of the cover spaced inwardly of the peripheral wall of the pan with a peripheral gap between the peripheral edge of the cover and the peripheral wall of the pan that provides a fluidly communicative passage between the retainment volume of the pan and the chamber of the housing; a transmission that, in operation, oscillates the pan to mechanically fluidize the plurality of particulates in the retainment volume to produce a mechanically fluidized particulate bed in the retainment volume; a gas distribution header including at least one conduit having a fluid passage that extends therethrough, the fluid passage fluidly coupled to a proximal end of at least one injector having at least one outlet disposed at a distal end thereof, the passage which fluidly communicatively couples an external source of a first gaseous chemical species to the at least one outlet, the at least one outlet disposed in the retainment volume of the pan, the at least one injector penetrates and is sealingly coupled to the cover to provide a gas-tight seal therebetween, the at least one outlet, in operation, discharges the first gaseous chemical species at one or more locations in the mechanically fluidized particulate bed; and a heater thermally coupled to the pan that, in operation, raises a temperature of the mechanically fluidized particulate bed above a thermal decomposition temperature of the first gaseous chemical species to thermally decompose at least a portion of the first gaseous chemical species present in the mechanically fluidized particulate bed to at least a non-volatile second chemical species that deposits on at least a portion of the particulates in the mechanically fluidized particulate bed to provide a plurality of coated particles, and a third gaseous chemical species, the peripheral gap which provides an exit for the third gaseous chemical species into the chamber of the housing from the mechanically fluidized particulate bed. The cover may be disposed parallel to the major horizontal surface of the pan.

The mechanically fluidized reactor system may further include a flexible member that separates the chamber in the housing into an upper chamber and a lower chamber, the flexible member having a first continuous edge and a second continuous edge disposed laterally across the flexible member from the first continuous edge, the first continuous edge of the flexible member physically couples to the housing, to form a gas-tight seal therebetween, and the second continuous edge of the flexible member physically couples to the pan to form a gas-tight seal therebetween such that, in operation: the upper chamber includes at least a portion of the chamber inclusive of the retainment volume; the lower chamber includes at least a portion of the chamber exclusive of the retainment volume; and the flexible member forms a hermetic seal between the upper chamber and the lower chamber. The at least one outlet of the at least one injector may be positioned to discharge the first gaseous chemical species to at least one central location within the mechanically fluidized particulate bed. The at least one outlet of the at least one injector may include a plurality of outlets positioned to discharge the first gaseous chemical species in each of a plurality of locations within the mechanically fluidized particulate bed. The peripheral gap may have a width that, in operation, maintains a gas flow from the retainment volume through the peripheral gap to the upper chamber below a defined gas velocity, at or below which seed particles formed in-situ in the mechanically fluidized particulate bed are retained in the mechanically fluidized particulate bed. The peripheral gap may have a width that, in operation, maintains a gas flow through the peripheral gap below a defined gas velocity at which particles larger than 80 microns are retained in the mechanically fluidized particulate bed. The peripheral gap may have a width that, in operation, maintains a gas flow through the peripheral gap below a defined gas velocity at which particles larger than 10 microns are retained in the mechanically fluidized particulate bed. The peripheral gap may have a width of at least 0.0625 inches.

The mechanically fluidized reactor system may further include one or more thermal energy transfer devices thermally coupled to the transmission. The one or more thermal energy transfer devices thermally coupled to the transmission may include at least one of: a passive thermal energy transfer system or an active thermal energy transfer system. The cover may include an insulative layer. The insulative layer may include a gas impermeable member that encloses at least a portion of the insulative layer of the cover. The pan may include molybdenum.

The mechanically fluidized reactor system may further include one or more thermal energy transfer systems thermally coupled to at least a portion of the upper chamber of the housing. The one or one or more thermal energy transfer systems thermally coupled to at least a portion of the upper chamber of the housing may include at least one of: a passive thermal energy transfer system or an active thermal energy transfer system.

The mechanically fluidized reactor system may further include one or more thermal energy transfer systems thermally coupled to at least a portion of the lower chamber of the housing. The one or more thermal energy transfer devices thermally coupled to at least a portion of the lower chamber of the housing may include at least one of: a passive thermal energy transfer system or an active thermal energy transfer system.

The mechanically fluidized reactor system may further include an insulative layer disposed in contact with at least a portion of at least one of: the peripheral wall of the pan or the flexible member, so that the at least one of the peripheral wall of thermal member is thermally isolated from the lower chamber.

The insulative layer may further include a gas impermeable layer physically isolating at least a portion of the insulative layer from at least one of: the upper chamber or the lower chamber.

The mechanically fluidized reactor system may further include an insulative layer disposed about the heater such that the heater is thermally isolated from the lower chamber.

The insulative layer may further include a gas impermeable layer physically isolating at least a portion of the insulative layer disposed about the heater from at least one of the upper chamber or the lower chamber. The upper chamber may define a first volume; wherein a volumetric displacement caused by the oscillation of the pan defines a second volume; and wherein a ratio of the defined first volume to the defined second volume is greater than about 5:1. The ratio of the defined first volume to the defined second volume may be greater than about 100:1.

The mechanically fluidized reactor system may further include a controller that, in operation, executes a machine-executable instruction set that causes the controller to: maintain a first gas pressure level in the upper chamber and a second gas pressure level in the lower chamber, wherein the first gas pressure level is different from the second gas pressure level.

The mechanically fluidized reactor system may further include a gas detector fluidly coupled to a chamber maintained at the lower of the first gas pressure or the second gas pressure, the gas detector indicative of gas leakage from the higher pressure chamber to the lower pressure chamber.

The controller, in operation, may execute a machine-executable instruction set that further causes the controller to: adjust at least one process condition to provide the plurality of coated particles meeting at least one defined criterion including at least one of: at least one chemical composition criterion or at least one physical property criterion, the at least one process condition including at least one of: an oscillatory frequency of the pan, an oscillatory displacement of the pan, a temperature of the mechanically fluidized particulate bed, a gas pressure in the upper chamber, a feed rate of the first gaseous chemical species to the mechanically fluidized particulate bed, a mole fraction of the first gaseous chemical species in the upper chamber, a removal rate of the third gaseous chemical species from the upper chamber, a volume of the mechanically fluidized particulate bed, or a depth of the mechanically fluidized particulate bed.

The controller, in operation, may execute a machine-executable instruction set that further causes the controller to: adjust at least one process condition to provide a defined conversion of the first gaseous chemical species to the second chemical species, the at least one process condition including at least one of: an oscillatory frequency of the pan, an oscillatory displacement of the pan, a temperature of the mechanically fluidized particulate bed, a gas pressure in the upper chamber, a feed rate of the first gaseous chemical species to the mechanically fluidized particulate bed, a mole fraction of the first gaseous chemical species in the upper chamber, a removal rate of the third gaseous chemical species from the upper chamber, a volume of the mechanically fluidized particulate bed, or a depth of the mechanically fluidized particulate bed.

The controller, in operation, may execute a machine-executable instruction set that further causes the controller to: adjust at least one process condition to maintain a gas composition in the upper chamber within a defined range, the at least one process condition including at least one of: an oscillatory frequency of the pan, an oscillatory displacement of the pan, a temperature of the mechanically fluidized particulate bed, a gas pressure in the upper chamber, a feed rate of the first gaseous chemical species to the mechanically fluidized particulate bed, a removal rate of the third gaseous chemical species from the upper chamber, a volume of the mechanically fluidized particulate bed or a depth of the mechanically fluidized bed.

The machine-executable instruction set that may cause the controller to adjust at least one process condition to provide the plurality of coated particles having a minimum first dimension, may further cause the controller to: adjust the at least one process condition to provide the plurality of coated particles that includes coated particles having diameters of 600 microns or greater.

The machine-executable instruction set that may cause the controller to adjust at least one process condition to provide the plurality of coated particles having a minimum first dimension, may further cause the controller to: adjust the at least one process condition to provide the plurality of coated particles that includes coated particles having diameters of 300 microns or greater.

The machine-executable instruction set that may cause the controller to adjust at least one process condition to provide the plurality of coated particles having a minimum first dimension, may further cause the controller to: adjust the at least one process condition to provide the plurality of coated particles that includes coated particles having diameters of 10 microns or greater.

The machine-executable instruction set that may cause the controller to adjust at least one process condition to provide the plurality of coated particles having a minimum first dimension, may further cause the controller to: adjust the at least one process condition to provide the plurality of coated particles in which the particulate diameters form a Gaussian distribution.

The machine-executable instruction set that may cause the controller to adjust at least one process condition to provide the plurality of coated particles having a minimum first dimension, may further cause the controller to: adjust the at least one process condition to provide the plurality of coated particles in which the particulate diameters form a non-Gaussian distribution. The upper chamber of the housing may define a first volume, the mechanically fluidized particulate bed may define a third volume, and a ratio of the first volume to the third volume may be greater than about 0.5:1. The cover may be physically affixed to the housing such that, in operation, the cover does not oscillate with the pan. A volumetric displacement of the fluidized bed may be caused by the oscillation of the pan and a peripheral gap volume may be greater than the volumetric displacement of the fluidized bed. The cover may be physically affixed to the pan such that, in operation, the cover oscillates with the pan. The transmission, in operation, may oscillate the pan with at least one of an oscillatory displacement or an oscillatory frequency along at least an axis perpendicular to the bottom of the pan such that the mechanically fluidized particulate bed contacts (e.g., lightly, firmly) the lower surface of the cover. The transmission, in operation, may oscillate the pan in a direction defined by a first component having a displacement of a first magnitude along a first axis normal to the bottom of the pan and a second component having a displacement of a second magnitude along a second axis orthogonal to the first axis such that the mechanically fluidized particulate bed contacts (e.g., lightly, firmly) the lower surface of the cover.

The mechanically fluidized reactor system may further include a product removal tube penetrating and sealingly coupled to the major horizontal surface; wherein each of the number of injectors fluidly coupled to the first gaseous chemical species distribution header penetrates the cover in a respective location disposed radially about the product removal tube. The cover may be apportioned into a raised portion and a non-raised portion, the raised portion including a portion of the cover directly above and extending radially outward from the product removal tube a fixed radius such that the distance between a lower surface of the raised portion of the cover and the major horizontal surface is greater than the distance between the lower surface of the non-raised portion of the cover and the major horizontal surface. At least a portion of the non-raised portion of the cover may include an insulative layer.

A mechanically fluidized reactor system may be summarized as including a housing having a chamber therein; a pan received in the chamber of the housing, the pan having a major horizontal surface with a periphery and an upward extending peripheral wall that surrounds the periphery of the major horizontal surface that at least partially form a retainment volume to at least partially temporarily retain a plurality of particulates, the peripheral wall terminates in a peripheral edge; a transmission that, in operation, oscillates the pan to mechanically fluidize a plurality of particulates in the retainment volume to produce a mechanically fluidized particulate bed therein; a heater thermally coupled to the pan that, in operation, causes a temperature of the mechanically fluidized particulate bed to increase above a thermal decomposition temperature of a first gaseous chemical species, resulting in the thermal decomposition of at least a portion of the first gaseous chemical species present in the mechanically fluidized particulate bed to at least a non-volatile second chemical species that deposits on at least a portion of the plurality of particulates in the mechanically fluidized particulate bed to form a plurality of coated particles; and a thermally insulated feed tube that includes a thermally insulated fluid passage, the fluid passage coupled to a number of injectors, each of the number of injectors having at least one outlet positioned in the retainment volume below the peripheral edge of the perimeter wall of the pan, the thermally insulated fluid passage providing a fluidly communicative path between a source of the first gaseous chemical species and each of the number of injectors disposed at respective locations in the mechanically fluidized particulate bed. Each of the number of injectors may be at least partially thermally insulated and the thermally insulated fluid passage fluidly may communicatively couple the source of the first gaseous chemical species and the outlet positioned in the retainment volume, below the peripheral edge of the perimeter wall of the pan. The thermally insulated feed tube may include an outer tube member that forms an outer tube passage and an open-ended inner tube member that forms the insulated fluid passage, the open-ended inner tube member received in the outer tube passage of the outer tube member; and, wherein the outer tube member and the open-ended inner tube member contact each other at a location proximate the outlet of each of the number of injectors to form a closed-ended void along at least a portion of the length of the thermally insulated feed tube and the number of injectors, the closed-ended void including an insulative vacuum. The thermally insulated feed tube may include an outer tube member that forms an outer tube passage and an open-ended inner tube member that forms the insulated fluid passage, the open-ended inner tube member received in the outer tube passage of the outer tube member; and, wherein the outer tube member and the open-ended inner tube member contact each other at a location proximate outlet of each one of the number of injectors to form a closed-ended void that extends along at least a portion of the length of the thermally insulated feed tube and the number of injectors, the closed-ended void including one or more thermally insulating materials or substances.

The mechanically fluidized reactor system may further include a cooling media supply system; wherein the thermally insulated feed tube comprises an outer tube member that forms an outer tube passage and an open-ended inner tube member that forms the insulated fluid passage, the open-ended inner tube member received in the outer tube passage of the outer tube member; wherein the outer tube member and the open-ended inner tube member are not in contact with each other along the thermally insulated feed tube and the number of injectors to form an open-ended void that extends along at least a portion of the length of the thermally insulated feed tube and the number of injectors; and wherein the cooling media supply system fluidly couples to the open-ended void to provide a flow path for passage of one or more insulative, non-reactive, gases that maintain the temperature of the first gaseous chemical species within the inner tube member below the thermal decomposition temperature of the first gaseous chemical species.

The mechanically fluidized reactor system may further include a recirculated, closed-loop, cooling media supply system; wherein the thermally insulated feed tube comprises an outer tube member that forms an outer tube passage and an open-ended inner tube member that forms the insulated fluid passage, the open-ended inner tube member received in the outer tube passage of the outer tube member; wherein the outer tube member and the open-ended inner tube member contact each other at a location proximate the outlet of one or more of the number of injectors to form a closed-ended void that extends along at least a portion of the length of the thermally insulated feed tube and the number of injectors; and wherein the closed-ended void fluidly couples to the cooling media supply system to provide a closed loop cooling system about the inner tube member that maintains the temperature of the first gaseous chemical species within the inner tube member below the thermal decomposition temperature of the first gaseous chemical species.

The cooling media supply system may further include a second outer tube passage formed between the outer tube member and a second outer tube member the intervening space between the outer tube member and the second outer tube member forming the second outer tube passage; the outer tube passage and the second outer tube passage contact each other to form a close-ended void containing at least one of: an insulative vacuum or a thermally insulating material.

The thermally insulated feed tube may further include one or more features positioned proximate the outlet, the one or more features that cause at least a portion of the cooling fluid that exits the open-ended void to pass across the outlet of the inner tube. The one or more features may include at least one of: an extension of the outer tube member on each of the number of injectors so that the outer tube member extends a distance beyond the open-end of the inner tube member or a physical member disposed in the flow path of the cooling fluid that exits the open-ended void.

A mechanically fluidized reactor system may be summarized as including a housing having a chamber therein; a pan received in the chamber of the housing, the pan having a major horizontal surface with a periphery and an upward extending peripheral wall which terminates in a peripheral edge, the peripheral wall surrounding the periphery of the major horizontal surface to at least partially form a retainment volume that at least partially temporarily retains a plurality of particulates; a cover having an upper surface, a lower surface, and a peripheral edge, the cover disposed above the major horizontal surface of the pan; a transmission that, in operation, oscillates the pan to mechanically fluidize the plurality of particulates in the retainment volume to produce a mechanically fluidized particulate bed in the retainment volume; a heater thermally coupled to the pan that, in operation, causes a temperature of the mechanically fluidized particulate bed to increase above a thermal decomposition temperature of the first gaseous chemical species, causing the thermal decomposition of at least a portion of the first gaseous chemical species present in the mechanically fluidized particulate bed to at least a non-volatile second chemical species that deposits on at least a portion of the plurality of particulates in the mechanically fluidized particulate bed to provide a plurality of coated particles; a coated particle overflow conduit to remove at least a portion of the plurality of coated particulates from the mechanically fluidized bed, the coated particle overflow conduit having an inlet and a passage extending therethrough from the inlet to a distal portion of the coated particle overflow conduit, the coated particle overflow conduit projects a height above the major horizontal surface of the pan with the inlet positioned in the retainment volume of the pan to remove at least a portion of the plurality of coated particles from the retainment volume. The coated particle overflow conduit may include silicon having at least one of: a uniform thickness or a uniform density. The coated particle overflow conduit may include a metallic tubular member that includes a continuous layer of at least one of: graphite, quartz, silicon, silicon carbide, or silicon nitride disposed on at least a portion of an exterior portion of the coated particle overflow conduit exposed to the mechanically fluidized particulate bed. The inlet of the coated particle overflow conduit may be positioned a distance above the major horizontal surface of the pan and the distance may be variable. The coated particle overflow conduit may include a metallic tubular member that includes a continuous layer of at least one of: graphite, quartz, silicon, silicon carbide, or silicon nitride disposed on at least a portion of an interior portion of the coated particle overflow conduit exposed to the coated particles removed from the mechanically fluidized particulate bed. At least a portion of the lower surface of the cover may include silicon having at least one of: a uniform thickness or a uniform density. At least a portion of the lower surface of the cover may include a continuous layer of at least one of: metal silicide, graphite, quartz, silicon, silicon carbide, or silicon nitride disposed on at least a portion of the lower surface of the cover exposed to the mechanically fluidized particulate bed.

The mechanically fluidized reactor system may further include a gas-tight seal between the coated particle overflow conduit and the pan. The height of the open-ended coated particle overflow tube above the major horizontal surface may be selected such that, in operation, the plurality of particulates forming the mechanically fluidized particulate bed contact (e.g., lightly, firmly) the lower surface of the cover.

The mechanically fluidized reactor system may further include a particle receiver that, in operation, receives at least a portion of the plurality of coated particles removed from the mechanically fluidized particulate bed; and a product withdrawal tube having an inlet and a passage extending therethrough from the inlet to a distal portion of the product withdrawal tube, the product withdrawal tube fluidly communicably coupled to the distal end of the coated particle overflow conduit, the product withdrawal tube fluidly coupling the passage of the coated particle overflow conduit to the particle receiver. The coated particle overflow conduit and the product withdrawal tube may include a single tube, the single tube having a gas-tight seal to the pan. A peripheral gap may exist between at least a portion of the peripheral edge of the cover and the perimeter wall of the pan, the peripheral gap providing a passage fluidly coupling the retainment volume of the pan and the chamber of the housing. The cover may be apportioned into a raised portion and a non-raised portion, the raised portion including a portion of the cover directly above and extending radially outward from the product removal tube a fixed radius such that the distance between a lower surface of the raised portion of the cover and the major horizontal surface is greater than the distance between the lower surface of the non-raised portion of the cover and the major horizontal surface. At least a portion of the cover may include an insulative layer.

The mechanically fluidized reactor system may further include a thermal energy transfer system thermally coupled to at least the raised portion of the cover, the thermal energy transfer system to, in operation, maintain a temperature of the raised portion of the cover below the thermal decomposition temperature of the first gaseous chemical species:

The mechanically fluidized reactor system may further include a purge gas supply system fluidly coupled to the particle receiver to pass a quantity of non-reactive purge gas through the particle receiver and through the coated particle overflow conduit to the mechanically fluidized particulate bed. The peripheral edge of the cover may be disposed proximate the pan and further the cover may include at least one central aperture; the central aperture disposed at a distance about the coated particle overflow conduit; the central aperture providing a passage fluidly coupling the retainment volume of the pan and the chamber of the housing. The coated particle overflow conduit may be positioned at a location centered in the pan.

The mechanically fluidized reactor system may further include a number of baffles arranged concentrically about the coated particle overflow conduit, and spaced outwardly from the coated particle overflow conduit; wherein each of the number of baffles either: physically couples to the lower surface of the cover, extends downward and does not contact the major horizontal surface of the pan; or, physically couples to the major horizontal surface of the pan, extends upward, and does not contact the lower surface of the cover. The number of baffles may include a plurality of baffles arranged concentrically with respect to one another and to the coated particle overflow conduit, successive ones of the baffles alternatingly extend upward from the major horizontal surface of the pan and downward from the lower surface of the cover to create a serpentine flow path between the coated particulate removal tube and the peripheral wall of the pan. The plurality of baffles may include: a first group of baffles physically coupled to and projecting downwardly from the lower surface of the cover such that in operation, the respective baffle included in the first group of baffles extends at least partially into the mechanically fluidized particulate bed and does not contact the major horizontal surface of the pan; and a second group of baffles, each of the second group of baffles interposed between two of the baffles included in the first group of baffles, each of the baffles in the second group of baffles projecting upwardly from the major horizontal surface of the pan such that, in operation, the respective baffle included in the second group of baffles extends at least partially through the mechanically fluidized particulate bed and does not contact the lower surface of the cover. Each of the plurality of baffles may include a silicon member. Each of the plurality of baffles may include silicon having at least one of: a uniform thickness or a uniform density. Each of the plurality of baffles may include a metallic member that includes a continuous layer of at least one of: graphite, silicon, silicon carbide, quartz, or silicon nitride disposed on at least a portion of the at least one baffle exposed to the mechanically fluidized particulate bed.

The mechanically fluidized reactor system may further include a flexible member that separates the chamber in the housing into an upper chamber and a lower chamber, the flexible member having a first continuous edge and a second continuous edge disposed laterally across the flexible member from the first continuous edge, the first continuous edge of the flexible member physically couples to the housing, to form a gas-tight seal therebetween, and the second continuous edge of the flexible member physically couples to the pan to form a gas-tight seal therebetween such that, in operation: the upper chamber includes at least a portion of the chamber inclusive of the retainment volume; the lower chamber includes at least a portion of the chamber exclusive of the retainment volume; and the flexible member forms a hermetic seal between the upper chamber and the lower chamber.

A mechanically fluidized reactor system may be summarized as including a housing having a chamber therein; a plurality of pans received in the chamber of the housing, each of the plurality of pans having a major horizontal surface with a periphery and an upward extending peripheral wall which terminates in a peripheral edge that surrounds the periphery of the major horizontal surface to at least partially form a retainment volume that at least partially temporarily retains a plurality of particulates; a divider plate apportioning the housing into an upper chamber and a lower chamber, the divider plate having a plurality of apertures, each of the plurality of apertures corresponding to a respective one of the plurality of pans; a transmission that, in operation, oscillates the plurality of pans to mechanically fluidize the plurality of particulates in the retainment volume in each of the plurality of pans to produce a mechanically fluidized particulate bed the retainment volume in each of the plurality of pans; at least one heater thermally coupled to each of the plurality of pans that, in operation, raises a temperature of the mechanically fluidized particulate bed in each of the plurality of pans above a thermal decomposition temperature of the first gaseous chemical species to thermally decompose at least a portion of the first gaseous chemical species present in the mechanically fluidized particulate bed in each of the plurality of pans to at least a non-volatile second chemical species that deposits on at least a portion of the particulates in the mechanically fluidized particulate bed in each of the plurality of pans to provide a plurality of coated particles, and a third gaseous chemical species, the peripheral gap which provides an exit for the third gaseous chemical species into the chamber of the housing from the mechanically fluidized particulate bed in each of the plurality of pans; and a plurality of flexible members, each of the plurality of flexible members having a first continuous edge and a second continuous edge disposed laterally across the respective flexible member from the first continuous edge, the first continuous edge of each of the plurality of flexible members physically coupled to the perimeter wall of one of the plurality of pans and the second continuous edge of each of the plurality of flexible members coupled to the aperture in the divider plate corresponding to the respective pan to form a gas-tight seal between the pan and the divider plate such that, in operation: the upper chamber includes at least a portion of the chamber inclusive of the retainment volume in each of the plurality of pans; the lower chamber includes at least a portion of the chamber exclusive of the retainment volume in each of the plurality of pans; and the plurality of flexible members form a hermetic seal between the upper chamber and the lower chamber. The plurality of pans may consist of four pans. The transmission may include a single transmission shared by all of the pans included in the plurality of pans. The transmission may oscillate each of the plurality of pans in a first operating mode in which a displacement magnitude and a displacement direction of all of the pans in the plurality of pans is substantially identical. The transmission may oscillate each of the plurality of pans in a second operating mode in which a displacement magnitude and a displacement direction of at least some of the pans in the plurality of pans is different from a displacement magnitude and a displacement direction of at least some of the other pans in the plurality of pans such that, in operation, a fluctuation in a first pressure in the upper chamber of the housing and a fluctuation in a second pressure in the lower chamber of the housing are minimized. At least a major horizontal surface of each of the plurality of pans may include silicon having at least one of: a uniform thickness or a uniform density. At least a portion of the major horizontal surface of each of the plurality of pans may include molybdenum. At least a portion of the major horizontal surface of each of the plurality of pans may include at least one of: graphite, silicon, silicon carbide, quartz, or silicon nitride.

A mechanically fluidized reactor system may be summarized as including a housing having a chamber therein; a major horizontal surface having a perimeter, the major horizontal surface disposed transversely across the chamber and rigidly physically coupled about the perimeter to the housing, the major horizontal surface apportioning the chamber into an upper chamber and a lower chamber, the upper chamber hermetically sealed from the lower chamber; a cover having an upper surface, a lower surface, and a peripheral edge, the cover disposed in the upper chamber of the housing, a fixed distance above the major horizontal surface to define a retainment volume between the major horizontal surface and the lower surface of the cover; a transmission that, in operation, oscillates the housing to mechanically fluidize the plurality of particulates in the retainment volume to produce a mechanically fluidized particulate bed in the retainment volume; and a heater thermally coupled to the major horizontal surface that, in operation, raises a temperature of the mechanically fluidized particulate bed above a thermal decomposition temperature of the first gaseous chemical species to thermally decompose at least a portion of the first gaseous chemical species present in the mechanically fluidized particulate bed to at least a non-volatile second chemical species that deposits on at least a portion of the particulates in the mechanically fluidized particulate bed to provide a plurality of coated particles, and a third gaseous chemical species, wherein the peripheral gap provides an exit for the third gaseous chemical species from the mechanically fluidized particulate bed into the upper chamber of the housing.

The mechanically fluidized reactor system may further include a first gaseous species feed system flexibly coupled to the housing; and a first gaseous chemical species distribution header fluidly coupled to the first gaseous species feed system and to a number of injectors, each including at least one outlet positioned in the mechanically fluidized particulate bed, the first gaseous chemical species distribution header rigidly physically coupled in the upper chamber of the housing. Each of the number of injectors fluidly coupled to the first gaseous chemical species distribution header may penetrate the cover in a respective location and may be sealingly coupled to the cover to provide a gas-tight seal therebetween. The cover may include a central aperture that provides a fluidly communicative passage between the retainment volume and the upper chamber of the housing; the peripheral edge of the cover may be physically affixed to an interior wall forming at least a portion of the upper chamber of the housing; and each of the number of injectors fluidly coupled to the first gaseous chemical species distribution header may penetrate the cover at a respective location proximate the peripheral edge of the cover so that the first gaseous chemical species exiting the injectors via the one or more outlets flows radially inward toward the center of the mechanically fluidized particulate bed. The cover may be affixed to at least one of the housing or the major horizontal surface; wherein the peripheral edge of the cover is spaced inward of the housing to provide a peripheral gap between the peripheral edge of the cover and the housing that provides a fluidly communicative passage between the retainment volume and the upper chamber, of the housing; and wherein each of the number of injectors fluidly coupled to the first gaseous chemical species distribution header penetrates the cover at a respective location proximate a central location of the cover such that the first gaseous chemical species exits the injectors via the one or more outlets and flows radially outward toward through the mechanically fluidized particulate bed and exits the retainment volume via the peripheral gap. The cover may be apportioned into a raised portion and a non-raised portion, the raised portion including a portion of the cover directly above and extending radially outward from the product removal tube a fixed radius such that the distance between a lower surface of the raised portion of the cover and the major horizontal surface is greater than the distance between the lower surface of the non-raised portion of the cover and the major horizontal surface. At least a portion of the non-raised portion of the cover may include an insulative layer.

The cover member may further include a number of baffle members projecting at least partially into the mechanically fluidized particulate bed, each of the number of baffle members physically coupled to at least one of: the lower surface of the cover or the major horizontal surface of the pan. Each of the number of baffle members may include silicon having at least one of: a uniform thickness or a uniform density. Each of the baffles may include at least one of: graphite, silicon, silicon carbide, quartz, or silicon nitride.

The mechanically fluidized reactor system may further include a product removal tube penetrating and sealingly coupled to the major horizontal surface; wherein the injectors fluidly coupled to the first gaseous chemical species distribution header penetrate the cover in a respective location disposed radially about the product removal tube.

The mechanically fluidized reactor system may further include a purge gas supply system fluidly coupled to the product removal tube to pass a quantity of non-reactive purge gas through the coated particle overflow conduit to the mechanically fluidized particulate bed.

A mechanically fluidized reactor system may be summarized as including a pan having a major horizontal surface with a periphery and an upward extending peripheral wall which terminates in a peripheral edge that surrounds the periphery of the major horizontal surface to at least partially form a retainment volume that at least partially temporarily retains a plurality of particulates; a cover having an upper surface and a lower surface, the cover positioned relative to the pan such that, in operation, the cover continuously contacts the perimeter wall of the pan, forming a hermetic seal between the cover and the perimeter wall of the pan; a transmission that, in operation, oscillates the pan to mechanically fluidize the plurality of particulates in the retainment volume to produce a mechanically fluidized particulate bed in the retainment volume; and a heater thermally coupled to the pan that, in operation, raises a temperature of the mechanically fluidized particulate bed above a thermal decomposition temperature of the first gaseous chemical species to thermally decompose at least a portion of the first gaseous chemical species present in the mechanically fluidized particulate bed to at least a non-volatile second chemical species that deposits on at least a portion of the particulates in the mechanically fluidized particulate bed to provide a plurality of coated particles.

The mechanically fluidized reactor system may further include a first gaseous chemical species feed system flexibly coupled to the cover; and a first gaseous chemical species distribution header fluidly coupled to the first gaseous chemical species feed system and rigidly coupled to the cover, the distribution header fluidly coupled to a number of injectors, each respective one of the number of injectors including at least one outlet positioned in the mechanically fluidized particulate bed. The injectors fluidly coupled to the first gaseous chemical species distribution header may penetrate the cover and may be sealingly coupled to the cover to provide a gas-tight seal therebetween. The cover may be apportioned into a raised portion and a non-raised portion, the raised portion including a portion of the cover directly above and extending radially outward from the product removal tube a fixed radius such that the distance between a lower surface of the raised portion of the cover and the major horizontal surface is greater than the distance between the lower surface of the non-raised portion of the cover and the major horizontal surface. At least a portion of the cover may include an insulative layer.

The mechanically fluidized reactor system may further include a thermal energy transfer system thermally coupled to at least the raised portion of the cover, the thermal energy transfer system to, in operation, maintain a temperature of the raised portion of the cover below the thermal decomposition temperature of the first gaseous chemical species. Each of the number of injectors may be at least partially thermally insulated; and the first gaseous chemical species distribution header may include a thermally insulated feed tube including a thermally insulated fluid passage that provides a hermetically sealed, fluidly communicative, path between the first gaseous chemical species feed system and at least one outlet on each respective one of the number of injectors positioned in the mechanically fluidized particulate bed. The thermally insulated feed tube may include an outer tube member that forms an outer tube passage and an open-ended inner tube member that forms the insulated fluid passage, the open-ended inner tube member received in the outer tube passage of the outer tube member; and the outer tube member and the open-ended inner tube member may contact each other at a location proximate the outlet of each of the number of injectors to form a closed-ended void that extends along at least a portion of the length of the thermally insulated feed tube and the number of injectors, the closed-ended void including an insulative vacuum. The thermally insulated feed tube may include an outer tube member that forms an outer tube passage and an open-ended inner tube member that forms the insulated fluid passage, the open-ended inner tube member received in the outer tube passage of the outer tube member; and, wherein the outer tube member and the open-ended inner tube member contact each other at a location proximate the outlet of each of the number of injectors to form a closed-ended void that extends along at least a portion of the length of the thermally insulated feed tube and the number of injectors, the closed-ended void including one or more thermally insulating materials or substances.

The mechanically fluidized reactor system may further include a cooling media supply system; wherein the thermally insulated feed tube comprises an outer tube member that forms an outer tube passage and an open-ended inner tube member that forms the insulated fluid passage, the open-ended inner tube received in the outer tube passage of the outer tube member; wherein the outer tube member and the open-ended inner tube member do not contact each other along at least a portion of the length of the thermally insulated feed tube and the number of injectors to form an open-ended flow path that extends along at least a portion of a length of the thermally insulated feed tube and the number of injectors; and wherein the cooling media supply system fluidly coupled to the open-ended void to provide a flow path for passage of a cooling fluid that maintains a temperature of the first gaseous chemical species within the insulated fluid passage below the thermal decomposition temperature of the first gaseous chemical species.

The mechanically fluidized reactor system may include a second outer tube passage formed between the outer tube member and a second outer tube member, the intervening space between the outer tube member and the second outer tube member forming the second outer tube passage; the outer tube passage and the second outer tube passage contact each other to form a close-ended void containing at least one of: an insulative vacuum or a thermally insulating material. The thermally insulated feed tube may further include one or more features positioned proximate the outlet, the one or more features causing at least a portion of the cooling fluid that exits the open-ended void to pass across the outlet of the inner tube. The one or more features may include at least one of: an extension of the outer tube member on each of the number of injectors so that the outer tube member extends a distance beyond the open-end of the inner tube member or a physical member disposed in the flow path of the cooling fluid that exits the open-ended void.

The mechanically fluidized reactor system may further include a hollow product removal tube having an inlet and a distal end, the hollow product removal tube penetrating and physically coupled to the major horizontal surface; wherein the injectors fluidly coupled to the first gaseous chemical species distribution header penetrates the cover in a plurality of locations disposed radially about the product removal tube.

The mechanically fluidized reactor system may further include a purge gas supply system fluidly coupled to the product removal tube to pass a quantity of non-reactive purge gas through the coated particle overflow conduit to the mechanically fluidized particulate bed. The inlet of the product removal tube may be positioned a distance above the upper surface of the major horizontal surface of the pan; and the distance the inlet of the product removal tube is positioned above the upper surface of the major horizontal surface of the pan is variable to adjust a depth of the mechanically fluidized particulate bed in the retainment volume.

A method of operating a mechanically fluidized reactor may be summarized as including introducing a plurality of particulates to a retainment volume defined by a pan and a cover disposed in a chamber of a housing, the pan having a major horizontal surface with a periphery and an upward extending peripheral wall that surrounds the periphery of the major horizontal surface that at least partially form the retainment volume, the cover, having an upper surface, a lower surface, and a peripheral edge is disposed above the major horizontal surface of the pan; oscillating the pan at least along an axis perpendicular to the major horizontal surface of the pan such that, in operation, the plurality of particulates carried by the major horizontal surface of the pan bottom is fluidized to form a mechanically fluidized particulate bed in the retainment volume; heating the mechanically fluidized particulate bed to a temperature in excess of a thermal decomposition temperature of a first gaseous chemical species; and causing the first gaseous chemical species to flow through at least a portion of the mechanically fluidized particulate bed; wherein the first gaseous chemical species comprises of a gas that thermally decomposes to at least a non-volatile second chemical species; wherein a first portion of the non-volatile second chemical species deposits on at least a portion of the plurality of particulates in the mechanically fluidized particulate bed to provide a plurality of coated particles; selectively removing at least a portion of the plurality of coated particles from the mechanically fluidized particulate bed in the retainment volume. The peripheral edge of the cover may be spaced a distance inward from the peripheral wall of the pan to form a peripheral gap therebetween; wherein causing the first gaseous chemical species to flow through at least a portion of the mechanically fluidized particulate bed may include: introducing the first gaseous chemical species to the mechanically fluidized particulate bed at one or more central locations in the mechanically fluidized particulate bed via a distribution header that includes a number of injectors, each of the injectors including at least one outlet positioned in the mechanically fluidized particulate bed; and causing the first gaseous chemical species to flow, via a plug flow regime, in a radially outward serpentine path through the mechanically fluidized particulate bed. Causing the first gaseous chemical species to flow, via a plug flow regime, in a radially outward serpentine path through the mechanically fluidized particulate bed may include causing the first gaseous chemical species to flow, via the plug flow regime, in the radially outward serpentine path through the mechanically fluidized particulate bed, the serpentine path created, at least in part, via a number of baffle members projecting at least partially through a depth of the mechanically fluidized particulate bed, each of the number of baffle members physically coupled to at least one of: the lower surface of the cover or the major horizontal surface of the pan.

Causing the first gaseous chemical species to flow, via the plug flow regime, in the radially outward serpentine path through the mechanically fluidized particulate bed, the serpentine path created, at least in part, via a number of baffle members projecting at least partially through a depth of the mechanically fluidized particulate bed may include causing the first gaseous chemical species to flow, via the plug flow regime, in the radially outward serpentine path through the mechanically fluidized particulate bed, the serpentine path created, at least in part, via the number of baffle members projecting at least partially through a depth of the mechanically fluidized particulate bed, each of the number of baffle members comprising silicon having at least one of: a uniform thickness or a uniform density.

Causing the first gaseous chemical species to flow, via the plug flow regime, in the radially outward serpentine path through the mechanically fluidized particulate bed, the serpentine path created, at least in part, via a number of baffle members projecting at least partially through a depth of the mechanically fluidized particulate bed may include: causing the first gaseous chemical species to flow, via the plug flow regime, in the radially outward serpentine path through the mechanically fluidized particulate bed, the serpentine path created, at least in part, via the number of baffle members projecting at least partially through a depth of the mechanically fluidized particulate bed, each of the number of baffle members comprising at least one of: graphite, silicon, silicon carbide, quartz, or silicon nitride.

The peripheral edge of the cover may contact and form a hermetic seal with the peripheral wall of the pan and the cover may further include at least one aperture fluidly coupling the retainment volume to the chamber of the housing; and causing the first gaseous chemical species to flow through at least a portion of the mechanically fluidized particulate bed may include: introducing the first gaseous chemical species to the mechanically fluidized particulate bed at one or more peripheral locations disposed in a pattern proximate the peripheral edge of the cover via a distribution header that includes a number of injectors, each of the injectors including at least one outlet positioned in the mechanically fluidized particulate bed; and causing the first gaseous chemical species to flow, via a plug flow regime, in a radially inward serpentine path through the mechanically fluidized particulate bed. Causing the first gaseous chemical species to flow, via a plug flow regime, in a radially inward serpentine path through the mechanically fluidized particulate bed may include: causing the first gaseous chemical species to flow, via the plug flow regime, in the radially inward serpentine path through the mechanically fluidized particulate bed, the serpentine path created, at least in part, via a number of baffle members projecting at least partially through a depth of the mechanically fluidized particulate bed, each of the number of baffle members physically coupled to at least one of: the lower surface of the cover or the major horizontal surface of the pan. Causing the first gaseous chemical species to flow, via the plug flow regime, in the radially inward serpentine path through the mechanically fluidized particulate bed, the serpentine path created, at least in part, via a number of baffle members projecting at least partially through a depth of the mechanically fluidized particulate bed may include: causing the first gaseous chemical species to flow, via the plug flow regime, in the radially inward serpentine path through the mechanically fluidized particulate bed, the serpentine path created, at least in part, via the number of baffle members projecting at least partially through a depth of the mechanically fluidized particulate bed, each of the number of baffle members comprising silicon having at least one of: a uniform thickness or a uniform density. Causing the first gaseous chemical species to flow, via the plug flow regime, in the radially inward serpentine path through the mechanically fluidized particulate bed, the serpentine path created, at least in part, via a number of baffle members projecting at least partially through a depth of the mechanically fluidized particulate bed may include: causing the first gaseous chemical species to flow, via the plug flow regime, in the radially inward serpentine path through the mechanically fluidized particulate bed, the serpentine path created, at least in part, via the number of baffle members projecting at least partially through a depth of the mechanically fluidized particulate bed, each of the number of baffle members comprising at least one of: graphite, silicon, silicon carbide, quartz, or silicon nitride.

The method may further include maintaining a first gas pressure level in the retainment volume and maintaining a second gas pressure level in at least a portion of the chamber external to the retainment volume, the first gas pressure level different than the second gas pressure level. Maintaining a first gas pressure level in the retainment volume may include: maintaining the first gas pressure level in the retainment volume by maintaining an upper chamber in the chamber of the housing at the first gas pressure level, the upper chamber formed by separating the chamber in the housing into the upper chamber and a lower chamber using a flexible member, the flexible member including a first continuous edge of the flexible member physically coupled to the housing, to form a gas-tight seal therebetween, and a second continuous edge of the flexible member physically couples to the pan to form a gas-tight seal therebetween such that, in operation: the upper chamber includes at least a portion of the chamber inclusive of the retainment volume; the lower chamber includes at least a portion of the chamber exclusive of the retainment volume; and the plurality of flexible members form a hermetic seal between the upper chamber and the lower chamber. Maintaining a second gas pressure level in at least a portion of the chamber external to the retainment volume, the first gas pressure level different than the second gas pressure level may include: maintaining the second gas pressure level in the lower chamber. Selectively removing at least a portion of the plurality of coated particles from the mechanically fluidized particulate bed in the retainment volume may include: collecting at least a portion of the plurality of coated particles from the mechanically fluidized particulate bed in a coated particle overflow conduit having an inlet and a passage extending therethrough from the inlet to a distal portion of the particle overflow tube, the coated particle overflow conduit which projects from the major horizontal surface of the pan with the inlet positioned in the retainment volume.

Selectively removing at least a portion of the plurality of coated particles from the mechanically fluidized particulate bed in the retainment volume may include: collecting at least a portion of the coated particles from the mechanically fluidized particulate bed that flow over the edge of the peripheral wall of the pan.

The method may further include maintaining the temperature in the chamber external to the mechanically fluidized bed that is less than the thermal decomposition temperature of the first gaseous chemical species. Introducing a plurality of particulates to a retainment volume defined by a pan and a cover disposed in a chamber of a housing may include: creating, in situ within the mechanically fluidized particulate bed, at least a portion of the plurality of particulates introduced to the retainment volume via the spontaneous decomposition and self-nucleation of at least a portion of the first gaseous chemical species passed through the mechanically fluidized particulate bed.

The method may further include controlling a velocity of a gas exiting the mechanically fluidized particulate bed to the chamber so that a majority of the self-nucleated particulates are retained in the mechanically fluidized particulate bed.

A method of operating a mechanically fluidized reactor may be summarized as including introducing a plurality of particulates to a retainment volume defined by a major horizontal surface, having an upper surface and a lower surface, and a cover disposed within a chamber in a housing and apportioning the chamber into an upper chamber and a lower chamber, the cover, having an upper surface, a lower surface, and a peripheral edge, is disposed above the major horizontal surface of the pan; oscillating the housing at least along an axis perpendicular to the major horizontal surface such that, in operation, the plurality of particulates carried by the major horizontal surface is fluidized to form a mechanically fluidized particulate bed; heating the mechanically fluidized particulate bed to a temperature in excess of a thermal decomposition temperature of a first gaseous chemical species; and causing the first gaseous chemical species to flow through at least a portion of the heated mechanically fluidized particulate bed; wherein the first gaseous chemical species comprises a gas that thermally decomposes to at least a non-volatile second chemical species; wherein a first portion of the non-volatile second chemical species deposits on at least a portion of the plurality of particulates in the heated mechanically fluidized particulate bed to provide a plurality of coated particles; selectively removing at least a portion of the plurality of coated particles from the mechanically fluidized particulate bed in the retainment volume. Passing the first gaseous chemical species through at least a portion of the mechanically fluidized particulate bed may include: maintaining a temperature of the first gaseous chemical species below the thermal decomposition temperature of the first gaseous chemical species prior to passing the first gaseous chemical species through at least a portion of the mechanically fluidized particulate bed. Selectively removing at least a portion of the plurality of coated particles from the mechanically fluidized particulate bed in the retainment volume may include: collecting at least a portion of the plurality of coated particles from the mechanically fluidized particulate bed in a coated particle overflow conduit having an inlet and a passage extending therethrough from the inlet to a distal portion of the particle overflow tube, the coated particle overflow conduit which projects from the major horizontal surface of the pan with the inlet positioned in the retainment volume.

The method may further include causing at least one inert gas to flow through the coated particle overflow conduit and into the mechanically fluidized particulate bed to prevent the flow of the first gaseous species through the coated particle overflow conduit. Oscillating the housing at least along an axis perpendicular to the major horizontal surface such that, in operation, the plurality of particulates carried by the major horizontal surface is fluidized to form a mechanically fluidized particulate bed may include: oscillating the housing at least along an axis perpendicular to the major horizontal surface such that, in operation, the plurality of particulates carried by the major horizontal surface is fluidized to form a mechanically fluidized particulate bed, wherein the mechanically fluidized particulate bed touches (e.g., lightly, firmly) the bottom surface of the cover. Introducing a plurality of particulates to a retainment volume defined by a major horizontal surface and a cover disposed in a chamber of a housing may include: creating, in situ within the mechanically fluidized particulate bed, at least a portion of the plurality of particulates introduced to the retainment volume via the spontaneous decomposition and self-nucleation of at least a portion of the first gaseous chemical species passed through the mechanically fluidized particulate bed.

The method may further include controlling a velocity of a gas exiting the mechanically fluidized particulate bed to the chamber so that a majority of the self-nucleated particulates are retained in the mechanically fluidized particulate bed. The peripheral edge of the cover may be spaced a distance inward from an interior wall forming at least a portion of the chamber of the housing to form a peripheral gap therebetween; and causing the first gaseous chemical species to flow through at least a portion of the mechanically fluidized particulate bed may include: introducing the first gaseous chemical species to the mechanically fluidized particulate bed at one or more central locations in the mechanically fluidized particulate bed via a distribution header that includes a number of injectors, each of the injectors including at least one outlet positioned in the mechanically fluidized particulate bed; and causing the first gaseous chemical species to flow, via a plug flow regime, in a radially outward serpentine path through the mechanically fluidized particulate bed. Causing the first gaseous chemical species to flow, via a plug flow regime, in a radially outward serpentine path through the mechanically fluidized particulate bed may include: causing the first gaseous chemical species to flow, via the plug flow regime, in the radially outward serpentine path through the mechanically fluidized particulate bed, the serpentine path created, at least in part, via a number of baffle members projecting at least partially through a depth of the mechanically fluidized particulate bed, each of the number of baffle members physically coupled to at least one of: the lower surface of the cover or the major horizontal surface of the pan. Causing the first gaseous chemical species to flow, via the plug flow regime, in the radially outward serpentine path through the mechanically fluidized particulate bed, the serpentine path created, at least in part, via a number of baffle members projecting at least partially through a depth of the mechanically fluidized particulate bed may include: causing the first gaseous chemical species to flow, via the plug flow regime, in the radially outward serpentine path through the mechanically fluidized particulate bed, the serpentine path created, at least in part, via the number of baffle members projecting at least partially through a depth of the mechanically fluidized particulate bed, each of the number of baffle members comprising silicon having at least one of: a uniform thickness or a uniform density. Causing the first gaseous chemical species to flow, via the plug flow regime, in the radially outward serpentine path through the mechanically fluidized particulate bed, the serpentine path created, at least in part, via a number of baffle members projecting at least partially through a depth of the mechanically fluidized particulate bed may include: causing the first gaseous chemical species to flow, via the plug flow regime, in the radially outward serpentine path through the mechanically fluidized particulate bed, the serpentine path created, at least in part, via the number of baffle members projecting at least partially through a depth of the mechanically fluidized particulate bed, each of the number of baffle members comprising at least one of: graphite, silicon, silicon carbide, quartz, or silicon nitride.

The peripheral edge of the cover may contact and form a hermetic seal with an interior wall surface forming the chamber of the housing and the cover may further include at least one aperture fluidly coupling the retainment volume to the chamber of the housing; and causing the first gaseous chemical species to flow through at least a portion of the mechanically fluidized particulate bed may include: introducing the first gaseous chemical species to the mechanically fluidized particulate bed at one or more peripheral locations disposed in a pattern proximate the peripheral edge of the cover via a distribution header that includes a number of injectors, each of the injectors including at least one outlet positioned in the mechanically fluidized particulate bed; and cause the first gaseous chemical species to flow, via a plug flow regime, in a radially inward serpentine path through the mechanically fluidized particulate bed. Causing the first gaseous chemical species to flow, via a plug flow regime, in a radially inward serpentine path through the mechanically fluidized particulate bed may include: causing the first gaseous chemical species to flow, via the plug flow regime, in the radially inward serpentine path through the mechanically fluidized particulate bed, the serpentine path created, at least in part, via a number of baffle members projecting at least partially through a depth of the mechanically fluidized particulate bed, each of the number of baffle members physically coupled to at least one of: the lower surface of the cover or the major horizontal surface of the pan. Causing the first gaseous chemical species to flow, via the plug flow regime, in the radially inward serpentine path through the mechanically fluidized particulate bed, the serpentine path created, at least in part, via a number of baffle members projecting at least partially through a depth of the mechanically fluidized particulate bed may include: causing the first gaseous chemical species to flow, via the plug flow regime, in the radially inward serpentine path through the mechanically fluidized particulate bed, the serpentine path created, at least in part, via the number of baffle members projecting at least partially through a depth of the mechanically fluidized particulate bed, each of the number of baffle members comprising silicon having at least one of: a uniform thickness or a uniform density. Causing the first gaseous chemical species to flow, via the plug flow regime, in the radially inward serpentine path through the mechanically fluidized particulate bed, the serpentine path created, at least in part, via a number of baffle members projecting at least partially through a depth of the mechanically fluidized particulate bed may include: causing the first gaseous chemical species to flow, via the plug flow regime, in the radially inward serpentine path through the mechanically fluidized particulate bed, the serpentine path created, at least in part, via the number of baffle members projecting at least partially through a depth of the mechanically fluidized particulate bed, each of the number of baffle members comprising at least one of: graphite, silicon, silicon carbide, quartz, or silicon nitride.

A method of operating a mechanically fluidized reactor may be summarized as including introducing a plurality of particulates to a retainment volume defined by a major horizontal surface of a pan and a cover hermetically sealed to an upturned peripheral wall of the pan, the cover, having an upper surface, a lower surface, and a peripheral edge, is disposed above the major horizontal surface of the pan; oscillating the pan and cover at least along an axis perpendicular to the major horizontal surface such that, in operation, the plurality of particulates carried by the major horizontal surface is fluidized to form a mechanically fluidized particulate bed; heating the mechanically fluidized particulate bed to a temperature in excess of a thermal decomposition temperature of a first gaseous chemical species; and passing the first gaseous chemical species through at least a portion of the mechanically fluidized particulate bed; wherein the first gaseous chemical species comprises of a gas that thermally decomposes to at least a non-volatile second chemical species; wherein a first portion of the non-volatile second chemical species deposits on at least a portion of the plurality of particulates in the mechanically fluidized particulate bed to provide a plurality of coated particles; selectively removing at least a portion of the plurality of coated particles from the mechanically fluidized particulate bed in the retainment volume. Introducing a plurality of particulates to a retainment volume defined by a major horizontal surface of a pan and a cover hermetically sealed to an upturned peripheral wall of the pan may include: creating, in situ within the mechanically fluidized particulate bed, at least a portion of the plurality of particulates introduced to the retainment volume via the spontaneous decomposition and self-nucleation of at least a portion of the first gaseous chemical species passed through the mechanically fluidized particulate bed.

The method may further include controlling a velocity of a gas exiting the mechanically fluidized particulate bed to the chamber so that a majority of the self-nucleated particulates are retained in the mechanically fluidized particulate bed.

### BRIEF DESCRIPTION OF SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements, as drawn, are not intended to convey any information regarding the actual shape of the particular elements; and have been solely selected for ease of recognition in the drawings.

FIG. 1 is a partial sectional view of an example mechanically fluidized reactor useful in chemical vapor deposition reactions in which a gaseous first chemical species decomposes within a mechanically fluidized particulate bed to deposit a non-volatile second chemical species on the particulates to form coated particles, according to an illustrated embodiment.

FIG. 2 is a partial sectional view of another example mechanically fluidized reactor useful in chemical vapor deposition reactions in which a gaseous first chemical species decomposes within a mechanically fluidized particulate bed to deposit a non-volatile second chemical species on the particulates to form coated particles, according to an illustrated embodiment.

FIG. 3A is a partial sectional view of another example mechanically fluidized reactor using a covered pan to contain the mechanically fluidized particulate bed; such reactors are useful in chemical vapor deposition reactions in which a gaseous first chemical species decomposes within the mechanically fluidized particulate bed to deposit a non-volatile second chemical species on the particulates to form coated particles, according to an illustrated embodiment.

FIG. 3B is a partial sectional view of a gas distribution system that includes a number of injectors fluidly coupled to a distribution header, each of the injectors surrounded by a close-ended void space containing one of either an insulative vacuum or an insulative material to prevent premature decomposition of the first gaseous chemical species in the injectors, according to an illustrated embodiment.

FIG. 3C is a partial sectional view of another gas distribution system that includes a number of injectors fluidly coupled to a distribution header, each of the injectors surrounded by an open-ended void space through which a cooling inert fluid is passed to prevent premature decomposition of the first gaseous chemical species in the injectors, according to an illustrated embodiment.

FIG. 3D is a partial sectional view of a gas distribution system that includes a number of injectors fluidly coupled to a distribution header, each of the injectors surrounded by an open-ended void space through which a cooling inert fluid is passed and a closed-ended second void space containing one of either an insulative vacuum or an insulative material to prevent premature decomposition of the first gaseous chemical species in the injectors, according to an illustrated embodiment.

FIG. 3E is a partial sectional view of a gas distribution system that includes a number of injectors fluidly coupled to a distribution header, each of the injectors surrounded by a close-ended void space through which a coolant fluid is passed to prevent premature decomposition of the first gaseous chemical species in the injectors, according to an illustrated embodiment.

FIG. 4A is a partial sectional view of an alternative covered pan featuring a peripheral vent and a “top hat” type chamber proximate the coated particle overflow and in which the first gaseous chemical species is introduced centrally and flows radially outward through the mechanically fluidized particulate bed, according to an illustrated embodiment.

FIG. 4B is a partial sectional view of an alternative covered pan featuring baffles disposed concentrically about the coated particle overflow and coupled to the cover and the pan in an alternating pattern to form a serpentine gas flow path from the first gaseous chemical species distribution header to the periphery of the pan, according to an illustrated embodiment.

FIG. 4C is a partial sectional view of an alternative covered pan featuring a central vent and a peripheral first gaseous chemical species distribution header in which the first gaseous chemical species is introduced peripherally and flows radially inward through the mechanically fluidized particulate bed, according to an illustrated embodiment.

FIG. 5A is a plan view of a cover used with a covered pan that is anchored to the pan and oscillates with the pan thereby maintaining a fixed volume mechanically fluidized bed, according to an illustrated embodiment.

FIG. 5B is a cross-sectional elevation of the cover depicted in FIG. 5A, according to an illustrated embodiment.

FIG. 5C is a plan view of a cover used with a covered pan that is anchored to the mechanically fluidized bed reactor vessel and does not oscillate with the pan thereby creating a variable volume mechanically fluidized bed, according to an illustrated embodiment.

FIG. 5D is a cross-sectional elevation of the cover depicted in FIG. 5C, according to an illustrated embodiment.

FIG. 6 is a partial sectional view of another example mechanically fluidized reactor using a plurality of covered pans each of which contains the mechanically fluidized particulate bed; such reactors are useful in chemical vapor deposition reactions in which a gaseous first chemical species decomposes within the mechanically fluidized particulate bed to deposit a non-volatile second chemical species on the particulates to form coated particles, according to an illustrated embodiment.

FIG. 7A is a partial sectional view of another example mechanically fluidized reactor using a covered pan to contain the mechanically fluidized particulate bed and in which the entire reaction vessel oscillates to mechanically fluidize the particulate bed carried in the covered pan; such reactors are useful in chemical vapor deposition reactions in which a gaseous first chemical species decomposes within the mechanically fluidized particulate bed to deposit a non-volatile second chemical species on the particulates to form coated particles, according to an illustrated embodiment.

FIG. 7B is a partial sectional view of an alternative covered pan featuring a peripheral vent and a “top hat” type chamber proximate the coated particle overflow and in which the first gaseous chemical species is introduced centrally and flows radially outward through the mechanically fluidized particulate bed; the covered pan positioned in a mechanically fluidized bed reactor in which the entire reaction vessel oscillates to mechanically fluidize the particulate bed carried in the covered pan, according to an illustrated embodiment.

FIG. 7C is a partial sectional view of an alternative covered pan featuring baffles disposed concentrically about the coated particle overflow and coupled to the cover and the pan in an alternating pattern to form a serpentine gas flow path from the first gaseous chemical species distribution header to the periphery of the pan; the covered pan positioned in a mechanically fluidized bed reactor in which the entire reaction vessel oscillates to mechanically fluidize the particulate bed carried in the covered pan according to an illustrated embodiment.

FIG. 7D is a partial sectional view of an alternative covered pan featuring a central vent and a peripheral first gaseous chemical species distribution header in which the first gaseous chemical species is introduced peripherally and flows radially inward through the mechanically fluidized particulate bed; the covered pan positioned in a mechanically fluidized bed reactor in which the entire reaction vessel oscillates to mechanically fluidize the particulate bed carried in the covered pan, according to an illustrated embodiment.

FIG. 8A is a partial sectional view of an example mechanically fluidized reactor in which the reactor itself functions as a covered pan to contain the mechanically fluidized particulate bed and in which the entire reaction vessel oscillates to mechanically fluidize the particulate bed; such reactors are useful in chemical vapor deposition reactions in which a gaseous first chemical species decomposes within the mechanically fluidized particulate bed to deposit a non-volatile second chemical species on the particulates to form coated particles, according to an illustrated embodiment.

FIG. 8B is a partial sectional view of another example mechanically fluidized reactor in which the reactor itself functions as a covered pan to contain the mechanically fluidized particulate bed and in which the entire reaction vessel oscillates to mechanically fluidize the particulate bed; such reactors are useful in chemical vapor deposition reactions in which a gaseous first chemical species decomposes within the mechanically fluidized particulate bed to deposit a non-volatile second chemical species on the particulates to form coated particles, according to an illustrated embodiment.

FIG. 9 is a schematic view of an example semi-batch production process including three serially coupled mechanically fluidized bed reaction vessels suitable for the production of second chemical species coated particles using one or more of the mechanically fluidized bed reactors depicted in FIGS. 1-7B, according to an embodiment.

### DETAILED DESCRIPTION

In the following description, certain specific details are included to provide a thorough understanding of various disclosed embodiments. One skilled in the relevant art, however, will recognize that embodiments may be practiced without one or more of these specific details, or with other methods, components, materials, etc. In other instances, well-known structures associated with systems for making silicon including, but not limited to, vessel design and construction details, metallurgical properties, piping, control system design, mixer design, separators, vaporizers, valves, controllers, or final control elements, have not been shown or described in detail to avoid unnecessarily obscuring descriptions of the embodiments.

Unless the context requires otherwise, throughout the specification and claims which follow, the word “comprise” and variations thereof, such as, “comprises” and “comprising” are to be construed in an open, inclusive sense, that is, as “including, but not limited to.”

Reference throughout this specification to “one embodiment,” or “an embodiment,” or “another embodiment,” or “some embodiments,” or “certain embodiments” means that a particular referent feature, structure, or characteristic described in connection with the embodiment is included in at least one embodiment. Thus, the appearance of the phrases “in one embodiment,” or “in an embodiment,” or “in another embodiment,” or “in some embodiments,” or “in certain embodiments” in various places throughout this specification are not necessarily all referring to the same embodiment. Furthermore, the particular features, structures, or characteristics may be combined in any suitable manner in one or more embodiments.

It should be noted that, as used in this specification and the appended claims, the singular forms “a,” “an,” and “the” include plural referents unless the content clearly dictates otherwise. Thus, for example, reference to a chlorosilane includes a single species of chlorosilane, but may also include multiple species of chlorosilanes. It should also be noted that the term “or” is generally employed as including “and/or” unless the content clearly dictates otherwise.

As used herein, the term “silane” refers to SiH₄. As used herein, the term “silanes” is used generically to refer to silane and/or any derivatives thereof. As used herein, the term “chlorosilane” refers to a silane derivative wherein one or more of hydrogen has been substituted by chlorine. The term “chlorosilanes” refers to one or more species of chlorosilane. Chlorosilanes are exemplified by monochlorosilane (SiH₃Cl or MCS); dichlorosilane (SiH₂Cl₂ or DCS); trichlorosilane (SiHCl₃ or TCS); or tetrachlorosilane, also referred to as silicon tetrachloride (SiCl₄ or STC). The melting point and boiling point of silanes increases with the number of chlorines in the molecule. Thus, for example, silane is a gas at standard temperature and pressure (0° C./1273 K and 101 kPa), while silicon tetrachloride is a liquid. As used herein, the term “silicon” refers to atomic silicon, i.e., silicon having the formula Si. Unless otherwise specified, the terms “silicon” and “polysilicon” are used interchangeably herein when referring to the silicon product of the methods and systems disclosed herein. Unless otherwise specified, concentrations expressed herein as percentages should be understood to mean that the concentrations are in mole percent.

As used herein, the terms “decomposition,” “chemical decomposition,” “chemically decomposed,” “thermal decomposition,” and “thermally decomposed” all refer to a process by which a first gaseous chemical species (e.g., silane) is heated above a thermal decomposition temperature at which the first gaseous chemical species decomposes to at least a non-volatile second chemical species (e.g., silicon). In some implementations, the decomposition of the first gaseous chemical species may also produce one or more reaction byproducts such as one or more third gaseous chemical species (e.g., hydrogen). Such reactions may be considered as a thermally initiated chemical decomposition or, more simply, as a “thermal decomposition.” It should be noted that the thermal decomposition temperature of the first gaseous chemical species is not a fixed value and varies with the pressure at which the first gaseous chemical species is maintained.

As used herein, the term “mechanically fluidized” refers to the mechanical suspension or fluidization of particles forming the particulate bed, for example by mechanically oscillating or vibrating the particulate bed in a manner promoting the flow and circulation (i.e., the “mechanical fluidization”) of the particles. Such mechanical fluidization, generated by a cyclical or repeated physical displacement (e.g., vibration or oscillation) of the one or more surfaces supporting the particulate bed (e.g., a pan or major horizontal surface) or the retainment volume about the particulate bed, is therefore distinct from a hydraulically fluidized bed generated by the passage of a liquid or gas through a particulate bed. It should be noted with particularity that a mechanically fluidized particulate bed is not reliant upon, and at time is independent of, the passage of a fluid (i.e., liquid or gas) through the plurality of particulates to attain fluid-like behavior. As such, fluid volumes passed through a mechanically fluidized bed can be significantly smaller than the fluid volumes used in a hydraulically fluidized bed. In addition, a quiescent (i.e., non-fluidized) plurality of particles represents a “settled bed” which occupies a “settled volume.” When fluidized, the same plurality of particles occupies a “fluidized volume” which is greater than the settled volume occupied by the plurality of particles. The terms “vibration” and “oscillation,” and variations of such (e.g., vibrating, oscillating) are used interchangeably herein.

As used herein, the terms “particulate bed” and “heated particulate bed” refer to any type of particulate bed, including packed (i.e., settled) particulate beds, hydraulically fluidized particulate beds, and mechanically fluidized particulate beds. The term “heated fluidized particulate bed” can refer to either or both a heated hydraulically fluidized particulate bed and/or a heated mechanically fluidized particulate bed. The term “hydraulically fluidized particulate bed” refers specifically to a fluidized bed created by the passage of a fluid (i.e., liquid or gas) through a particulate bed. The term “mechanically fluidized particulate bed” refers specifically to a fluidized bed created by oscillating or vibrating a surface supporting the particulate bed at an oscillatory frequency and/or oscillatory displacement sufficient to fluidize the particulate bed.

The headings provided herein are for convenience only and do not interpret the scope or meaning of the embodiments.

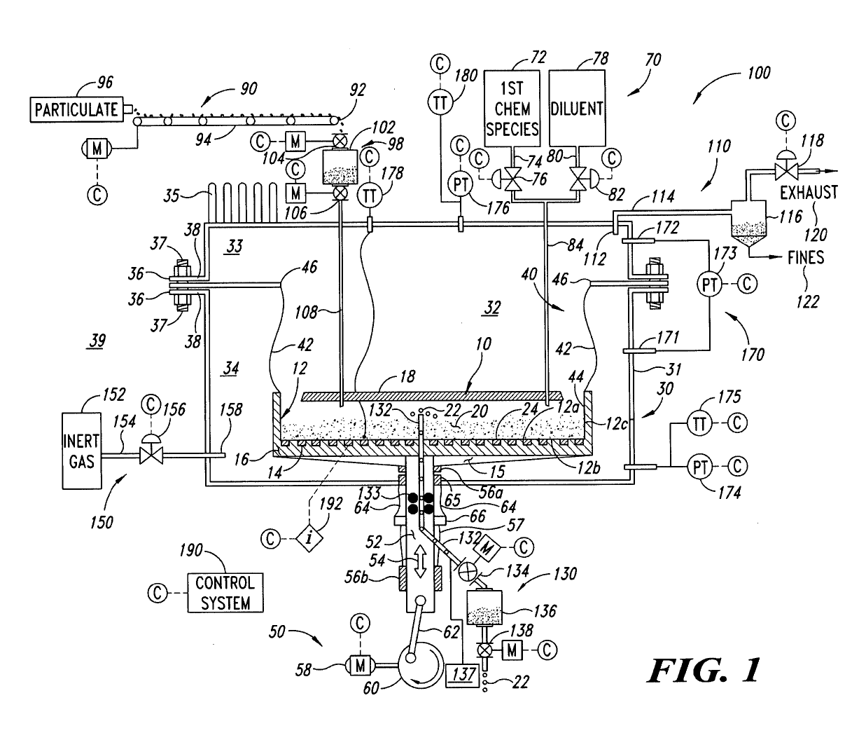

FIG. 1 shows a mechanically fluidized bed reactor system 100, according to one illustrated embodiment. In the mechanically fluidized bed reactor system 100, at least one gas including controlled quantities of a first gaseous chemical species and, optionally, controlled quantities of one or more diluent(s) is introduced to a mechanically fluidized particulate bed 20 carried by a pan 12. The interior of the mechanically fluidized bed reactor vessel 30 includes a chamber 32 that is, at times, apportioned into an upper chamber 33 and a lower chamber 34. In some instances, a flexible membrane 42 separates and hermetically seals all or a portion of the mechanically fluidized bed 20 in the upper chamber 33 from the lower chamber 34.

The mechanically fluidized bed reactor system 100 includes a mechanically fluidized bed apparatus 10 that is useful for mechanically fluidizing particles, seeds, dust, grains, granules, beads, etc. (hereinafter collectively referred to as “particulates” for clarity). The mechanically fluidized bed reactor system 100 also includes one or more thermal energy emitting devices 14, such as one or more heaters, that are thermally coupled to the pan 12 and/or the mechanically fluidized particulate bed 20, and are used to increase the temperature of the mechanically fluidized particulate bed 20 to a temperature in excess of the decomposition temperature of the first gaseous chemical species as the pan 12 oscillates or vibrates.

The heated, mechanically fluidized particles in the particulate bed 20 provide a substrate upon which the non-volatile second chemical species (e.g., polysilicon) formed by the thermal decomposition of the first gaseous chemical species (e.g., silane) deposits. At times, the thermal decomposition of the first gaseous chemical species occurs within the mechanically fluidized particulate bed 20 and either does not occur or occurs minimally in other locations within the chamber 32, even though the environment in the chamber 32 may be maintained at an elevated temperature and pressure (i.e., elevated relative to atmospheric temperatures and pressures).

One or more vessel walls 31 separate the chamber 32 from the vessel exterior 39. The reaction vessel 30 can feature either a unitary or multi-piece design. For example, as shown in FIG. 1 the reaction vessel 30 is a multi-piece vessel assembled using one or more fastener systems such as one or more flanges 36, threaded fasteners 37, and sealing members 38.

The mechanically fluidized bed apparatus 10 may be positioned in the chamber 32 in the reaction vessel 30. The system 100 further includes a transmission system 50, a gas supply system 70, a particle supply system 90, a gas recovery system 110, a coated particle collection system 130, an inert gas feed system 150, and a pressure system 170. The system 100 may also include an automated or semi-automated control system 190 that is communicably coupled to the various components and systems forming the system. For clarity, the communicative coupling of various components to the control system 190 is depicted using a dashed line and “©” symbol. Each of these structures, systems or systems is discussed in subsequent detail below.

During operation, the chamber 32 within the reaction vessel 30 is maintained at one or more controlled temperatures and/or pressures that are usually greater than the temperature and pressure found in the ambient environment 39 surrounding the vessel 30. Thus, the vessel wall 31 is of suitable material, design, and construction with adequate safety margins to withstand the expected working pressures and temperatures within the chamber 32, which may include repeated pressure and thermal cycling of the reaction vessel 30. Additionally, the overall shape of the reaction vessel 30 may be selected or designed to withstand such expected working pressures or to accommodate a preferred particle bed 20 configuration or geometry. In at least some instances, the reaction vessel 30 may be fabricated in conformance with the American Society of Mechanical Engineers (ASME) Section VIII code (latest version) covering the construction of pressure vessels. In some instances, the design and construction of the reaction vessel 30 may accommodate the partial or complete disassembly of the vessel for operation, inspection, maintenance, or repair. Such disassembly may be facilitated by the use of threaded or flanged connections on the reaction vessel 30 itself or the fluid connections made to the reaction vessel 30.

The reaction vessel 30 may optionally include one or more cooling features 35 physically and/or thermally coupled to all or a portion of an exterior surface of the vessel wall 31. Such cooling features 35 may be disposed at any location on the exterior surface of the reaction vessel 30 including the reaction vessel top, bottom, and/or sides. In some instances, the cooling features 35 may include passive cooling features such as extended surface area fins thermally conductively coupled to all or a portion of the exterior surface of the reaction vessel 30. In some instances, the cooling features 35 may include active cooling features such as a jacket and/or cooling coils through which a heat transfer media (e.g., thermal oil, boiler feed water) is circulated. In some instances, the cooling features 35, such as cooling jackets and/or cooling coils may be disposed at least partially within the chamber 32. In some instances, the cooling features 35 may be integral with the vessel wall 31 or may be thermally conductively coupled to the vessel wall 31.

Although depicted in FIG. 1 as a series of cooling fins (only a few shown) providing an extended surface area for convective heat dissipation to the ambient environment 39, such cooling features 35 may also include other passive or active thermal systems, devices, or combinations of systems and devices that aid in the addition or the removal of thermal energy from the upper chamber 33, the lower chamber 34, or both the upper and the lower chambers. Such cooling systems and devices may include active thermal transfer systems or devices such as cooling jackets having one or more heat transfer fluids circulated therein, or various combinations of surface features and cooling jackets.

One or more cooling features 35 may beneficially maintain a temperature in at least the upper chamber 33 below the thermal decomposition temperature of the first gaseous chemical species. In some instances, the cooling features 35 may be selectively disposed on portions of the chamber 32 or the reaction vessel 30 that are prone to localized concentrations of thermal energy to assist in the dissipation or distribution of such thermal energy. By maintaining the temperature in the upper chamber 33 below the thermal decomposition temperature of the first gaseous chemical species, spontaneous decomposition of the first gaseous chemical species in locations external to the mechanically fluidized bed 20 is advantageously minimized or even eliminated.

One or more cooling features 35 may maintain a temperature at some or all points in the upper chamber 33 external to the mechanically fluidized particulate bed 20 that is below a thermal decomposition temperature of the first gaseous chemical species. By maintaining the temperature below the thermal decomposition temperature of the first gaseous chemical species in the upper chamber external to the mechanically fluidized particulate bed 20, decomposition of the first gaseous chemical species and subsequent deposition of the second chemical species on surfaces external to the mechanically fluidized particulate bed 20 and/or the formation of second chemical species “dust” in the upper chamber 33 is beneficially reduced or even eliminated.

One or more cooling features 35 may maintain a temperature in the lower chamber 34 below the thermal decomposition temperature of the first gaseous chemical species. Additionally or alternatively, one or more passive or active cooling features 57 may be thermally and/or physically coupled to the transmission system 50 to maintain the temperature of the oscillatory transmission member at or below the thermal decomposition temperature of the first gaseous chemical species.

It is believed that one or more alloys (e.g., an alloy of molybdenum and Super Invar) may exist that is similar to, or ideally match, the thermal expansion coefficient of silicon, or silicon carbide, or silicon nitride, or fused quartz. Such alloys may provide a suitable substrate for a liner material suitable for use on at least a portion of the interior surfaces of the reactor 30, pan 12 and/or coated particle overflow conduit 132. In one instance, it is believed at least a portion of at least the upper chamber 33 of the reactor 30 may be formed from such an alloy and a quartz liner may be spray fused to at least a portion of such surfaces. Such construction would advantageously minimize the likelihood of the quartz liner spalling from the surfaces in the upper chamber 33 of the reactor 30 when the reactor is cycled between room temperature and operating temperature.

The mechanically fluidized bed apparatus 10 includes at least one pan 12 having a bottom (i.e., a major horizontal surface) that supports the mechanically fluidized particulate bed 20 and defines at least one boundary of a retainment volume that retains the mechanically fluidized particulate bed 20. The bottom or major horizontal surface of the pan 12 includes at least an upper surface 12a, a lower surface 12b. The bottom of the pan 12 can include an integral, unitary, and single piece surface that is continuous without penetrations and/or apertures. In some instances, the bottom of the pan 12 may be formed integral with the remaining portion of the pan 12. In other instances, all or a portion of the bottom of the pan 12 may be selectively removable from the pan 12, thereby facilitating the repair, rejuvenation, or replacement of a worn pan bottom and/or providing access to one or more thermal energy emitting devices 14 positioned proximate and beneath the bottom of the pan 12.

The pan 12 further includes a perimeter wall 12c that extends at an upward angle from a peripheral edge or periphery of the bottom of the pan 12. The perimeter wall 12c defines at least a portion of at least one boundary of the retainment volume that retains the mechanically fluidized particulate bed 20. At times, the perimeter wall 12c extends about only a portion of the periphery of the bottom of the pan 12. At times, the perimeter wall 12c extends about the entire periphery of the bottom of the pan 12. In some implementations, the bottom and the perimeter wall 12c of the pan 12 form at least a portion of an open-topped retainment volume that retains or otherwise confines the mechanically fluidized particulate bed 20.

The perimeter wall 12c of the pan 12 may extend a fixed height above the bottom of the pan 12 for the entire length of the perimeter wall 12c. At other times, the perimeter wall 12c of the pan 12 may extend a first fixed height above the bottom of the pan 12 for a first portion of the length of the perimeter wall 12c and a second fixed height above the bottom of the pan 12 for a second portion of the length of the perimeter wall 12c. In some instances, all or a portion of the perimeter wall 12c may include a notch, weir, or similar aperture that permits removal of coated particles 22 from the mechanically fluidized particulate bed 20 via overflow.

In operation, the retention volume within the pan 12 retains the mechanically fluidized particulate bed 20. Where coated particles 22 overflow the perimeter wall 12c of the pan 12, the height of the lowest portion of the perimeter wall 12c determines the depth of the mechanically fluidized particulate bed 20. At times, the perimeter wall 12c extends at an upward angle of from about 30° to about 90° from the upper surface of the pan 12a.

In some implementations, the height of the perimeter wall 12c is the same as or slightly lower than the depth of the mechanically fluidized particulate bed 20 such that, in operation, at least some of the plurality of coated particles 22 carried on the surface of the mechanically fluidized particulate bed 20 overflow the perimeter wall 12c for capture by the coated particle removal system 130. In such implementations, the coated particle removal system 130 includes one or more collection devices, for example one or more funnel-shaped coated particle diverters positioned proximate and beneath the pan 12 to catch coated particles 22 overflowing the perimeter wall 12c of the pan 12.

In other implementations, the height of the perimeter wall 12c is greater than the depth of the mechanically fluidized particulate bed 20 such that, in operation, the entirety of the mechanically fluidized particulate bed 20 is retained internal to the retainment volume and proximate the upper surface 12a of pan 12. In such implementations the coated particle removal system 130 includes one or more open-ended, hollow, coated particle overflow conduits 132 positioned in the retainment volume. Coated particles 22 overflow from the surface of the mechanically fluidized particulate bed 20 into the open end of the one or more coated particle overflow conduits 132. In some implementations, the coated particle overflow conduits 132 may be sealed via one or more sealing devices 133, such as one or more O-Rings or one or more mechanical seals. In such implementations, the perimeter wall 12c can extend above the upper surface of the mechanically fluidized particulate bed 20 (and the open end of the coated particle overflow conduit 132) by a distance of from about 0.125 inches (3 mm) to about 12 inches (30 cm); from about 0.125 inches (3 mm) to about 10 inches (25 cm); from about 0.125 inches (3 mm) to about 8 inches (20 cm); from about 0.125 inches (3 mm) to about 6 inches (15 cm); or from about 0.125 inches (3 mm) to about 3 inches (7.5 cm).

The pan 12 can have any shape or geometric configuration, including but not limited to: circular, oval, trapezoidal, polygonal, triangular, rectangular, square, or combinations thereof. For example, the pan 12 may have a generally circular shape with a diameter of from about 1 inch (2.5 cm) to about 120 inches (300 cm); from about 1 inch (2.5 cm) to about 96 inches (245 cm); from about 1 inch (2.5 cm) to about 72 inches (180 cm); from about 1 inch (2.5 cm) to about 48 inches (120 cm); from about 1 inch (2.5 cm) to about 24 inches (60 cm); or from about 1 inch (2.5 cm) to about 12 inches (30 cm).

The portions of the pan 12 contacting the mechanically fluidized particulate bed 20 are formed of an abrasion or erosion resistant material that is also resistant to chemical degradation by the first chemical species, the diluent(s), and the coated particles in the particulate bed 20. Use of a pan 12 having appropriate physical and chemical resistance reduces the likelihood of contamination of the fluidized particulate bed 20 by contaminants released from the pan 12. In some instances, the pan 12 can comprise an alloy such as a graphite alloy, a nickel alloy, a stainless steel alloy, or combinations thereof. In some instances, the pan 12 can comprise molybdenum or a molybdenum alloy.

In some applications, the pan 12 may include one or more layers or coatings of one or more resilient materials that resist abrasion or erosion, reduce unwanted product buildup, and/or reduce the likelihood of contamination of the mechanically fluidized particulate bed 20. In some instances, all or a portion of the bottom of the pan 12 and/or the perimeter walls 12c of the pan, may comprise substantially pure silicon (e.g., high purity silicon that is in excess of 99% silicon, 99.5% silicon, or 99.9% silicon). In at least some implementations, the substantially pure silicon layer can have at least one of: a uniform thickness or a uniform density. While the second chemical species may be deposited as a consequence of the decomposition of the first gaseous chemical species, it should be understood that the silicon comprising the bottom of the pan is present prior to the first use of the pan 12, in other words, the silicon comprising the pan 12 is different from the non-volatile second chemical species created by the thermal decomposition of the first gaseous chemical species in the mechanically fluidized particulate bed 20.

In some instances; the layer or coating in all or a portion of the pan 12 can include but is not limited to: a graphite layer, a quartz layer, a silicide layer, a silicon nitride layer, or a silicon carbide layer. In some instances, a metal silicide may be formed in situ by reaction of silane with iron, nickel, molybdenum, and other metals in the pan 12. A silicon carbide layer, for example, is durable and reduces the tendency of metal ions such as nickel, chrome, and iron from the metal comprising the pan to migrate into, and potentially contaminate, the plurality of coated particles 22 in the pan 12. In one example, the pan 12 comprises a 316 stainless steel pan with a silicon carbide layer deposited on at least a portion of the upper surface 12a of the bottom of the pan 12 and at least the portions perimeter wall 12c contacting the mechanically fluidized particulate bed 20.

In operation, one or more thermal energy emission devices 14 increase the temperature of the mechanically fluidized particulate bed 20 to a level in excess of the thermal decomposition temperature of the first gaseous chemical species at the operating pressure of the reactor. Heating the mechanically fluidized particulate bed 20 to a temperature in excess of thermal decomposition temperature of the first gaseous chemical species beneficially causes the preferential thermal decomposition of the first gaseous chemical species in the mechanically fluidized particulate bed 20 rather than in other locations within the reactor. Maintaining temperatures external to the mechanically fluidized particulate bed 20 below the thermal decomposition temperature of the first gaseous chemical species further reduces the likelihood of thermal decomposition of the first gaseous chemical species at locations in the reactor outside of the mechanically fluidized particulate bed 20. The thermal decomposition of the first gaseous chemical species (e.g., silane, dichlorosilane, trichlorosilane) causes deposition of a non-volatile second chemical species (e.g., silicon, polysilicon) on at least a portion of the plurality of particulates in the mechanically fluidized particulate bed 20 to provide the plurality of coated particles 22. The coated particles 22 circulate freely in the mechanically fluidized particulate bed 20 and, somewhat surprisingly, tend to rise within and “float” on the surface of the mechanically fluidized particulate bed 20. Such behavior allows for the selective separation and removal of coated particles 22 from the mechanically fluidized particulate bed 20.

At times, the gas within the chamber 32 is maintained at a low oxygen level (e.g., less than 20 volume percent oxygen) or at a very low oxygen level (e.g., less than 0.001 mole percent oxygen to less than 1 mole percent oxygen). Coated particles 22 in the chamber 32 are maintained in an environment having a low oxygen level (e.g., less than 20 volume percent oxygen) or a very low oxygen level (e.g., less than 1 mole percent oxygen to less than 0.001 mole percent oxygen) to reduce detrimental oxide formation on the exposed surfaces of the coated particles. In some instances, the gas within the chamber 32 is maintained at a low oxygen content that does not expose the coated particles 22 to atmospheric oxygen levels. In some instances, the gas within the chamber 32 is maintained at a low oxygen level of less than 20 volume percent (vol %). In some instances, the gas within the chamber 32 is maintained at a very low oxygen level of less than about 1 mole % (mol %) oxygen; less than about 0.5 mol % oxygen; less than about 0.3 mol % oxygen; less than about 0.1 mol % oxygen; less than about 0.01 mol % oxygen; or less than about 0.001 mol % oxygen.

By controlling the oxygen level in the chamber 32, oxide formation on exposed surfaces of the coated particles 22 is beneficially minimized, reduced, or even eliminated. For example, the formation of silicon oxides (e.g., silicon oxide, silicon dioxide) on the exposed surfaces of the silicon coated particles 22 is advantageously minimized, reduced, or even eliminated. In such an example, the silicon coated particles 22 can have a silicon oxides content of less than about 500 parts per million by weight (ppmw); less than about 100 ppmw; less than about 50 ppmw; less than about 10 ppmw; or less than about 1 ppmw.

At times, the one or more thermal energy emission devices 14 may be disposed proximate the lower surface of the bottom of the pan 12. For example, the one or more thermal energy emission devices may be disposed internal to the bottom of the pan 12. In other instances, the one or more thermal energy emission devices may be disposed proximate the lower surface of the bottom of the pan 12 in a sealed container or covered in an insulative blanket or similar insulative material. The thermally insulating material 16 or insulative blanket may be deposited about all sides of the one or more thermal energy emission devices 14 except for the portion of the one or more thermal energy emission devices 14 forming a portion of the pan 12. The thermally insulating material 16 may, for instance be a glass-ceramic material (e.g., Li₂O×Al₂O₃×nSiO₂-System or LAS System) similar that used in “glass top” stoves where the electrical heating elements are positioned beneath a glass-ceramic cooking surface. In some situations, the thermally insulating material 16 may include one or more rigid or semi-rigid refractory type materials such as calcium silicate.

Each of the plurality of coated particles 22 includes deposits or layers that include substantially pure second chemical species. At times, the coated particles 22 display morphology similar to an agglomeration of smaller second chemical species sub-particles. As mentioned previously, it has been observationally noted that the plurality of coated particles 22 tend to rise through and “float” on the surface of the mechanically fluidized particulate bed 20, particularly as the diameter of the coated particle increases.

Some or all of the plurality of coated particles 22 may be removed or extracted from the mechanically fluidized particulate bed 20 via overflow. In some instances, such coated particles 22 may overflow all or a portion of the perimeter wall 12c of the pan 12. In other instances, such coated particles 22 may overflow into one or more open-ended, hollow, coated particle overflow conduits 132 positioned at one or more defined locations in the pan 12 and projecting a defined distance above the upper surface 12a of the bottom of the pan 12. Regardless of the removal mechanism, the coated particle collection system 130 collects the plurality of coated particles 22 separated from the mechanically fluidized particulate bed 20. Collection of the coated particles 22 in the coated particle collection system 130 occurs continuously, intermittently, and/or periodically.

The one or more thermal energy emission devices 14 provide thermal energy to the mechanically fluidized particulate bed 20 sufficient to increase the temperature in the mechanically fluidized particulate bed 20 above the thermal decomposition temperature of the first gaseous chemical species. In some instances, the thermal energy emission devices 14 transfer thermal energy to the mechanically fluidized particulate bed 20 via conductive heat transfer, convective heat transfer, radiant heat transfer, or combinations thereof. In one instance, the one or more thermal energy emission devices 14 can be disposed proximate at least a portion of the pan 12, for example proximate all or a portion of the bottom of the pan 12. At times, the one or more thermal energy emission devices 14 used to increase the temperature of the mechanically fluidized particulate bed 20 above the thermal decomposition temperature of the first gaseous chemical species can include one or more resistive heaters, one or more radiant heaters, one or more convective heaters or combinations thereof. At times, the one or more thermal energy emission devices 14 may include one or more circulated heat transfer systems, for example one or more molten salt or thermal oil based heat transfer systems.

A transmission system 50 is physically and operably coupled to the pan 12 via one or more oscillatory transmission members 52. Although the oscillatory transmission member 52 is shown attached to the bottom surface of the pan 12 in FIG. 1, the oscillatory transmission member 52 may be operably coupled to any surface of the pan 12. One or more stiffening members 15 may be disposed about the lower surface 12b or about other surfaces of the pan 12 to increase rigidity and reduce operational flexing of the pan 12. In some instances, the one or more stiffening members 15 may be disposed on the upper surface of the pan 12a to improve the rigidity of the pan 12, or to improve the fluidization or flow characteristics of the mechanically fluidized particulate bed 20.

In at least some implementations, one or more thermal energy transfer devices 57 may be physically and/or thermally coupled to the transmission member 52 to transfer thermal energy from the transmission member 52. In some instances, the one or more thermal energy transfer devices 57 can include one or more passive thermal energy transfer devices, for example, one or more extended surface area heat sinks. In some instances, the one or more thermal energy transfer devices 57 can include one or more active thermal energy transfer devices, for example one or more coils and/or jackets through which a heat transfer media circulates.

The transmission system 50 is used to oscillate or vibrate the pan 12 along the one or more axes of motion 54a-54n (collectively, “one or more axes of motion 54”). FIG. 1 depicts a single axis of motion 54a that is perpendicular to the upper surface 12a of the bottom of the pan 12. The transmission system 50 includes any system, device, or any combination of systems and devices capable of providing an oscillatory or vibratory displacement of the pan 12 along the one or more axes of motion 54. In at least some instances, the one or more axes of motion 54 include a single axis that is normal (i.e., perpendicular) to the upper surface of the bottom of pan 12. The transmission system 50 can include at least one electrical system, mechanical system, electromechanical system, or combinations thereof capable of oscillating or vibrating the pan 12 along the one or more axes of motion 54. One or more bushings 56a, 56b (collectively, “bushings 56”) substantially align the vibratory or oscillatory motion of the pan 12 along the one or more axes of motion 54.

At times, the bushings 56 also restrict, constrain, or otherwise limit the uncontrolled or unintended displacement of the pan 12 either laterally or in other directions that are not aligned with the one or more axes of motion 54. Maintaining the vibratory or oscillatory motion of the pan 12 in substantial alignment with the one or more axes of motion 54 advantageously reduces the likelihood of forming of “fines” within the mechanically fluidized particulate bed 20. Additionally, maintaining the vibratory or oscillatory motion of the pan 12 in substantial alignment with the one or more axes of motion 54 advantageously increases the uniformity of coated particle distribution in the pan 12, thereby improving the overall conversion, yield, or particle size distribution within the particulate bed 20. Limiting the formation of ultra-small particles within the mechanically fluidized particulate bed 20 increases the overall yield of the second chemical species by increasing the available quantity of first chemical species for deposition on the particulates in the mechanically fluidized particulate bed 20. As used in this context, “ultra-small particles” represent those particles having physical properties such that they are removed from the mechanically fluidized particulate bed 20 by entrainment in the exhaust gas exiting the bed. Such “ultra-small particles” may have diameters, for example, of less than about 1 micron or less than about 5 microns.

The first bushing 56a is disposed about the oscillatory transmission member 52 and includes an aperture through which the oscillatory transmission member 52 passes. In some instances, the first bushing 56a may be disposed about the oscillatory transmission member 52 proximate the vessel wall 31, In other instances the first bushing 56a may be disposed about the oscillatory transmission member 52 remote from the vessel wall 31.

In some instances, a second bushing 56b is disposed along the one or more axes of motion 54 at a location remote from the first bushing 56a. The second bushing 56b also includes an aperture through which the oscillatory transmission member 52 passes. Such a spaced arrangement of the bushings 56 with passages aligned along the one or more axes of motion 54 assists in maintaining the alignment of the oscillatory transmission member 52 along the one or more axes of motion 54. Further, the spaced arrangement of the bushings 56 also advantageously limits or constrains the motion or displacement of the oscillatory transmission member 52 in directions other than the one or more axes of motion 54.

Any number of electrical, mechanical, electromagnetic, or electromechanical drivers 58 can be operably coupled to the oscillatory transmission member 52. In at least some situations, the driver can include an electromechanical system comprising a prime mover such as a motor 58, coupled to a cam 60 or similar device that is capable of providing a regular, repeatable, oscillatory or vibratory motion via a linkage 62 to the oscillatory transmission member 52. The transmission member 52 communicates the oscillatory or vibratory motion to the pan 12 via one or more couplings linking the oscillatory transmission member 52 to the pan 12.

In one illustrative embodiment, the one or more permanent magnets may be coupled or otherwise physically affixed to the pan 12. One or more electromagnetic force producing drivers may be disposed external to the reactor 30. The changes in the electromagnetic force producing drivers positioned external to the reactor 30 may cause a cyclical displacement of the magnets coupled to the pan 12 thereby oscillating the pan and fluidizing the particulate bed 20 thereupon.

The oscillation or vibration of the pan 12 along the one or more axes of motion 54 may occur at one or at any number of frequencies and have any displacement. At times, the pan 12 oscillates or vibrates at a first frequency for a first interval and at a second frequency for a second interval. In some instances, the second frequency may be 0 Hz (i.e., no oscillatory motion) thereby creating a cycle where the pan 12 is oscillated at the first frequency for the first interval and remains stationary for the second interval. The first interval can have any duration and may be shorter or longer than the second interval. In at least some instances, the pan 12 can have a frequency of oscillation or vibration of from about 1 cycle per second (Hz) to about 4,000 Hz; about 500 Hz to about 3,500 Hz; or about 1,000 Hz to about 3,000 Hz.

The oscillatory or vibratory magnitude and direction of the pan 12 may, at times, lie along a single axis of motion 54a, for example an axis that is substantially normal (i.e., perpendicular) to the upper surface 12a of the bottom of the pan 12. At other times, the oscillatory or vibratory magnitude and direction of the pan 12 may include components that lie along two orthogonal axes of motion 54a, 54b. For example, the oscillatory or vibratory magnitude and direction of the pan 12 may include a first component in a direction along the first axis of motion 54a and having a magnitude normal to the upper surface of the bottom of the pan 12 (i.e., a vertical component) and a second component in a direction along the second axis of motion 54b (not shown in FIG. 1) and having a magnitude parallel to the upper surface of the bottom of the pan 12 (i.e., a horizontal component). At times, a horizontal component that is lesser in magnitude than the vertical component has been found to advantageously assist in the selective removal of coated particles from the mechanically fluidized particulate bed 20.

Further, the magnitude of the oscillatory or vibratory displacement of the pan 12 along the one or more axes of motion 54 may be fixed or varied based at least in part upon the desired properties of the second chemical species coating the particles in the mechanically fluidized particulate bed 20. In at least some instances, the pan 12 can have an oscillatory or vibratory displacement of from about 0.01 inches (0.3 mm) to about 2.0 inches (50 mm); 0.01 inches (0.3 mm) to about 0.5 inches (12 mm); or from about 0.015 inches (0.4 mm) to about 0.25 inches (6 mm); or from about 0.03 inches (0.8 mm) to about 0.125 inches (3 mm). In at least one implementation, the displacement of the pan 12 may be about 0.1 inches. In at least some instances, either or both the frequency of the oscillation or vibration of the pan 12 or the oscillatory or vibratory displacement of the pan 12 may be continuously adjustable over one or more ranges or values, for example using the control system 190. Altering or adjusting the frequency or displacement of the oscillation or vibration of the pan 12 can provide conditions conducive to the deposition of a second chemical species having a preferred depth, structure, composition, or other physical or chemical properties, on the surface of the particles in the mechanically fluidized particulate bed 20.

In some instances, a bellows or boot 64 is disposed about the oscillatory transmission member 52. In some instances, an internal gas seal 65 may be disposed about the oscillatory transmission member 52. The boot 64 can be fluidly coupled to the vessel 30, for example at the vessel wall 31, the oscillatory transmission member 52, or both the vessel 30 and the oscillatory transmission member 52. The boot 64 isolates the lower portion of the chamber 34 from exposure to the external environment 39 about the vessel 30. In some instances, the boot 64 can be replaced or augmented using a shaft seal 65 to prevent the emission of gas from the lower portion of the chamber 34 to the external environment 39. The boot 64 provides a secondary sealing member (in addition to the flexible membrane 42 and shaft seal 65) that prevents the escape of the gas containing the first chemical species to the external environment 39. In some instances, the first chemical species can include silane which is pyrophoric at atmospheric oxygen levels such as those typically found in the external environment 39. In such an instance, the second seal provided by the boot 64 can minimize the likelihood of a leak to the external environment even in the event of a failure of the flexible membrane 42 and shaft seal 65.

In some instances, the boot 64 can include a bellows-type seal or a similar flexibly pleated membrane-like structure. In other instances, the boot 64 can include an elastomeric flexible-type coupling or similar elastomeric membrane-like structure. A first end of the boot 64 may be temporarily or permanently affixed, attached, or otherwise bonded to the exterior surface of the vessel wall 31 and the second end of the boot 64 may be similarly temporarily or permanently affixed, attached, or otherwise bonded to a ring 66 or similar structure on the oscillatory transmission member 52. At times, one or more gas detection devices responsive to the first gaseous chemical species (not shown in FIG. 1) may be disposed at a location internal to the lower chamber 34 or at a location external to the boot 64 to detect leakage of the first gaseous chemical species from the upper chamber 33 of the reaction vessel 30.

To improve the permeation of the first gaseous chemical species into the particulate bed 20, the particulate bed 20 is mechanically fluidized to increase the volume of the bed and increase the distance between the particles (i.e., the number or size of the interstitial voids between the particulates) forming the mechanically fluidized particulate bed 20. Additionally, the mechanical fluidization of the particulate bed 20 causes the particulates within the bed to flow and circulate throughout the bed, thereby drawing the first gaseous chemical species throughout the bed and hastening the permeation and mixing of the first chemical species with the plurality of particulates forming the mechanically fluidized particulate bed 20. The intimate contact achieved between the first gaseous chemical species and the heated particulates forming the mechanically fluidized particulate bed 20 results in the thermal decomposition of at least a portion of the first gaseous chemical species within the mechanically fluidized particulate bed 20. The intimate proximity of the first gaseous chemical species to the particulate bed 20 causes at least a portion of the non-volatile second chemical species to deposit on the exterior surface of the particles forming the mechanically fluidized particulate bed 20. Further, the fluid nature of the fluidized particulate bed 20 permits gaseous byproducts (e.g., a third gaseous chemical species such as hydrogen) to escape from the particulate bed 20.

An initial charge of small diameter “seed particulates” are initially added to the pan 12 to form the plurality of particulates on which the second chemical species deposits. In operation, additional fine particulates, or “fines,” may be formed within the particulate bed 20 by the abrasion and fracturing of the particles in the particulate bed 20 and/or spontaneous self-nucleation of the second chemical species (e.g., polysilicon seeds) from the first gaseous chemical species. At times, such autonomously or spontaneously formed particulate “fines” are sufficient to replace the particulate volume lost from the mechanically fluidized particulate bed 20 in the form of coated particles 22.

At times, it is particularly advantageous to retain the particulate fines generated by spontaneous self-nucleation and physical abrasion within the mechanically fluidized particulate bed 20 to provide additional second chemical species deposition sites and/or to reduce dust formation within the housing 30. The retention of such small diameter particulate fines in the mechanically fluidized particulate bed 20 is attributable, in whole or in part, to the relatively low first gaseous chemical species flow rate or flow velocity through the mechanically fluidized particulate bed 20. The retention of smaller diameter fine particulates in the mechanically fluidized particulate bed 20 can beneficially minimize, reduce, or even eliminate the need to feed seed particulates from an external source such as the particulate feed system 90.

Since traditional hydraulically fluidized particulate beds rely upon relatively high superficial gas flow rates or velocities to suspend the particulates and create the fluidized bed, the low gas velocities possible in a mechanically fluidized particulate bed 20 are simply not possible. Thus a mechanically fluidized particulate bed 20 can provide a significant advantage over hydraulically fluidized beds by retaining small diameter particulate fines. For example, a mechanically fluidized particulate bed 20 may retain particulate fines having particulate diameters as small as 1 micrometer (μm); 5 μm; 10 μm; 20 μm; 30 μm; 50 μm; 70 μm; 80 μm; 90 μm; or 100 μm; while a hydraulically fluidized particulate bed may only retain particulates having particulate diameters in excess of 100 μm; 150 μm; 200 μm; 250 μm; 300 μm; 350 μm; 400 μm; 450 μm; 500 μm; or 600 μm.

At other times, spontaneous self-nucleation of particulates in the mechanically fluidized particulate bed 20 may be insufficient to make-up for the particulates lost in the plurality of coated particles 22. In such instances, the particle supply system 90 may provide additional, new, particulates to the mechanically fluidized particulate bed 20 on a periodic, intermittent, or continuous basis.

Sometimes, it is advantageous to remove at least a portion of very fine particulates, for example those whose diameter is smaller than 10 micrometers (μm), from the mechanically fluidized bed reactor 10. Such particulate fine removal may be at least partially accomplished, for example, by removing and filtering at least a portion of the gas present in the upper portion 33 of the chamber 32 on an intermittent, periodic, or continuous basis. Such removal may also be at least partially accomplished, for example, by filtering at least a portion of the exhaust gas removed from the upper portion 33 of the chamber 32. Selective removal from system 100 of fines, for example based on particulate, particle, or fine diameter, may be accomplished by filtration of the gas mixture or the exhaust gas. The selective presence of fines in the exhaust gas removed from the upper chamber 33 of the reactor 30 may be caused by selective entrainment of the fines in the off-gas exiting the mechanically fluidized particulate bed 20. For example, by controlling the velocity of the off-gas exiting the mechanically fluidized bed 20, fines having a particular range of diameters may be selectively removed from the mechanically fluidized particulate bed 20 and carried, entrained in the off-gas exiting the mechanically fluidized particulate bed 20 into the upper portion 33 of the chamber 32. For example, increasing the off-gas velocity from the mechanically fluidized particulate bed 20 tends to entrain and remove larger diameter fine particles from the mechanically fluidized particulate bed 20. Conversely, decreasing the off-gas velocity from the mechanically fluidized particulate bed 20 tends to entrain and remove smaller diameter fine particles from the mechanically fluidized particulate bed 20.

Product in the form of the plurality of coated particles 22 is removed periodically, intermittently, or continuously from the mechanically fluidized particulate bed 20. At times such coated particles 22 are selectively removed from the mechanically fluidized particulate bed 20 based on one or more physical properties, such as a coated particles 22 having a diameter in excess of a defined value (e.g., greater than about 100 micrometers (μm): greater than about 500 micrometers (μm); greater than about 1000 micrometers (μm); greater than about 1500 micrometers (μm)). In other instances, a physical property such as coated particle density may be used to selectively remove the coated particles 22 from the mechanically fluidized particulate bed 20.

As mentioned above, somewhat unexpectedly, coated particles 22 having a larger diameter (i.e., those having greater deposits of the second chemical species) tend to “rise” within the bed 20 and “float” on the surface of the mechanically fluidized particulate bed 20 while particulates having a smaller diameter (i.e., those having lesser deposits of the second chemical species) tend to “sink” and are consequently retained within the bed 20. In some instances, this effect can be enhanced by placing an electrostatic charge on all or a portion of the pan 12 to attract the smaller particulates towards the pan 12 and thus to the bottom of the bed 20. Attracting smaller particulates to the bottom of the pan beneficially retains smaller particles or fines within the bed 20 and reduces the transfer of fine particulates from the mechanically fluidized particulate bed 20 to the upper chamber 33.

A partitioning system 40 partitions the chamber 32 into the upper portion 33 and the lower portion 34. The partitioning system 40 includes a flexible member 42 that is physically affixed, attached, or coupled 44 to the pan 12 and physically affixed, attached or coupled 46 to the reaction vessel 30. In at least some implementations, the flexible member 42 hermetically seals the upper chamber 33 from the lower chamber 34. The flexible member 42 apportions the chamber 32 such that the upper surface of the pan 12a is exposed to the upper portion of the chamber 33 and not to the lower portion of the chamber 34. Similarly, the lower surface of the pan 12b is exposed to the lower portion of the chamber 34 and not to the upper portion of the chamber 33.

To accommodate the relative motion between the pan 12 and the reaction vessel 30, the flexible member 42 can include a material or be of a geometry and/or construction able to withstand the potentially extended and repeated oscillation or vibration of the pan 12 along the one or more axes of motion 54. In some instances, the flexible member 42 can be of a bellows type construction that accommodates the displacement of the pan 12 along the one or more axes of 54. In other instances, the flexible member 42 can include a “boot” or similar flexible coupling or membrane that incorporates or includes a resilient material that is both chemically and thermally resistant to the physical and chemical environment in both the upper 33 and lower 34 portions of the chamber 32. In some implementations, the flexible member 42 can be insulated to retain heat within the upper chamber 33 and/or to limit the transfer of heat from the upper chamber 33 to the lower chamber 34. The insulation is on the 34 side of the flexible member 42. In at least some implementations, the insulation is on the side of the flexible member 42 exposed to the lower chamber 34. Such positioning advantageously precludes contamination of the mechanically fluidized particulate bed 20 by the insulation.

In at least some instances, the flexible member 42 may be in whole or in part a flexible metallic member, for example a flexible 316SS member. In at least some embodiments, the physical coupling 46 of the flexible member 44 to the reaction vessel 30 may include a flange or similar structure adapted for insertion between two or more reaction vessel 30 mating surfaces, for example between the flanges 36 as shown in FIG. 1. The physical coupling 44 between the flexible membrane 42 and the pan 12 can be made along one or more of: the upper surface of the pan 12a, the lower surface of the pan 12b, or the perimeter wall of the pan 12c. In some instances, all or a portion of the flexible member 42 may be integrally formed with at least a portion of the pan 12 or at least a portion of the reaction vessel 30. In some instances, where some or all of the flexible member 42 comprises a metallic member, the flexible membrane 42 may be welded or similarly thermally bonded to the pan 12, the vessel 30, or both the pan 12 and the vessel 30.

Gases, including the first gaseous chemical species and, optionally, one or more diluent(s) may be added to the upper chamber 33 either individually or as a bulk gas mixture. In some instances, only the first gaseous chemical species is added to the upper chamber 33. In some instances, some or all of the first gaseous chemical species and some or all of any optional diluents are added via a fluid conduit 84 that fluidly couples the upper chamber 33 to the first gaseous chemical species feed system 72 and to the one or more diluent(s) feed systems 78. At times, the first gaseous chemical species and the optional diluent are mixed and supplied via the fluid conduit 84 to the upper portion of the chamber 33 as a bulk gas mixture by the gas supply system 70.

Although depicted as feeding from above the mechanically fluidized particulate bed 20 through the upper chamber 33, the fluid conduit 84 may also feed from below the mechanically fluidized particulate bed 20 passing through the lower chamber 34. Feeding the first gaseous chemical species and the one or more diluent(s) from below, through the lower chamber 34, may advantageously permit the passage of the first gaseous chemical species via the fluid conduit 84 through the relatively low temperature lower chamber 84. Passing the first gaseous chemical species through the relatively low temperature lower chamber beneficially reduces the likelihood of thermal decomposition of the first gaseous chemical species outside of the mechanically fluidized particulate bed 20.

The bulk gas mixture supplied to the upper portion of the chamber 33 produce a pressure that is measurable, for example using a pressure transmitter 176. If pressure were permitted to build within only the upper portion of the chamber 33 the amount of force required from the transmission system 50 to oscillate or vibrate the pan 12 along the one or more axes of motion 54 would increase as the pressure of the bulk gas mixture in the upper portion of the chamber 33 is increased due to the pressure exerted by the gas in the upper chamber 33 on the upper surface of the pan 12a. To reduce the force required to oscillate or vibrate the pan 12, an inert gas or inert gas mixture may be introduced to the lower portion of the chamber 34 using an inert gas supply system 150. Introducing an inert gas into the lower portion of the chamber 34 can reduce the pressure differential between the upper portion of the chamber 33 and the lower portion of the chamber 34. Reducing the pressure differential between the upper portion of the chamber 33 and the lower portion of the chamber 34 reduces the output force required from the transmission system 50 to oscillate or vibrate the pan 12.

The pan 12 oscillates or vibrates and mechanically fluidizes the plurality of particulates carried by the upper surface 12a of the bottom of the pan 12. The repetitive motion of the oscillatory transmission member 52 through the bushing 56a can create contaminants during normal operation. Such contaminants may include, inter alia, shavings from or pieces of the bushing 56a, metallic shavings from the oscillatory transmission member 52, and the like which may be expelled into the chamber 32. In the absence of the flexible member 44, such contaminants expelled into the chamber 32 may enter the mechanically fluidized particulate bed 20, potentially contaminating all or a portion of the plurality of coated particles 22 contained therein. The presence of the flexible member 44 therefore reduces the likelihood of contamination within the mechanically fluidized particulate bed 20 from metal or plastic shavings, lubricants, or similar debris or materials generated as a consequence of the routine operation of the transmission system 50.

The inert gas supply system 150 that is fluidly coupled to the lower chamber 34 can include an inert gas reservoir 152, any number of fluid conduits 154, and one or more inert gas final control elements 156, such as one or more flow or pressure control valves. The inert gas final control elements 156 are adjusted, controlled or otherwise modulated to maintain a desired inert gas pressure within the lower chamber 34. The one or more inert gas final control elements 156 can modulate, regulate, or otherwise control the admission rate or pressure of the inert gas in the lower portion of the chamber 34. The inert gas provided from the inert gas reservoir 152 can include one or more gases displaying non-reactive properties in the presence of the first chemical species. In some instances, the inert gas can include, but is not limited to, at least one of: argon, nitrogen, or helium. The inert gas introduced to the lower portion of the chamber 34 can be at a pressure of from about 5 psig to about 900 psig; from about 5 psig to about 600 psig; from about 5 psig to about 300 psig; from about 5 psig to about 200 psig; from about 5 psig to about 150 psig; or from about 5 psig to about 100 psig.

In some implementations, the pressure of the inert gas in the lower chamber 34 is greater than the pressure of the gas in the upper chamber 33. In various implementations, the control system 190 may maintain the gas pressure in the lower chamber 34 at a level greater than the gas pressure in the upper chamber 33, by about 10 inches of water or less (0.02 atm.); about 20 inches of water (0.04 atm.) or less; about 1.5 psig (0.1 atm.) differential or less; about 5 psig (0.3 atm.) differential or less; about 10 psig (0.7 atm.) differential or more; about 25 psig (1.7 atm.) differential or more; about 50 psig (3.4 atm.) differential or more; about 75 psig (5 atm.) differential or more; or about 100 psig (7 atm.) differential or more. In one specific embodiment, the pressure in the lower chamber 34 may be about 600 psig (40 atm.) and the pressure in the upper chamber 33 can be about 550 psig (37.5 atm.). By maintaining the pressure in the lower chamber 34 at a level greater than the pressure in the upper chamber 33, any breach of or leakage through the flexible membrane 42 will result in passage of the inert gas from the lower chamber 34 to the upper chamber 33.

In some instances, an analyzer or detector responsive to at least the inert gas in the lower chamber 34 may be placed in or fluidly coupled to the upper chamber 33. Detection of inert gas leakage to the upper chamber 33 can indicate a failure of the flexible member 42. Beneficially, the lower pressure of the gas in the upper chamber 33 prevents the escape of the potentially flammable first gaseous chemical species to the lower chamber 34. In some instances, an analyzer or detector responsive to the inert gas in the lower chamber 34 may be placed in the exterior environment 39 about the vessel 10 to detect an external leak of non-reactive gas from the lower chamber 34.

In other implementations, the pressure of the inert gas in the lower chamber 34 is less than the pressure of the gas in the upper chamber 33. In various implementations, the control system 190 may maintain the gas pressure in the upper chamber 33 at a level lower than the gas pressure in the lower chamber 34, by about 10 inches of water or less (0.02 atm.); about 20 inches of water (0.04 atm.) or less; about 1.5 psig (0.1 atm.) differential or less; about 5 psig (0.3 atm.) differential or less; about 10 psig (0.7 atm.) differential or less; about 25 psig (1.7 atm.) differential or less; about 50 psig (3.4 atm.) differential or less; about 75 psig (5 atm.) differential or less; or about 100 psig (7 atm.) differential or less. In one specific embodiment, the pressure in the lower chamber 34 may be about 600 psig (40 atm.) and the pressure in the upper chamber 33 can be about 550 psig (37.5 atm.). In an illustrative embodiment, the pressure in the lower chamber 34 may be about 600 psig (40 atm.) and the pressure in the upper chamber 33 can be about 550 psig (37.5 atm.). By maintaining the pressure in the upper chamber 33 at a level lower than the pressure in the lower chamber 34, any breach of or leakage through the flexible membrane 42 will result in passage of the gas from the lower chamber 34 to the upper chamber 33. By maintaining the upper chamber 33 at a lower pressure than the lower chamber 34 the reactive gas from the upper chamber 33 cannot enter the lower chamber with its moving parts and pressure sealing systems.

In some instances, an analyzer or detector responsive to at least the gas in the lower chamber 34 may be placed in or fluidly coupled to the upper chamber 33. Detection of gas leakage to the upper chamber 33 can indicate a failure of the flexible member 42. In some instances, an analyzer or detector responsive to at least the gas in the upper chamber 33 may be placed in or fluidly coupled to the lower chamber 34. Detection of gas leakage to the lower chamber 34 can indicate a failure of the flexible member 42. In some instances, an analyzer or detector responsive to the gas in the upper chamber 33 may be placed in the exterior environment 39 about the vessel 10 to detect an external leak of gas from the upper chamber 33.

One or more temperature transmitters 175 measure the temperature of the inert gas in the lower chamber 34. At times, the temperature of the inert gas in the lower chamber 34 may be maintained below the thermal decomposition temperature of the first gaseous chemical species. Maintaining the temperature of the inert gas below the thermal decomposition temperature of the first gaseous chemical species can advantageously reduce the likelihood of second chemical species deposition on the flexible member 44 since the relatively cool inert gas will tend to limit the buildup of heat within the flexible member 44 during routine operation of the system 100. Further, it prevents the seals on the drive mechanism from over-heating resulting in seal failure. The temperature of the inert gas in the lower section 34 can be controlled by means of cooling coils placed inside the lower section 34, cooled by a cooling medium. It can also be controlled by introducing the inert gas to the lower chamber 34 at a temperature of from about 25° C. to about 375° C.; from about 25° C. to about 300° C.; from about 25° C. to about 225° C.; from about 25° C. to about 150° C.; or from about 25° C. to about 75° C. At times, the inert gas introduced to the lower chamber 34 can be at a temperature of less than the thermal decomposition temperature of the first gaseous chemical species. At such times, the inert gas introduced to the lower chamber 34 can be at least about 100° C.; at least about 200° C.; at least about 300° C.; at least about 400° C.; at least about 500° C.; or at least about 550° C. below the thermal decomposition temperature of the first gaseous chemical species.

One or more temperature transmitters 180 measure the temperature of the gas in the upper chamber 33. At times, the temperature of the gas in the lower chamber 33 may be maintained below the thermal decomposition temperature of the first gaseous chemical species. Maintaining the temperature of the gas below the thermal decomposition temperature of the first gaseous chemical species can advantageously reduce the likelihood of second chemical species deposition on surfaces external to the mechanically fluidized bed 20 since the relatively cool gas will tend to limit surface temperatures within the upper chamber 33 during routine operation of the system 100. The temperature of the inert gas in the upper section 33 can be controlled by means of cooling coils placed inside the upper section 33, cooled by a cooling medium. It can also be cooled by means of cooling fins place on the external wall of vessel 30.

Gas in the upper chamber 33 can be at a temperature of from about 25° C. to about 500° C.; from about 25° C. to about 300° C.; from about 25° C. to about 225° C.; from about 25° C. to about 150° C.; or from about 25° C. to about 75° C. At times, the gas in the upper chamber 33 can be at a temperature of less than the thermal decomposition temperature of the first gaseous chemical species. At such times, the gas in the upper chamber 33 can be at least about 100° C.; at least about 200° C.; at least about 300° C.; at least about 400° C.; at least about 500° C.; or at least about 550° C. below the thermal decomposition temperature of the first gaseous chemical species.

One or more differential pressure measurement systems 170 monitor and if necessary, control the pressure differential between the upper chamber 33 and the lower chamber 34. At times, the differential pressure measurement systems 170 maintains the maximum differential pressure between the upper chamber 33 and the lower chamber 34 below the maximum working differential pressure of the flexible member 44. As discussed above, an excessive differential pressure between the upper chamber 33 and the lower chamber 34 can increase the force and consequently the power required to oscillate or vibrate the pan 12. The differential pressure system 170, including a lower chamber pressure sensor 171 and an upper chamber pressure sensor 172 coupled to a differential pressure transmitter 173 can be used to provide a process variable signal indicative of the pressure differential between the upper chamber 33 and the lower chamber 34. The differential pressure between the upper chamber 33 and the lower chamber 34 can be maintained at less than about 25 psig; less than about 10 psig; less than about 5 psig; less than about 1 psig; less than about 20 inches of water; or less than about 10 inches of water.

The differential pressure between the upper chamber 33 and the lower chamber 34 of the chamber 32 can be monitored, adjusted, and/or controlled by the control system 190. For example, the control system 190 may adjust the pressure in the upper chamber 33 by adjusting the flow or pressure of the first gaseous chemical species and/or the optional diluent to the upper chamber 33 by modulating or controlling final control elements 76 or 82, respectively, or by modulating or controlling exhaust valve 118. The control system 190 may adjust the pressure in the lower chamber 34 by adjusting the flow or pressure of the inert gas introduced to the lower chamber 34 from the inert gas reservoir 152 by modulating or controlling final control element 156.

The one or more thermal energy emission devices 14 may take a variety of forms, for example one or more radiant or resistive elements that emit or otherwise produce thermal energy in the form of heat in response to the passage of an electrical current provided by a source 192. The one or more thermal energy emission devices 14 increase the temperature of mechanically fluidized particulate bed 20 carried by the pan 12 via the conductive, convective, and/or radiant transfer of thermal energy provided by the one or more thermal energy emission devices 14. The one or more thermal energy emission devices 14 may for instance, be similar to the nickel/chrome/iron (“nichrome” or Calrod®) electric coils commonly found in electric cook top stoves, or immersion heaters.

One or more temperature transmitters 178 measure the temperature of the mechanically fluidized particulate bed 20. In some instances, the control system 190 may variably adjust the current output of the source 192 responsive to the measured temperature of the mechanically fluidized particulate bed 20, to maintain a particular bed temperature. The control system 190 can maintain the mechanically fluidized particulate bed 20 at or above a particular temperature that is greater than the thermal decomposition temperature of the first chemical species at the measured process conditions (e.g., pressure, gas composition, etc.) in the upper chamber 33.

For example, where the first chemical species comprises silane and the measured gas pressure within the upper chamber 33 is about 175 psig (12 atm.), a temperature of about 550° C. will result in the thermal decomposition of the silane and the deposition of polysilicon (i.e., the second chemical species) on the particles in the particulate bed 20. Where chlorosilanes form at least a portion of the first chemical species, a temperature commensurate with the thermal decomposition temperature of the particular chlorosilane or chlorosilane mixture is used.

Dependent at least in part on the composition of the first chemical species, the mechanically fluidized particulate bed 20 can be controlled to a range from a minimum temperature of about 100° C., about 200° C.; about 300° C.; about 400° C.; or about 500° C. to a maximum temperature of about 500° C.; about 600° C.; about 700° C.; about 800° C.; or about 900° C. In at least some instances, the temperature of the mechanically fluidized particulate bed 20 may be manually, semi-automatically, or automatically adjustable over one or more ranges or values, for example using the control system 190. Such adjustable temperature ranges provide a thermal environment within the particulate bed 20 conducive to the deposition of the second chemical species having a preferred thickness, structure, or composition on the surface of the particles in the mechanically fluidized particulate bed 20. In at least one implementation, the control system 190 maintains a first temperature in the mechanically fluidized particulate bed 20 (e.g., 650° C.) that is greater than the thermal decomposition temperature of the first gaseous chemical species and a temperature elsewhere in the upper chamber 33 and/or lower chamber 34 (e.g., 300° C.) that is below the thermal decomposition temperature of the first gaseous chemical species.

In some instances, a thermally reflective material may be included in the thermally insulating material 16 to reflect at least a portion of the thermal energy emitted by the one or more thermal energy emission devices 14 towards the pan 12.

In at least some instances, at least one thermally reflective member 18 may be located within the upper chamber 33 and positioned to return at least a portion of the thermal energy radiated by the mechanically fluidized particulate bed 20 back to the bed. Such thermally reflective members 18 may advantageously assist in reducing the quantity of energy consumed by the one or more thermal energy emission devices 14 in maintaining the temperature of the mechanically fluidized particulate bed 20. Additionally, the at least one thermally reflective member 18 may also advantageously assist in maintaining a temperature in the upper chamber 33 that is below the thermal decomposition temperature of the first chemical species by limiting the quantity of thermal energy radiated from the mechanically fluidized particulate bed 20 to the upper chamber 33. In at least some instances, the thermally reflective member 18 may be a polished thermally reflective stainless steel or nickel alloy member. In other instances, the thermally reflective member 18 may be a member having a polished thermally reflective coating comprising one or more precious metals such as silver or gold.

It is noted, however, that while called a thermally reflective member, the member 18 does not have to comprise a thermally reflective surface. It may serve to reduce heat flux to from bed 20 to upper section 33 by means of an insulation layer placed on the upper surface of member 18. This layer may be sealed inside a metal or, alternatively, a non-thermally conductive container to prevent contamination of the particulates and coated particles in the mechanically fluidized bed 20. Further, this layer may function in concert with a thermally reflective surface on the under-side of member 18.

In operation, the first chemical species (e.g., silane or one or more chlorosilanes) is transferred from the first chemical species reservoir 72 and optionally mixed with one or more diluent(s) (e.g., hydrogen) transferred from the diluent reservoir 78. The gas or bulk gas mixture is introduced to the upper chamber 33. Surfaces in the upper chamber 33 at temperatures exceeding the thermal decomposition temperature of the first gaseous chemical species promote the thermal decomposition of the first gaseous chemical species and the deposition of the second chemical species (e.g., polysilicon) on those surfaces. Thus, by maintaining the plurality of particulates in the mechanically fluidized particulate bed 20 at temperatures greater than the thermal decomposition temperature of the first gaseous chemical species, the first gaseous chemical species thermally decomposes within the mechanically fluidized particulate bed 20. The second chemical species deposits on the exterior surfaces of the plurality of particulates in the fluidized bed 20 to form the plurality of coated particles 22.

If the temperature of the upper chamber 33 and the various components within the upper chamber 33 are maintained below the thermal decomposition temperature of the first gaseous chemical species, then the likelihood of deposition of the second chemical species on those surfaces is reduced. Advantageously, if the temperature of the mechanically fluidized particulate bed 20 is the only location within the upper chamber 33 that is maintained above the decomposition temperature of the first chemical species, then the likelihood of deposition of the second chemical species within the mechanically fluidized particulate bed 20 is increased while the likelihood of deposition of the second chemical species outside of the particulate bed 20 is reduced.

In at least some instances, the control system 190 can vary or adjust the operation of the mechanically fluidized particulate bed 20 to advantageously alter or affect the yield, composition, or structure of the second chemical species deposited on the plurality of coated particles 22. At times, the control system 190 may oscillate the pan 12 at a displacement and/or frequency that minimizes the fluctuation in gas pressure in the upper chamber 33. The displacement volume of the pan 12 is given by the area of the bottom of the pan 12 multiplied by the displacement distance. For example, a 12 inch diameter circular pan having a displacement of one-tenth of an inch has a displacement volume of approximately 11.3 cubic inches. One method of minimizing the fluctuation in gas pressure in the upper chamber is to ensure the ratio of the volume of the upper chamber to the displacement volume exceeds a defined value. For example, to minimize the pressure fluctuation in the upper chamber 33 attributable to the oscillation of the pan 12, the ratio of the volume of the upper chamber to the displacement volume may exceed about 5:1; about 10:1; about 20:1; about 50:1; about 80:1; or about 100:1.

In other instances, the control system 190 may oscillate or vibrate the mechanically fluidized particulate bed 20 at a first frequency for a first interval, followed by stopping or halting the oscillation or vibration the bed for a second interval. Alternating an interval of bed circulation with a regular or irregular interval without bed circulation can advantageously promote the permeation of the first gaseous chemical species into the interstitial spaces within the plurality of particulates forming the mechanically fluidized particulate bed 20. When the oscillation or vibration of the particulate bed 20 is halted, all or a portion of the first gaseous chemical species can be trapped within the settled bed. The ratio of the first time (i.e., the time the bed is fluidized) to the second time (i.e., the time the bed is settled) can be less than about 10,000:1; less than about 5,000:1; less than about 2,500:1; less than about 1,000:1; less than about 500:1; less than about 250:1; less than about 100:1; less than about 50:1; less than about 25:1; less than about 10:1; or less than about 1:1.

In other instances, the control system 190 alters, adjusts, or controls at least one of an oscillatory frequency and/or an oscillatory displacement along at least one axis of motion. In one example, the control system 190 may alter, adjust, or control the oscillatory frequency of the pan 12 for example by adjusting the frequency upward or downward to achieve a desired coated particle 22 separation from the mechanically fluidized particulate bed 20. In another example, the control system 190 may alter, adjust, or control the oscillatory displacement of the pan 12 along a single axis of motion (e.g., an axis normal to the bottom of the pan 12) or along a plurality of orthogonal axes of motion (e.g., an axis normal to the bottom of the pan 12, and at least one axis parallel to the bottom of the pan 12).

In other implementations, the oscillation or vibration of the pan 12 is maintained more or less constant while the first gaseous chemical species is introduced to the upper chamber 33 and/or the mechanically fluidized particulate bed 20. The oscillatory displacement and/or oscillatory frequency of the pan 12 can be varied intermittently or continuously to favor the deposition of the second chemical species on the plurality of particles forming the mechanically fluidized particulate bed 20. The second chemical species deposits on the exterior surfaces of the plurality of particulates forming the mechanically fluidized particulate bed 20. All or a portion of the resultant plurality of coated particles 22 may be removed from the bed mechanically fluidized particulate bed 20 on a batch, semi-continuous, or continuous basis.

The particulate supply system 90 includes a particulate transporter 94, for example a conveyor, to deliver the fresh particulates 92 from the particulate reservoir 96 directly to the mechanically fluidized particulate bed 20 or one or more intermediate systems such as a particulate inlet system 98. In some embodiments, a particle feed vessel 102 in the particulate inlet system 98 may serve as a reservoir of fresh particulates 92.

The fresh particulates 92 may have any of a variety of forms. For example, the fresh particulates 92 may be provided as regularly or irregularly shaped particulates that serve as a nucleation points for the deposition of the second chemical species in the mechanically fluidized particulate bed 20. At times, the fresh particulates 92 may include particulates formed from the second chemical species. The fresh particulates 92 supplied to the mechanically fluidized particulate bed 20 can have a diameter of from about 0.01 mm to about 2 mm; 0.1 mm to about 2 mm; from about 0.15 mm to about 1.5 mm; from about 0.25 mm to about 1.5 mm; from about 0.25 mm to about 1 mm; or from about 0.25 mm to about 0.5 mm.

The sum of the surface areas of each of the particulates in the mechanically fluidized particulate bed 20 provides an aggregate bed surface area. In at least some instances, the quantity of particles added to the mechanically fluidized particulate bed 20 may be controlled, for example using the control system 190, to maintain a target ratio of aggregate bed surface area to the surface area of the upper surface of the pan bottom 12a. The aggregate bed surface area to surface area of the upper surface of the pan bottom 12a can be a ratio of from about 10:1 to about 10,000:1; about 10:1 to about 5,000:1; about 10:1 to about 2,500:1; about 10:1 to about 1,000:1; about 10:1 to about 500:1; or about 10:1 to about 100:1.

In other instances, the number of fresh particulates 92 added to the mechanically fluidized particulate bed 20 may be based on the overall area of the upper surface of the bottom of the pan 12a. It has been unexpectedly found that the size of the coated particles 22 produced in the mechanically fluidized particulate bed 20 operating at a given production rate, is a strong function of the number of fresh (i.e., seed) particulates 92 generated or added per unit time per unit area of the upper surface of the bottom of the pan 12a. In fact, the number of fresh particulates 92 added per unit time per unit area of the upper surface of the bottom of the pan 12a is at least one identified controlling factor establishing one or more physical properties (e.g., size or diameter) of the plurality of coated particles 22. The particulate supply system 90 can add particles to the particulate bed 20 at a rate of from about 1 particle/minute-square inch of upper surface 12a area (p/m-in²) to about 5,000 p/m-in²; about 1 particle/minute-square inch of upper surface 12a area (p/m-in²) to about 2,000 p/m-in²; about 1 particle/minute-square inch of upper surface 12a area (p/m-in²) to about 1,000 p/m-in²; about 2 p/m-in² to about 200 p/m-in²; about 5 p/m-in² to about 150 p/m-in²; about 10 p/m-in² to about 100 p/m-in²; or about 10 p/m-in² to about 80 p/m-in².

The particulate transporter 94 can include at least one of: a pneumatic feeder (e.g., a blower); a gravimetric feeder (e.g., a weigh-belt feeder); a volumetric feeder (e.g., a screw type feeder); or combinations thereof. In at least some instances, the volumetric or gravimetric delivery rate of the particulate transporter 94, may be continuously adjusted or varied over one or more ranges, for example the control system 190 may continuously control the weight or volume of fresh particulates 92 delivered by the particulate supply system 90 and by correlation with the weight of the average coated particle 22, the number of particulates added per unit time.

The particulate inlet system 98 receives fresh particulates 92 from the particulate transporter 94 and includes: a particulate inlet valve 104, a particulate feed vessel 102, and a particulate outlet valve 106. Particulates are discharged from the particulate transporter 94 through the particle inlet valve 104 and into the particulate feed vessel 102. The accumulated fresh particulates 92 may be discharged from the particle feed vessel 102 continuously, intermittently, or periodically via the particulate outlet valve 106. The particulate inlet valve 104 and the particulate outlet valve 106 can include any type of flow control device, for example one or more motor driven, variable speed, rotary valves.

In at least some instances, the fresh particulates 92 flowing into the upper portion of the chamber 33 are deposited in mechanically fluidized particulate bed 20 using a conduit or hollow member 108 such as a dip-tube, pipe, or the like. The control system 190 may coordinate or synchronize volume or weight of fresh particles 92 supplied by the particulate supply system 90 to the volume or weight of the coated particles 22 removed by the coated particle collection system 130. Using the control system 190 to coordinate or synchronize the feed rate of fresh particulates 92 to the mechanically fluidized particulate bed 20 with the removal rate of coated particles 22 from the mechanically fluidized particulate bed 20 provides a system capable of controlling the average particle diameter of discharged coated particles 22. Adding a greater amount of fresh particle—measured as the number of particles, the volumetric rate of particles, or the mass of particles measured as the number of particles, the volumetric rate of particles, or the mass of particles—decreases the average size of discharged particles 22.

The gas supply system 70 includes a first gaseous chemical species reservoir 72 containing the first gaseous chemical species. In some instances, the first gaseous chemical species reservoir 72 may be optionally fluidly coupled to a diluent reservoir 78 containing the one or more optional diluent(s). Where the first gaseous chemical species is provided to the mechanically fluidized particulate bed 20 as a mixture with the optional diluent gas, flow from each of the reservoirs 72, 78 mixes and enters the upper chamber 33 as a bulk gas mixture via the fluid conduit 84.

The gas supply system 70 also includes various conduits 74, 80, a first gaseous chemical species final control element 76, a diluent final control element 82, and other components that, for clarity, are not shown in FIG. 1 (e.g., blowers, compressors, eductors, block valves, bleed systems, environmental control systems, etc.). Such equipment and ancillary systems permit the delivery of the bulk gas mixture containing the first chemical species to the upper portion of the chamber 33 in a controlled, safe, and environmentally conscious manner.

The gas containing the first gaseous chemical species may optionally include one or more diluents (e.g., hydrogen) pre-mixed with the first gaseous chemical species. The first gaseous chemical species can include, but is not limited to silane, monochlorosilane, dichlorosilane, trichlorosilane, or tetrachlorosilane to provide a non-volatile second chemical species that includes silicon. However, other alternative gaseous chemical species may also be used, including gases or gas mixtures that upon decomposition provide a variety of non-volatile second chemical species such as silicon carbide, silicon nitride, or aluminum oxide (sapphire glass).

The one or more optional diluent(s) stored in the diluent reservoir 78 can be the same as or different from the third gaseous chemical species produced as a byproduct of the thermal decomposition of the first gaseous chemical species. Although hydrogen provides an illustrative optional diluent, other diluents may be used in the upper chamber 33. In at least some implementations, the one or more optional diluents may include one or more dopants such as arsenic and arsenic containing compounds, boron and boron containing compounds, phosphorus and phosphorus containing compounds, gallium and gallium containing compounds, germanium or germanium containing compounds, or combinations thereof.

Although shown in FIG. 1 as entering at the top of the upper chamber 33, the first gaseous chemical species and/or the bulk gas mixture may be introduced, in whole or in part, at any number of points and/or locations within the upper chamber 33. For example, at least a portion of the first gaseous chemical species and/or the bulk gas mixture may be introduced to the sides of the upper chamber 33. In another example, at least a portion of the first gaseous chemical species and/or the bulk gas mixture may be discharged directly into the mechanically fluidized particulate bed 20, for example using one or more flexible connections to a gas distributor located on the upper surface of the pan 12a. The first gaseous chemical species and/or bulk gas mixture may be added intermittently or continuously to the upper chamber 33 and/or the mechanically fluidized particulate bed 20. In at least some instances, the first gaseous chemical species and/or the bulk gas mixture is received by the mechanically fluidized particulate bed 20 via one or more apertures 10 in the thermally reflective member 18.

The control system 190 varies, alters, adjusts or controls the flow and/or pressure of the first gaseous chemical species and/or the bulk gas mixture to the upper chamber 33. One or more pressure transmitters 176 monitor gas pressure within the upper chamber 33. In one example, a first gaseous chemical species that includes silane gas is introduced to the upper chamber 33 and/or to the heated, mechanically fluidized particulate bed 20. As the silane thermally decomposes within the mechanically fluidized particulate bed 20, polysilicon deposits on the surface of the particulates in the mechanically fluidized particulate bed 20 to provide the plurality of coated particles 22. As the coated particles 22 increase in diameter the depth of the mechanically fluidized particulate bed 20 increases and at least some of the coated particles 22 fall into the coated particle overflow conduit 132.

In such an example, the control system 190 may introduce the first gaseous chemical species and optional dopants at a controlled rate to maintain a defined first gaseous chemical species partial pressure in the upper chamber 33 and/or in the mechanically fluidized particulate bed 20. In some instances, the first gaseous chemical species can have a partial pressure of from about 0 atmospheres (atm.) to about 40 atm. in the upper chamber 33 or in the mechanically fluidized particulate bed 20. In some instances, the optional diluent (e.g., hydrogen) can have a partial pressure of from about 0 atm. to about 40 atm in the upper chamber 33 or in the mechanically fluidized particulate bed 20. In some instances, the optional diluent can have a mole fraction of from about 0 mol % to about 99 mol % in the upper chamber 33 or in the mechanically fluidized particulate bed 20.

In some instances, the upper chamber 33 can be maintained at a pressure of from about 5 psia (0.33 atm.) to about 600 psia (40 atm.); from about 15 psia (1 atm.) to about 220 psia (15 atm.); from about 30 psia (2 atm.) to about 185 psia (12.5 atm.); or from about 75 psia (5 atm.) to about 175 psia (12 atm.). Within the upper chamber 33, the first gaseous chemical species can have a partial pressure of from about 0 psi (1 atm.) to about 600 psi (40 atm.); from about 5 psi (0.33 atm.) to about 150 psi (10 atm.); from about 15 psi (1 atm.) to about 75 psi (5 atm.); or from about 0.1 psi (0.01 atm.) to about 45 psi (3 atm.). Within the upper chamber 33, the one or more optional diluent(s) can be at a partial pressure of from about 1 psi (0.067 atm.) to about 600 psi (40 atm.); from about 15 psi (1 atm.) to about 220 psi (15 atm.); from about 15 psi (1 atm.) to about 150 psi (10 atm.); from about 0.1 psi (0.01 atm.) to about 220 psi (15 atm.); or from about 45 psi (3 atm.) to about 150 psi (10 atm.).

In one illustrative continuous operation example, the operating pressure within the upper chamber 33 is maintained at about 165 psia (11.2 atm.), with the partial pressure of silane (i.e., the first gaseous chemical species) in the off-gas from the upper section 33 maintained at about 0.5 psi (0.35 atm.), and the partial pressure of hydrogen (i.e., the diluent which can be as a third gaseous chemical species) maintained at about 164.5 psi (11.1 atm.). The diluent may be added as a feed gas to the upper chamber 33 or in the case of silane decomposition may be produced as a third gaseous chemical species byproduct of the thermal decomposition of silane according to the formula SiH₄→Si+2H₂.

The environment in the upper chamber 33, overflow conduit 132, and product receiver 130 is maintained at a low oxygen level (e.g., less than 20 volume percent oxygen) or a very low oxygen level (e.g., less than 0.001 mole percent oxygen to less than 1.0 mole percent oxygen). In some instances, the environment within the upper chamber 33 is maintained at a low oxygen content that does not expose the coated particles 22 to atmospheric oxygen. In some instances, the environment within the upper chamber 33, overflow conduit 132, and product receiver 130 is maintained at a low oxygen level of less than 20 volume percent (vol %). In some instances, the environment within the upper chamber 33 is maintained at a very low oxygen level of less than about 1 mole % (mol %) oxygen; less than about 0.5 mol % oxygen; less than about 0.3 mol % oxygen; less than about 0.1 mol % oxygen; less than about 0.01 mol % oxygen; or less than about 0.001 mol % oxygen.

Since the oxygen concentration in the upper chamber 33 is limited, oxide formation of the surface of the coated particles 22 is beneficially minimized or even eliminated. In one example, if the coated particles 22 include silicon coated particles, the formation of a layer containing silicon oxides (e.g., silicon oxide, silicon dioxide) is advantageously minimized or even eliminated. In such an example, the silicon coated particles 22 produced in the mechanically fluidized particulate bed 20 can have a silicon oxides content of less than about 500 parts per million by weight (ppmw); less than about 100 ppmw; less than about 50 ppmw; less than about 10 ppmw; or less than about 1 ppmw.

The control system 190 varies, alters, adjusts, modulates, and/or controls the composition of the gas in the upper chamber 33. The control system 190 makes such adjustments on an intermittent, periodic, or continuous basis to maintain any desired gas composition (i.e., first gaseous chemical species/optional diluent/third gaseous chemical species) in the upper chamber 33. In some instances, one or more gas analyzers (e.g., an online gas chromatograph) sample the gas composition in the upper chamber 33 on an intermittent, periodic, or continuous basis. The use of such analyzers may advantageously provide an indication of the conversion and rate at which the second chemical species deposits on in the mechanically fluidized particulate bed 20 and the quantity of third gaseous chemical species produced.

The control system 190 can intermittently, periodically or continuously adjust, alter, vary and/or control the flow or the pressure of either or both the first gaseous chemical species and the optional diluent added to the upper chamber 33 and/or the mechanically fluidized particulate bed 20. The control system 190 can maintain the concentration of the first gaseous chemical species in the upper chamber 33 and/or mechanically fluidized particulate bed 20 from about 0.1 mole percent (mol %) to about 100 mol %; about 0.5 mol % to about 50 mol %; from about 5 mol % to about 40 mol %; from about 10 mol % to about 40 mol %; from about 10 mol % to about 30 mol %; or from about 20 mol % to about 30 mol %. The control system 190 can maintain the concentration of the optional diluent in the upper chamber 33 and/or mechanically fluidized particulate bed 20 from about 0 mol % to about 95 mol %; from about 50 mol % to about 95 mol %; from about 60 mol % to about 95 mol %; from about 60 mol % to about 90 mol %; from about 70 mol % to about 90 mol %; or from about 70 mol % to about 80 mol %.

When the mechanically fluidized particulate bed 20 is designed according to the teachings contained herein most, if not essentially all, of the first gaseous chemical species (e.g., silane) is thermally decomposed in the mechanically fluidized particulate bed 20 to provide the plurality of coated particles 22 containing the second chemical species (e.g., polysilicon). The required pan 12 size can be calculated using the surface are of the particles comprising the bed, the bed temperature, hold-up time in the bed, system pressure in chamber 33, gas/granule contracting efficiency, bed action, and the partial pressure of first gaseous chemical species in the gas contained in the upper portion of the chamber 33.

In at least some instances, the first gaseous chemical species is maintained at a temperature below its decomposition temperature at all points in the upper chamber 33 external to the mechanically fluidized particulate bed 20. The control system 190 maintains the temperature of the first gaseous chemical species below its thermal decomposition temperature to reduce the likelihood of auto-decomposition of the first gaseous chemical species outside of the mechanically fluidized particulate bed 20. Further, the control system 190 maintains the temperature sufficiently high to reduce the thermal energy demand placed on the thermal energy emitting device 14 to maintain the mechanically fluidized particulate bed 20 at a temperature greater than the thermal decomposition temperature of the first chemical species.

In some instances, the first gaseous chemical species and any optional diluents may be added to the upper chamber 33 at a temperature that is between a minimum temperature of about 10° C.; about 20° C.; about 50° C.; about 70° C.; about 100° C.; about 150° C.; or about 200° C. to a maximum temperature of about 250° C.; about 300° C.; about 350° C.; about 400° C.; or about 450° C. In some instances, the first gaseous chemical species and any optional diluents added to the upper chamber may be maintained a minimum of about 10° C.; about 20° C.; about 50° C.; about 70° C.; about 100° C.; about 150° C.; about 200° C.; about 250° C.; or about 300° C. below the thermal decomposition temperature of the first gaseous chemical species.

The thermal energy used to increase the temperature of the first gaseous chemical species and, optionally, any diluents may be sourced from any thermal energy emitting device. Such thermal energy emitting devices may include, but are not limited to, one or more external electric heaters, one or more external fluid heaters, or one or more heat interchanges/exchangers where hot gases are used to increase the temperature of the first gaseous chemical species and, optionally, any diluents.

In some instances, the first gaseous chemical species and, optionally, any diluents may be passed through the upper chamber 33 which supplies the thermal energy to preheat the first gaseous chemical species prior to introduction to the mechanically fluidized particulate bed 20. In such instances, the first gaseous chemical species and, optionally, any diluents may be apportioned into two portions. The first portion passes through a heat interchanger/heat exchanger (e.g., a coil) positioned in the upper chamber 33 of the reactor 30. The second portion bypasses the heat interchanger/heat exchanger and is combined with the heated gas exiting the heat interchanger/heat exchanger. The combined first gaseous chemical species and any optional diluents are injected into the mechanically fluidized particulate bed 20. The proportion of gas in the first portion and the second portion will determine the temperature of the combined stream that is injected into the mechanically fluidized particulate bed 20. If the temperature of the combined gas stream approaches the decomposition temperature of the first gaseous chemical species, the gas allocated to the first portion (i.e., the portion bypassing the heat interchanger/heat exchanger) can be adjusted. Such an approach advantageously controls and/or maintains the temperature of the first gaseous chemical species introduced to the mechanically fluidized particulate bed 20 at an optimal temperature and controls and/or maintains the temperature in the upper chamber 33 below the thermal decomposition temperature of the first gaseous chemical species to minimize or eliminate the thermal decomposition of the first gaseous chemical species at locations external to the mechanically fluidized particulate bed 20. In some instances, the temperature of the first gaseous chemical species and any optional diluents may be adjust prior to apportioning into the first portion and the second portion.

In some instances, the first portion that is passed through the heat interchanger/heat exchanger is maintained below the thermal decomposition temperature of the first gaseous chemical species because auxiliary cooling in the upper zone (e.g., a fluid cooler and cooling coil) controls and/or maintains the temperature of the gas in the upper chamber 33 below the thermal decomposition temperature of the first gaseous chemical species.

In at least some instances, the addition of the first gaseous chemical species to the upper chamber 33 may advantageously permit the use of a pure or near pure first gaseous chemical species (e.g., silanes) to achieve an overall polysilicon conversion of greater than about 70%; greater than about 75%; greater than about 80%; greater than about 85%; greater than about 90%; greater than about 95%; greater than about 99%; or greater than about 99.7%.

The gas recovery system 110 removes byproducts such as a byproduct third gaseous chemical species generated during the thermal decomposition of the first gaseous chemical species. The gas recovery system 110 includes an exhaust port 112 and conduit 114 fluidly coupled to the upper chamber 33 to remove gaseous byproducts and entrained fines from the upper chamber 33. The gas recovery system 110 further includes various exhaust fines separators 116, exhaust control devices 118, and other components (e.g., blowers, compressors—not shown in FIG. 1) useful in removing or expelling as an exhaust 120 at least a portion of the gas removed from the upper portion of the chamber 33.

The gas recovery system 110 may be useful in removing any unreacted first gaseous chemical species, optional diluent(s), and/or byproducts present in the upper chamber 33 for recovery or additional processing. In one example, at least a portion of the gas removed from the upper chamber 33 in a first reaction vessel 30a may be introduced to the upper chamber 33 in a second reaction vessel 30b. In some instances, all or a portion of the diluent(s) present in the gas removed from the upper chamber 33 may be recycled to the upper chamber 33. In some instances, the gas removed from the upper chamber 33 by the gas recovery system 110 may be treated, separated, or otherwise purified prior to discharge, disposal, sale, or recovery. In some instances, a portion of the gas separated by the gas recovery system (e.g., first gaseous chemical species, one or more diluents, one or more dopants or the like) may be recovered for reuse in reactor 30. In such instances, the pressure of any recovered gas can be increased using one or more gas compressors 340 or similar devices.

At times, the gas removed from the upper chamber 33 contains suspended fines 122 such as amorphous silica (a.k.a. “poly-powder”), other decomposition byproducts, and physical erosion byproducts. The exhaust fines separator 116 separates at least some of the fines 122 present in the gas removed from the upper chamber 33. The exhaust fines separator 116 can include at least one separation stage, and may include multiple separation stages each using the same or a different solid/gas separation technology. In one example, the exhaust fines separator 116 includes a cyclonic separator followed by one or more particulate filters.

The coated particle collection system 130 collects at least a portion of the plurality of coated particles 22 that overflow from the mechanically fluidized particulate bed 20. As the diameter of coated particles 22 present in the mechanically fluidized particulate bed 20 increase, the coated particles “float” to the surface of the mechanically fluidized particulate bed 20.

In some instances, the coated particle collection system 130 collects coated particles 22 that overflow the perimeter wall 12c of the pan 12 and fall into one or more coated particle overflow collection devices positioned at least partially about the perimeter wall 12c of the pan 12. In such instances, the height of the perimeter wall 12c of the pan 12 determines the depth of the mechanically fluidized particulate bed 20.

In other instances, the coated particle collection system 130 collects coated particles 22 that overflow into one or more hollow coated particle overflow conduits 132 positioned at defined locations (e.g., in the center) of the pan 12. In such instances, the distance the inlet of the hollow coated particle overflow conduit 132 extends above the upper surface 12a of the bottom of the pan 12 determines the depth of the mechanically fluidized particulate bed 20. The distance the inlet of the hollow coated particle overflow conduits 132 above the upper surface 12a of the bottom of the pan 12 can be about 0.25 inches (6 mm) or more; about 0.5 inches (12 mm) or more; about 0.75 inches (18 mm) or more; about 1 inch (25 mm) or more; about 1.5 inches (37 mm) or more; about 2 inches (50 mm) or more; about 2.5 (65 mm) inches or more; about 3 inches (75 mm) or more; about 4 inches (100 mm) or more; about 5 inches (130 mm) or more; about 6 inches (150 mm) or more; about 7 inches (180 mm) or more; or about 15 inches (180 mm) or more.

The mechanically fluidized particulate bed 20 can have a settled (i.e., in a non-mechanically fluidized state) bed depth of from about 0.10 inches (3 mm) to about 10 inches (255 mm); from about 0.25 inches (6 mm) to about 6 inches (150 mm); from about 0.50 inches (12 mm) to about 4 inches (100 mm); from about 0.50 inches (12 mm) to about 3 inches (75 mm); or from about 0.75 inches (18 mm) to about 2 inches (50 mm).

When needed, the number of fresh particles 92 added by the particulate feed system 90 is sufficiently small that the impact on the volume of the mechanically fluidized particulate bed 20 is minimal. Substantially all of the volumetric increase experienced by the mechanically fluidized particulate bed 20 is attributable to the deposition of the second chemical species (e.g. silicon) on the particulates in the mechanically fluidized particulate bed 20 and the resultant increase in diameter (and volume) of the plurality of coated particles 22.

The number of fresh particles 92 generated within the mechanically fluidized particulate bed 20 and/or added to the mechanically fluidized particulate bed 20 determines the size and number of the plurality of coated particles 22 produced. The size of the fresh particles 92 generated within the mechanically fluidized particulate bed 20 and/or added to the mechanically fluidized particulate bed 20 minimally impacts on the size of the final coated particles 22 produced in the mechanically fluidized particulate bed 20. Instead, the number of fresh particles generated within the mechanically fluidized particulate bed 20 and/or added to the mechanically fluidized particulate bed 20 has a much greater impact on the size of the coated particles 22.

At times the open-ended inlet of the hollow coated particle overflow conduit 132 is positioned or projects a fixed distance above the upper surface 12a of the bottom of the pan 12. For example, the open-ended inlet of the hollow coated particle overflow 132 can project from the upper surface 12a of the pan 12 a distance of about 0.25 inches (6 mm); about 0.5 inches (12 mm); about 0.75 inches (18 mm); about 1 inch (25 mm); about 1.5 inches (37 mm); about 2 inches (50 mm); about 2.5 inches (60 mm); about 3 inches (75 mm); about 4 inches (100 mm); about 5 inches (125 mm); about 6 inches (150 mm); about 7 inches (175 mm); about 8 inches (200 mm); or about 15 inches (380 mm). The hollow coated particle overflow conduit 132 can have an inside diameter of about 3 mm to about 55 mm; about 6 mm to about 25 mm; or about 13 mm. In some instances, the control system 190 intermittently, periodically, or continuously adjusts the depth of the mechanically fluidized particulate bed 20 by varying the projection of the coated particle overflow conduit 132 above the upper surface 12a of the bottom of the pan 12. Such adjustment of the projection of the coated particle overflow conduit 132 above the upper surface 12a of the bottom of the pan 12 may be accomplished using an electromechanical system such as a motor and transmission assembly, or an electromagnetic system such as magnetically coupling the hollow member to an electric coil.

The depth of the mechanically fluidized particulate bed 20 can influence one or more physical parameters such as particle diameter, particle composition, particle morphology, and/or particle density of the coated particles 22 that are selectively removed or separated from the mechanically fluidized particulate bed 20. Thus, mechanically fluidized particulate bed 20 bed depth may be adjusted to produce coated particles 22 having one or more desirable physical or compositional characteristics. For example, adjusting the hold-up time in the mechanically fluidized particulate bed 20 can reduce or lower the residual hydrogen content as either bonded hydrogen on the surface or as encapsulated hydrogen in at least a portion of the plurality of coated particles 22 that are selectively removed or separated from the mechanically fluidized particulate bed 20. The projection of the coated particle overflow conduit 132 above the upper surface of the pan 12a can be less than the height of the perimeter walls 12c of the pan 12 to reduce the likelihood of spillage of the coated particles 22 from the pan 12 or to retain the mechanically fluidized particulate bed 20 and the plurality of coated particles 22 in the bed. In some instances, the coated particles 22 removed from the mechanically fluidized particulate bed 20 can have a diameter of from about 0.01 mm to about 5 mm; from about 0.5 mm to about 4 mm; from about 0.5 mm to about 3 mm; from about 0.5 mm to about 2.5 mm; from about 0.5 mm to about 2 mm; from about 1 mm to about 2.5 mm; or from about 1 mm to about 2 mm.

Coated particles 22 removed via the coated particle overflow conduit 132 pass through one or more coated particle inlet valves 134 and accumulate in the coated particle discharge vessel 136. Coated particles 22 accumulated in the coated particle discharge vessel 136 are periodically or continuously removed as product coated particles 22 via one or more coated particle outlet valves 138. The coated particle inlet valve 134 and the coated particle outlet valve 138 can include any type of flow control device, for example one or more prime motor driven, variable speed, rotary valves. In at least some instances, the control system 190 can limit, control, or otherwise vary the discharge of finished coated particles 22 from the coated particle collection system 130. In at least some instances, the control system 190 can adjust the removal rate of the coated particles 22 from the mechanically fluidized particulate bed 20 to match the addition or generation rate of seed or fresh particles 92 in the mechanically fluidized particulate bed 20. In some instances, the coated particles 22 may pass through one or more post-treatment processes on a continuous or on an “as-needed” basis, for example a diluent gas purging process or a heating process, e.g., heating at 500 C to 700 C, to de-gas hydrogen from the coated particles 22. Although not shown in FIG. 1, all or a portion of such post-treatment processes may be integrated into the particle collection system 130.

In some implementations the coated particle collection system can include one or more purge gas systems 137 that supplies a chemically inert purge gas to the mechanically fluidized particulate bed 20 via countercurrent flow through the particle removal conduit 132. Such countercurrent purge gas flow assists in reducing the entry of the first gaseous chemical species into the coated particle overflow conduit 132. In some instances, the chemically inert purge gas can include the same gas used as a diluent (e.g., hydrogen) that is used to dilute the first gaseous chemical species in the upper chamber 33.

Such countercurrent purge gas also can be used to effect a selective removal or separation of at least a portion of the plurality of coated particles 22 from the mechanically fluidized particulate bed 20. For example, the countercurrent purge gas may assist in the selective removal or separation of coated particles having one or more desirable compositional and/or physical properties (e.g., coated particle diameter) from the mechanically fluidized particulate bed 20. In some instances, increasing the flow of purge gas tends to increase countercurrent gas velocity within the coated particle overflow tube 132 which tends to return smaller diameter coated particles back to the mechanically fluidized particulate bed 20. Conversely, decreasing the flow of purge gas tends to decrease countercurrent gas velocity within the coated particle overflow tube 132 which tends to separate smaller diameter coated particles from the mechanically fluidized particulate bed 20 while permitting the flow of larger diameter coated particles 22 from the mechanically fluidized particulate bed 20.

The control system 190 may be communicably coupled to control one or more other elements of the system 100. The control system 190 may include one or more temperature, pressure, flow, or analytical sensors and transmitters to provide process variable signals indicative of an operating parameter of one or more components of the system 100. For instance, the control system 190 may include a number of temperature transmitters (e.g., thermocouples, resistive thermal devices) to provide one or more process variable signals indicative of a temperature of the lower surface 12b of the bottom of the pan 12, or of the upper surface 12a of the bottom of the pan, or of the particulates in mechanically fluidized particulate bed 20. The control system 190 may also receive process variable signals from sensors associated with various valves, blowers, compressors, and other equipment. Such process variable signals may be indicative of a position or state of operation of the specific pieces of equipment or indicative of the operating characteristics within the specific pieces of equipment such as flow rate, temperature, pressure, vibration frequency, vibration amplitude, density, weight, or size.

The second chemical species diameter, bulk density, and/or volume of the coated particles 22 may be increased by increasing deposition rate of the second chemical species, by adjusting one or more of: the mechanically fluidized particulate bed 20 depth; the addition rate of the first gaseous chemical species; the concentration of the optional diluents in the mechanically fluidized particulate bed 20; the number of fresh particles 92 added to or generated in the mechanically fluidized particulate bed 20 per unit time; the temperature of the mechanically fluidized particulate bed 20, the temperature of the first gaseous chemical species in the mechanically fluidized particulate bed 20; the gas pressure in the upper chamber 33; or combinations thereof.

In at least some instances, increasing the temperature of the mechanically fluidized particulate bed 20 can increase the thermal decomposition rate of the first gaseous chemical species, advantageously increasing the deposition rate of the second chemical species. However, such increases in bed temperature will increase the electrical energy consumed by the one or more thermal energy emission devices 14 used to heat the mechanically fluidized particulate bed 20 which may result in a disadvantageous higher electrical usage per unit of polysilicon product (i.e., result in higher kilo-watt hours per kilogram of polysilicon produced). As such, an optimal mechanically fluidized particulate bed 20 temperature may be selected for any given system and set of operational objectives and cost factors, balancing production rate with electrical cost by adjusting the temperature of the mechanically fluidized particulate bed 20.

The control system 190 may use the various process variable signals to generate one or more control variable outputs useful for controlling one or more of the elements of the system 100 according to a defined set of machine executable instructions or logic. The machine executable instructions or logic may be stored in one or more non-transitory storage locations that are communicably coupled to the control system 190. For example, the control system 190 may produce one or more control signal outputs for controlling various elements such as valve(s), thermal energy emission devices, motors, actuators or transducers, blowers, compressors, etc. Thus, for instance, the control system 190 may be communicatively coupled and configured to control one or more valves, conveyors or other transport mechanisms to selectively provide fresh particles 92 to the mechanically fluidized particulate bed 20. Also for instance, the control system 190 may be communicatively coupled and configured to control a frequency of vibration or oscillation of the pan 12 or the oscillatory or vibratory displacement of the pan 12 along the one or more axes of motion 54 to produce the desired level of fluidization within the mechanically fluidized particulate bed 20.

The control system 190 may be communicatively coupled and configured to control a temperature of all or a portion of the pan 12 or of the mechanically fluidized particulate bed 20 retained therein. Such control may be accomplished by controlling a flow of current through the one or more thermal energy emission devices 14. Also for instance, the control system 190 may be communicatively coupled and configured to control a flow of the first chemical species from the first gaseous chemical species reservoir 72 or one or more optional diluent(s) from the diluent reservoir 78 into the upper chamber 33. Such control may be accomplished using one or more variably adjustable final control elements such as control valves, solenoids, relays, actuators, valve positioners and the like or by controlling the delivery rate or pressure of one or more blowers or compressors, for example by controlling a speed of an associated electric motor.

Also for instance, the control system 190 may be communicatively coupled and configured to control the withdrawal of gas from the upper chamber 33 via the gas recovery system 110. Such control may be accomplished by providing suitable control signals including information obtained from an on-line analyzer (e.g., a gas chromatograph) monitoring the concentration of the first gaseous chemical species in the upper chamber 33 or a pressure transmitter, to control one or more valves, dampers, back-pressure control valve, blowers, exhaust fans, via one or more solenoids, relays, electric motors or other actuators.

In some instances, the control system 190 may be communicatively coupled and configured to control a back-pressure control valve to alter, adjust, and/or control system pressure in the upper chamber 33. At times, the control system 190 can control the feed rate of the first gaseous chemical species (e.g., silane) into the mechanically fluidized particulate bed 20 based at least in part on the measured pressure in the upper chamber 33 and the concentration of the first gaseous chemical species in the gas present in the upper chamber 33.

The control system 190 may take a variety of forms. For example, the control system 190 may include a programmed general purpose computer having one or more microprocessors and memories (e.g., RAM, ROM, Flash, rotating media). Alternatively, or additionally, the control system 190 may include a programmable gate array, application specific integrated circuit, and/or programmable logic controller.

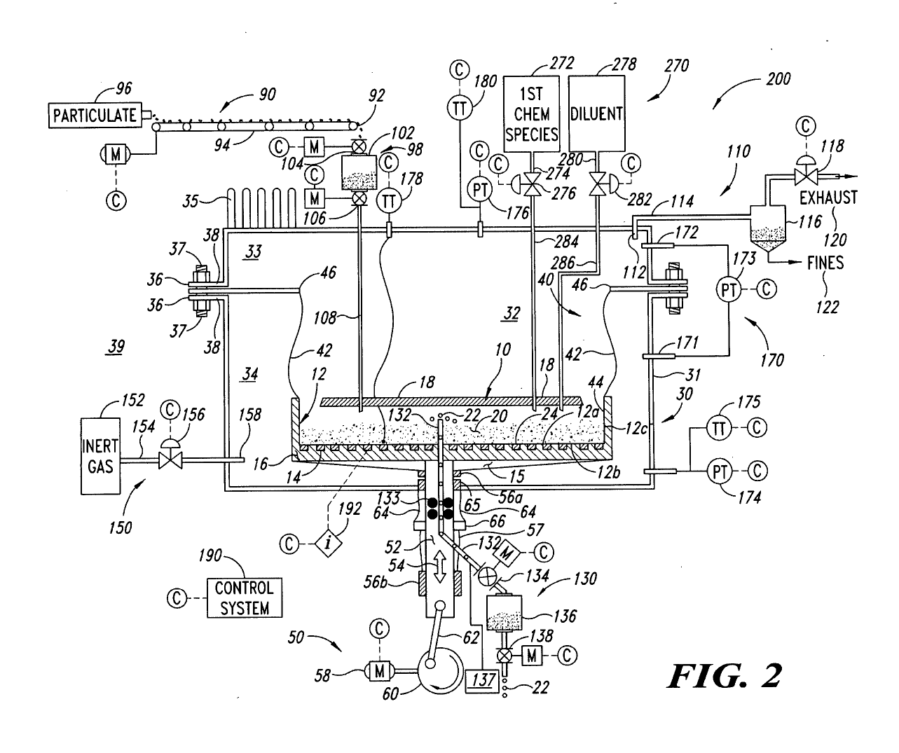

FIG. 2 shows another mechanically fluidized bed reactor system 200, according to one illustrated embodiment. In the continuously operated mechanically fluidized bed reactor system 200, fresh particles 92 are fed on an as needed basis to the mechanically fluidized particulate bed 20 and quantities of the first gaseous chemical species and one or more optional diluent(s) are introduced to the upper chamber 33, according to an embodiment. As the first gaseous chemical species permeates the heated mechanically fluidized particulate bed 20, the thermal decomposition of the first gaseous chemical species within the particulate bed 20 deposits a second chemical species on the particulates to form the plurality of coated particles 22. Some or all of the plurality of coated particles 22 are removed from the mechanically fluidized particulate bed 20 via the coated particle collection system 130.

Within the mechanically fluidized bed reactor, all or a portion of the first gaseous chemical species and all or a portion of the one or more optional diluent(s) are introduced via separate fluid conduits 284, 286 (respectively) to the upper chamber 33 and/or the mechanically fluidized particulate bed 20. In such a manner, the flow and pressure of the first gaseous chemical species and the one or more diluent(s) may be individually controlled, altered, or adjusted to provide a wide range of operating environments within the upper chamber 33.

In at least some operating modes, no diluent is added to the upper chamber 33 or the mechanically fluidized particulate bed 20. At such times, the first gaseous chemical species may be added to the upper chamber 33 and/or the mechanically fluidized particulate bed 20 in the absence of separate diluent feed. At other times, the first gaseous chemical species may be added to the upper chamber 33 and/or the mechanically fluidized particulate bed 20 either premixed with or separate but contemporaneous with a diluent.

Prior to flowing into the upper chamber 33 via fluid conduit 284, the first gaseous chemical species and any diluent(s) premixed therewith are transferred from a reservoir 272 via one or more conduits 274 and one or more final control elements 276, such as one or more flow or pressure control valves. In a similar manner, when used and prior to flowing into the upper chamber 33 via fluid conduit 286, the one or more optional diluent(s) are transferred from a reservoir 278 via one or more conduits 280 and one or more final control elements 282, such as one or more flow or pressure control valves. The first gaseous chemical species and any diluent(s) flow into the upper chamber 33 in a controlled, safe, and environmentally conscious manner.

The control system 190 intermittently, periodically, or continuously adjusts, alters, modulates, or controls the flow or pressure of either or both the first gaseous chemical species or the one or more diluent(s) to achieve a desired gas composition in the upper chamber and/or the mechanically fluidized particulate bed 20. The control system 190 intermittently, periodically, or continuously adjusts, alters, modulates, or controls the concentration of the first gaseous chemical species in the upper chamber 33 and/or mechanically fluidized particulate bed 20 from about 0.1 mole percent (mol %) to about 100 mol %; from about 0.1 mol % to about 40 mol %; from about 0.1 mol % to about 30 mol %; from about 0.01 mol % to about 20 mol %; or from about 20 mol % to about 30 mol %. The control system 190 intermittently, periodically, or continuously adjusts, alters, modulates, or controls the concentration of the diluent(s) in the upper chamber 33 from about 1 mol % to about 99.9 mol %; from about 50 mol % to about 99.9 mol %; from about 60 mol % to about 90 mol %; from about 70 mol % to about 99 mol %; or from about 70 mol % to about 80 mol %.

The first gaseous chemical species is added to the upper portion of the chamber 33 via fluid conduit 284 at a temperature below its thermal decomposition temperature. The fluid conduit 284 may introduce the first gaseous chemical species at one or more points in the upper chamber 33 including one or more points in the vapor space of the upper chamber 33 and/or one or more points submerged in the mechanically fluidized particulate bed 20. The thermal decomposition temperature and consequently the temperature at which the first gaseous chemical species is added to the upper portion of the chamber 33 depends upon both the operating pressure of the upper portion of the chamber 33 and the composition of the first gaseous chemical species. In some instances, the first gaseous chemical species may be added to the upper chamber 33 and/or the mechanically fluidized particulate bed 20 at a temperature that is about 10° C. to about 500° C.; about 10° C. to about 400° C.; about 10° C. to about 300° C.; about 10° C. to about 200° C.; or about 10° C. to about 100° C. less than its thermal decomposition temperature. In other instances, the first gaseous chemical species can be introduced to the upper chamber 33 and/or the mechanically fluidized particulate bed 20 at a temperature of from about 10° C. to about 450° C.; about 20° C. to about 375° C.; about 50° C. to about 275° C.; about 50° C. to about 200° C.; or about 50° C. to about 125° C.

In some instances, the temperature of the first gaseous chemical species and the one or more diluent(s) may be selected to maintain a desired temperature in the upper chamber 33. In some instances, the temperature of the first gaseous chemical species and the one or more diluent(s), if present, may be introduced to the mechanically fluidized particulate bed 20 at a temperature slightly below the thermal decomposition temperature of the first gaseous chemical species. Such advantageously minimizes the heat load on the heater 14. In some instances, the control system 190 maintains the temperature in the upper chamber 33 using one or more cooling features 35. At times, the control system 190 maintains the temperature of the gas in the upper chamber 33 below the thermal decomposition temperature of the first gaseous chemical species to reduce the likelihood of second species deposition or of poly-powder formation within the upper chamber 33 in locations external to the mechanically fluidized particulate bed 20. In some instances, the control system 190 maintains the temperature in the upper chamber 33 below the thermal decomposition temperature of the first chemical species by controlling the rate of heat removal through cooling features 35 and/or other thermal energy transfer systems or devices. The control system 190 can maintain the temperature of the gas in the upper chamber at less than about 500° C.; less than about 400° C., or less than about 300° C. In some instances, to reduce the power required by the thermal energy emission device 14, the control system 190 can maintain the temperature of the gas in the upper chamber 33 at the highest temperature at which substantially no second species deposits or polysilicon powder forms.

The control system 190 controls the addition of the one or more diluent(s) to the upper chamber 33 and/or the mechanically fluidized particulate bed 20 via inlet 286. At times, the control system 190 may halt the flow of the one or more diluent(s) to the upper chamber 33 and/or mechanically fluidized particulate bed 20. The control system 190 can maintain the temperature of the one or more diluent(s) added to the upper chamber 33 and/or mechanically fluidized particulate bed 20 at the same or different from the temperature of the first gaseous chemical species added to the upper chamber and/or the mechanically fluidized particulate bed 20.

In at least some instances, the control system 190 maintains the temperature of the one or more diluent(s) added to the upper chamber 33 and/or the mechanically fluidized particulate bed 20 below the thermal decomposition temperature of the first gaseous chemical species. The control system 190 maintains the temperature of the one or more diluent(s) added to the upper chamber 33 at about 10° C. to about 500° C.; about 10° C. to about 400° C.; about 10° C. to about 300° C.; about 10° C. to about 200° C.; or about 10° C. to about 100° C. less than the thermal decomposition temperature of the first chemical species. In other instances, the control system 190 maintains the temperature of the one or more diluent(s) added to the upper chamber 33 and/or the mechanically fluidized particulate bed 20 from about 10° C. to about 450° C.; about 20° C. to about 375° C.; about 50° C. to about 325° C.; about 50° C. to about 200° C.; or about 50° C. to about 125° C.

At times, the first gaseous chemical species and the one or more optional diluent(s) may be added to the upper chamber 33 and/or mechanically fluidized particulate bed 20 on a continuous or near-continuous basis. When introduced to the mechanically fluidized particulate bed 20 and then heated to a temperature in excess of the thermal decomposition temperature of the first gaseous chemical species, the first chemical species thermally decomposes, depositing the second chemical species on the surface of the particulates in the mechanically fluidized particulate bed 20.

Measuring the partial pressure of the first gaseous chemical species in the gas contained in the upper chamber 33 in combination with the total pressure in the upper chamber 33 and the feed rates of first gaseous chemical species to the upper chamber 33, provides an indication of the quantity of first chemical species thermally decomposed. As the partial pressure of the first gaseous chemical species varies in the upper chamber 33, the control system 190 may intermittently, periodically, or continuously introduce less or additional first gaseous chemical species to the upper chamber to maintain a desired gas composition. The control system 190 may intermittently, periodically, or continuously transfer additional first chemical species from the reservoir 272 or one or more diluent(s) from the reservoir 278 to the upper portion of the chamber 33 to maintain a desired first chemical species partial pressure or gas composition in the upper chamber 33.

As the second chemical species deposits on the surface of the particles in the particulate bed 20, at least some of the plurality of coated particles 22 (i.e., those having greater quantities of second chemical species disposed thereupon and hence larger diameter) will tend to “float” within, or rise to the surface of, the particulate bed 20. The control system 190 removes coated particles 22, which particles may be removed on from the mechanically fluidized particulate bed 20 on an intermittent, periodic or continuous basis via the coated particle overflow conduit 132.

At times, spontaneous self-nucleation of the second chemical species and physical abrasion of the second chemical species within the mechanically fluidized particulate bed 20 generate sufficient seed particulates for continuous operation of the mechanically fluidized particulate bed 20. In such instances, the control system 190 may suspend the addition of fresh particulates 92 from the particle feed system 90 to the mechanically fluidized particulate bed 20. At other times, spontaneous self-nucleation of the second chemical species and physical abrasion of the second chemical species within the mechanically fluidized particulate bed 20 may be insufficient for continuous operation of the mechanically fluidized particulate bed 20. In such instances, the control system 190 intermittently, periodically, or continuously adds fresh particulates 92 from the particle feed system 90 to the mechanically fluidized particulate bed 20.

The substantially continuous addition of the first gaseous chemical species to the upper chamber 33 and/or the mechanically fluidized particulate bed 20 advantageously permits the substantially continuous production of coated particles 22. The substantially continuous addition of the first gaseous chemical species to the upper chamber 33 and/or the mechanically fluidized particulate bed 20 advantageously achieves a single stage overall conversion of the first gaseous chemical species to the second chemical species of greater than about 50%; greater than about 55%; greater than about 60%; greater than about 65%; greater than about 70%; greater than about 75%; greater than about 80%; greater than about 85%; greater than about 90%; greater than about 95%; or greater than about 99%:

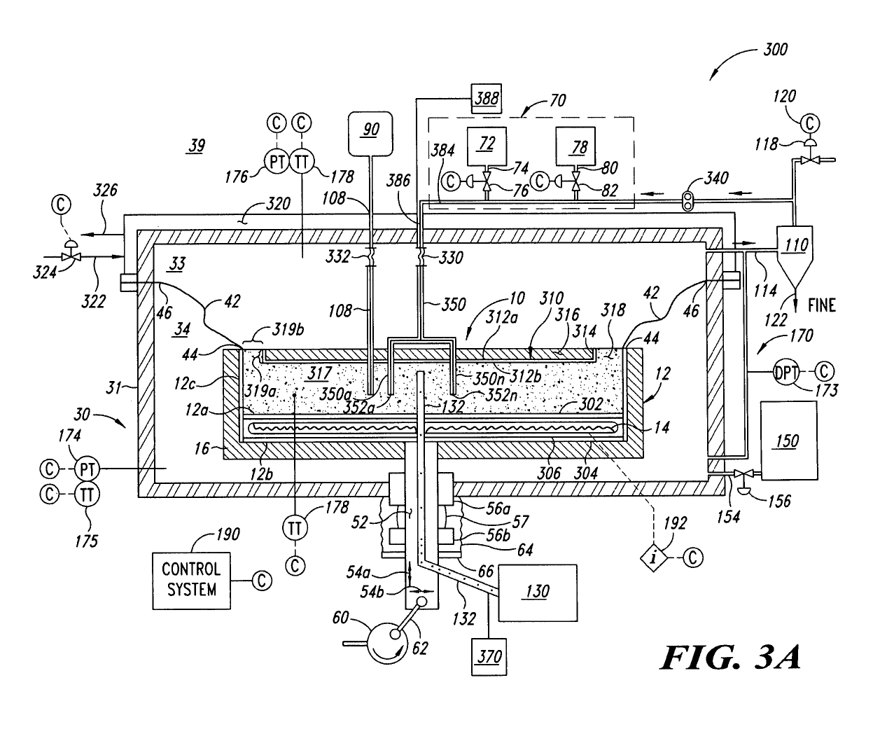

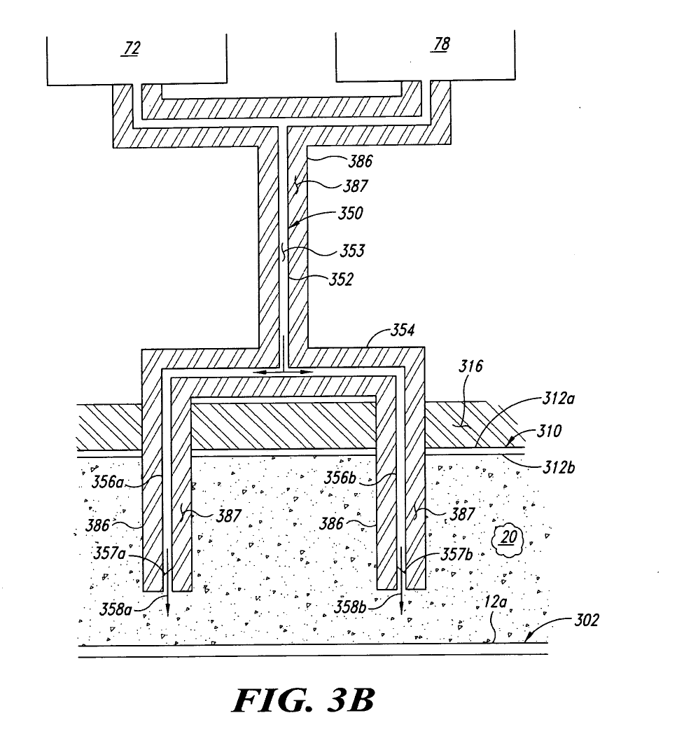

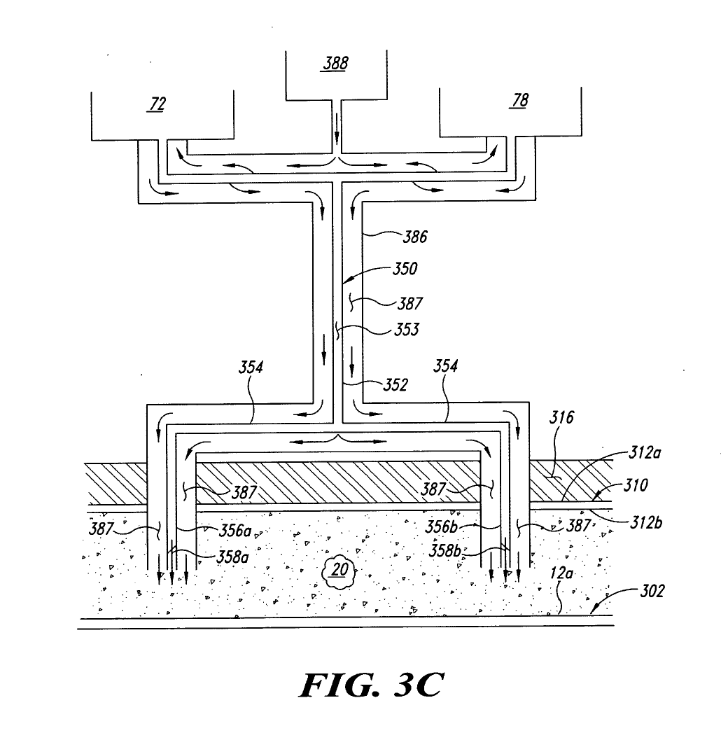

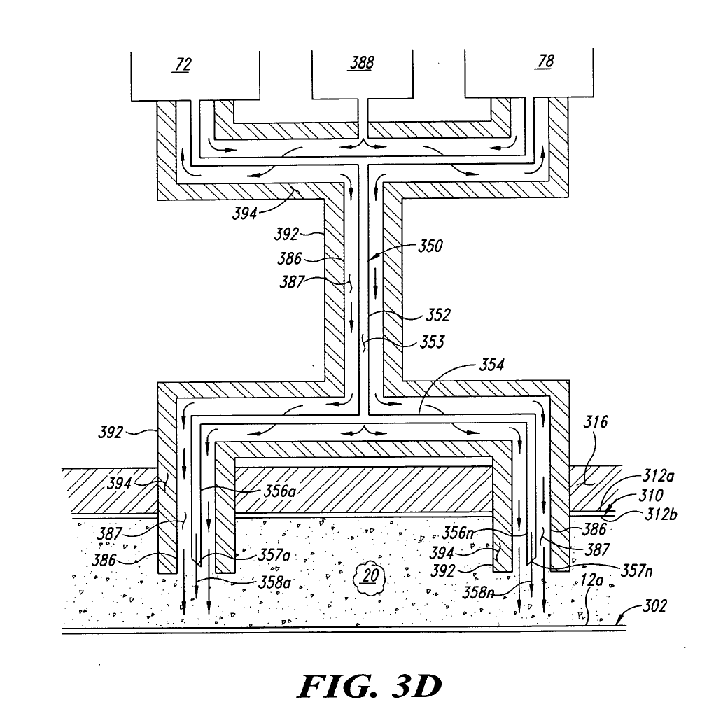

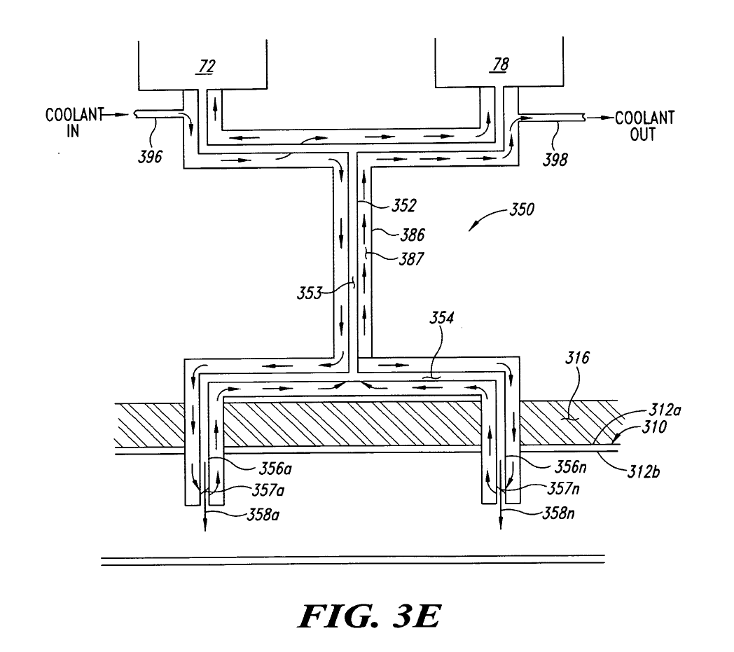

FIG. 3A shows another illustrative mechanically fluidized bed reactor 300 that includes a different configuration in which the pan 12 includes a major horizontal surface 302 and a second horizontal surface 304 having an interstitial space 306 formed therebetween in which the one or more thermal energy emission devices 14 are located, according to an embodiment. In addition, the pan 12 further includes a cover 310 that includes a raised lip 314 and at least one insulative layer 316. The cover 310 is geometrically similar to, but smaller, than the peripheral wall 12c of the pan 12, forming an annular gap 318 having a gap height 319a and a gap width 319b between the cover 310 and the peripheral wall 12c of the pan 12. The cover 310 and the pan 12 define at least some of the boundaries about a retention volume 317 that retains the mechanically fluidized particulate bed 20.

The pan 12 includes a major horizontal surface 302 that supports the mechanically fluidized particulate bed 20. In at least some implementations, the major horizontal surface 302 is a silicon or silicon coated surface that is provided prior to the introduction of any particulates or first gaseous chemical species to the reactor 300. At times, the major horizontal surface 302 may be substantially pure silicon. In some instances the major horizontal surface 302 may be selectively removable from the pan 12, for example to replace a worn surface or to provide access for maintenance, repair, or replacement of the one or more thermal energy emission devices 14 disposed in the space 306 beneath the major horizontal surface 302. At other times, the major horizontal surface 302 may be integrally formed and non-removable from the pan 12. At times, the perimeter wall 12c of the pan extends beyond the major horizontal surface 302 and terminates at the second horizontal surface 304, forming the interstitial space 306 between the major horizontal surface 302 and the second horizontal surface 304. The pan 12 may have any shape or geometric configuration. For example, the pan 12 may have a generally circular shape with a diameter of from about 1 inch to about 120 inches; about 1 inch to about 96 inches; about 1 inch to about 72 inches; about 1 inch to about 48 inches; about 1 inch to about 24 inches; or about 1 inch to about 12 inches. The perimeter wall of the pan 12c can extend upwardly from the upper surface 12a of the second horizontal surface 304 the pan 12 to a height greater than the depth of the mechanically fluidized particulate bed 20 retained on the major horizontal surface 302.

In some instances, the height of the perimeter wall 12c may be set at a distance from the upper surface 12a of the major horizontal surface 302 of the pan 12 such that a portion of the particulates forming the particulate bed 20 flow over the top of the perimeter wall for capture by the coated particle collection system 130. The perimeter wall 12c can extend above the upper surface 12a of the major horizontal surface 302 by a distance of from about 0.25 inches to about 20 inches; about 0.50 inches to about 10 inches; about 0.75 inches to about 8 inches; about 1 inch to about 6 inches; or about 1 inch to about 3 inches.

The portions of the pan 12 contacting the mechanically fluidized particulate bed 20, including at least a portion of the perimeter wall 12c and the major horizontal surface 302 may include one or more abrasion or erosion resistant materials that are also resistant to chemical degradation. In at least some instances, the major horizontal surface 302 can be an integral (i.e., without open perforations, apertures or similar open penetrations), unitary and single piece member that is either selectively removable from the pan 12 or integrally formed with the pan 12. Alternatively, the pan 12 may have one or more sealed apertures, for example where the hollow coated particle overflow conduit 132 passes through the bottom of the pan 12. In such instances, the joint between the bottom of the pan 12 and the penetrating member (e.g., the hollow coated particle overflow conduit 132) can be sealed using an appropriate sealer and/or via thermal fusion, welding, or similar. Use of a pan 12 having appropriate physical and chemical resistance reduces the likelihood of contamination of the mechanically fluidized particulate bed 20 by contaminants, such as metal ions, that are released from the pan 12. In some instances, the pan 12 can comprise an alloy such as a graphite alloy, a nickel alloy, a stainless steel alloy, or combinations thereof. In at least some instances, the pan 12 can comprise molybdenum or a molybdenum alloy.

At times, a liner or similar layer or coating of resilient material that resists abrasion or erosion, reduces unwanted product buildup, or reduces the likelihood of contamination of the mechanically fluidized particulate bed 20 may be deposited on all or a portion of the major horizontal surface 302 and/or pan walls 12c that contact the mechanically fluidized particulate bed 20. In some instances, all or a portion of at least the upper surface 12a of the major horizontal surface 302 and/or the perimeter walls 12c of the pan, may comprise silicon or high purity silicon (e.g., >99.0% Si, >99.9% Si, or >99.9999% Si). It should be understood that the silicon comprising the bottom of the pan is present prior to the first use of the pan 12, in other words, the silicon comprising the pan is different from the non-volatile second chemical species created by the thermal decomposition of the first gaseous chemical species in the mechanically fluidized particulate bed 20.

In some instances, the liner, layer, or coating in all or a portion of the pan 12 can include: a graphite layer, a quartz layer, a silicide layer, a silicon nitride layer, or a silicon carbide layer. In some instances, a metal silicide may be formed in situ by reaction of silane with iron, nickel, and other metals in the pan 12. A silicon carbide layer, for example, is durable and reduces the tendency of metal ions such as nickel, chrome, and iron from the metal comprising the pan to migrate into, and potentially contaminate, the plurality of coated particles 22 in the pan 12. In one example, the pan 12 comprises a 316 stainless steel pan with a silicon carbide layer deposited on at least a portion of the upper surface 12a of the major horizontal surface 302 and the perimeter wall 12c contacting the mechanically fluidized particulate bed 20. In another example, the pan 12 comprises a 316 stainless steel major horizontal surface 302 that is overlaid with a selectively removable silicon liner that is substantially pure silicon (i.e., >99.9% Si).

At times, the liner or layer may be physically coupled to the major horizontal surface 302 and/or pan 12 using one or more mechanical fasteners, for example one or more threaded fasteners, bolts, nuts, or the like. At other times, the liner or layer may be physically coupled to the major horizontal surface 302 and/or pan 12 using one or more spring clips, clamps, or similar devices. At yet other times, the liner or layer may be physically coupled to the major horizontal surface 302 and/or pan 12 using metal fusion, one or more adhesives or similar bonding agents.

One or more thermal energy emission devices 14 are disposed in the chamber 306 formed by the major horizontal surface 302, the second horizontal surface 304 and the perimeter wall 12c of the pan 12. At times, the thermal output of the one or more thermal energy emission devices 14 may be limited, regulated, or controlled by the control system 190 to prevent thermal damage to the pan 12. This is of particular importance when a non-metallic major horizontal surface 302 or a non-metallic lined major horizontal surface 302 is used. In at least some implementations, the interstitial space 306 can be hermetically sealed from the upper chamber 33, the lower chamber 34, or both the upper and the lower chambers to prevent the ingress of polysilicon or other gases or gas borne particulates into the interstitial space 306 or the egress of insulation materials from interstitial space into the upper chamber 33 or the lower chamber 34. In operation, the thermal energy emission devices 14 are controlled by the control system 190 to increase the temperature of the mechanically fluidized particulate bed 20 above the thermal decomposition temperature of the first gaseous chemical species.

An insulative layer 16 may be disposed about all or a portion of the exterior surfaces of the pan 12 and flexible membrane 42, including the perimeter wall 12c and the lower surface 12b of the second horizontal surface 304. The insulative layer 16 can limit or otherwise restrict the flow or transfer of thermal energy from the thermal energy emission devices 14 to the upper chamber 33 and lower chamber 34. Further, the at least one insulative layer 316 positioned on the cover 310 can limit or otherwise restrict the flow or transfer of thermal energy from the mechanically fluidized particulate bed 20 to the upper chamber 33. At times, a gas impermeable, rigid, covering, for example a metallic cover or structure, may at least partially enclose the insulative layer 16. At other times, the insulative layer 16 may include a gas impermeable flexible insulative layer 16, for example insulation blankets with or without jacketing. Such gas impermeable coverings or jackets minimize the likelihood of deposition of polysilicon or other gas-borne contaminants in the insulative layer 16. At times, the temperature of the exterior surface of the insulative layer 16 exposed to the lower chamber 34 is less than the thermal decomposition temperature of the first gaseous chemical species. The cover 310 is disposed in the upper chamber 34 and is positioned a distance above the upper surface 12a of the major horizontal surface 302 of the pan 12. In operation, the cover 310 advantageously assists in both retaining thermal energy in the mechanically fluidized particulate bed 20 and promoting extended contact and plug flow contact between the first gaseous chemical species and the mechanically fluidized particulate bed 20.

The cover includes an upper surface 312a, a lower surface 312b and a peripheral edge 314, some or all of which may be upturned to provide a peripheral wall. The peripheral edge 314 of the cover 310 is spaced inward of the peripheral wall 12c of the pan 12 forming a peripheral gap 318 between the peripheral edge 314 of the cover 310 and the perimeter wall 12c of the pan 12. In at least some implementations, the peripheral gap 318 can have a gap height 319a equal to the height of the wall formed by the upturned peripheral edge 314 of the cover 310. At least a portion of the lower surface 312b of the cover 310 may include a continuous layer of at least one of: a metal silicide, graphite, quartz, silicon, silicon carbide, or silicon nitride disposed on at least a portion of the lower surface of the cover exposed to the mechanically fluidized particulate bed.

The volumetric displacement of the mechanically fluidized particulate bed 20 in operation may be used to determine one or more dimensions of the peripheral gap 318. Such prevents expelling hot gas from the mechanically fluidized particulate bed 20 to the upper chamber 33 on the upstroke of each oscillation or vibration cycle and permits the mechanically fluidized particulate bed 20 to draw any such expelled hot gas retained in the volume formed by the peripheral gap 318 back into the particulate bed 20 on the downstroke of each oscillation or vibration cycle.

By way of example, assuming a mechanically fluidized particulate bed 20 diameter of 12 inches and an operating displacement of 0.1 inch, the total displacement volume of the mechanically fluidized particulate bed 20 is given by the following equation:

Volume=πr₍ₚₐₙ₎²×displacement=11.3 in³ (1)

Assuming a peripheral gap width 319b of 0.5 inches (i.e., a cover diameter of 11 inches), the peripheral gap height 319a is determined using the following equation:

height=Volume/(πr₍ₚₐₙ₎²−πr_{(cover)}²)=0.626 in. (2)

At times, the dimensions of the peripheral gap 318 (e.g., the width 319a) are determined based on the gas flow of the unreacted first gaseous chemical species and any byproduct gases from the mechanically fluidized particulate bed 20. For example, the width 319a may be determined based on maintaining a gas flow velocity through the peripheral gap 318 less than a defined threshold at which particles having one or more physical properties are retained in the mechanically fluidized particulate bed 20. In at least one embodiment, the width 319b may be based at least in part on maintaining a gas velocity below a threshold at which particulates are entrained and carried from the mechanically fluidized particulate bed 20. For example, the gap width 319a may be determined based on not entraining particulates having at least one physical property greater than one or more defined parameters (e.g., a particulate diameter greater than a defined diameter, a particulate density greater than a defined density). At times, the gas velocity in the peripheral gap 318 can be low enough to retain coated particles having a diameter greater than about 1 micron; about 5 microns; about 10 microns; about 20 microns; about 50 microns; about 80 microns; or about 100 microns to about 50 microns; about 80 microns; about 100 microns; about 120 microns; about 150 microns; or about 200 microns in the mechanically fluidized particulate bed 20. In various embodiments, the peripheral gap width 319b can be about 1/16 inch or more; about ⅛ inch or more; about ¼ inch or more; about ½ inch or more; or about 1 inch or more.

Selective removal of fines from system 300, based on particle diameter, by filtration of the gas mixture or the exhaust gas is possible because the velocity of the off-gas exiting the mechanically fluidized bed can be controlled by adjusting the size of the peripheral gap 318 that fluidly connects the mechanically fluidized particulate bed 20 with the upper portion 33 of the chamber 32. Increasing the off-gas velocity by reducing the size of the peripheral gap 318 will tend to entrain and remove larger diameter fine particles and/or particulates from the mechanically fluidized particulate bed 20 into upper portion 33 of the chamber 32. Conversely, decreasing the off-gas velocity by increasing the size of the peripheral gap 318 will tend to entrain and remove smaller diameter particles and/or particulates from the mechanically fluidized particulate bed 20 into upper portion 33 of the chamber 32.

At times, the cover 310 includes a thermally reflective material to return at least a portion of the thermal energy radiated by the mechanically fluidized particulate bed 20 back to the mechanically fluidized particulate bed 20. To further reduce the flow of thermal energy from the mechanically fluidized particulate bed 20 to the upper chamber 34, a thermally insulating material 316 may be disposed proximate the cover 310 on the surface opposite the mechanically fluidized particulate bed 20. At other times, at least a portion of the lower surface 312b of the cover 310 contacting the mechanically fluidized particulate bed 20 may include silicon or high-purity silicon (e.g., 99+%, 99.5+%, or 99.9999+% silicon). Such silicon construction is present prior to the first use of the cover 310 and is not attributable to deposition of the second chemical species on the lower surface 312b of the cover 310.

The thermally insulating material 316 may, for instance be a glass-ceramic material (e.g., Li₂O×Al₂O₃×nSiO₂-System or LAS System) similar that used in “glass top” stoves where the electrical heating elements are positioned beneath a glass-ceramic cooking surface. In some situations, the thermally insulating material 316 may include one or more rigid or semi-rigid refractory type materials such as calcium silicate. In some situations, the thermally insulating material 316 may include one or more flexible insulative materials, for example ceramic insulation blankets or other similar non-thermally conductive rigid, semi-rigid, or flexible coverings.

In operation, although the settled particulate bed typically does not contact the lower surface 312b of the cover 310, it is advantageous of the mechanically fluidized particulate bed 20 touches (e.g., lightly, firmly) the lower surface 312b of the cover 310 when the bed is fluidized. In such instances the contact of the mechanically fluidized particulate bed 20 with the lower surface 312b of the cover 310 beneficially prevents short circuiting of the first gaseous chemical species around (as opposed to through) the mechanically fluidized particulate bed 20. Additionally, by contacting (e.g., lightly, firmly) the lower surface 312b of the cover 310, deposition of the second chemical species on the lower surface 312b of the cover 310 is beneficially reduced. Further, by only lightly touching or by just contacting the lower surface 312b of the cover 310, the fluid nature of the mechanically fluidized particulate bed 20 is not compromised or limited in any way.

FIG. 3B depicts an illustrative gas distribution system 350, according to an embodiment. In some implementations, the gas distribution system 350 includes at least one inner tube member 352 that defines a fluid passage 353. The fluid passage 353 fluidly couples to one or more distribution headers 354. One or more injectors 356a-356n (collectively “injectors 356”) each having a least one respective outlet 357a-357n at a distal end thereof, fluidly couple at a proximal end to the one or more distribution headers 354. The injectors 356 project through the cover member 310 and extend a distance into the mechanically fluidized particulate bed 20. Gas flow 358a-358n from the one or more outlets 357 enters the mechanically fluidized particulate bed 20 at a location between the upper surface 12a of the major horizontal member 302 and the lower surface 312b of the cover 310. The injectors 356 can be disposed in any random or geometric pattern or configuration in the mechanically fluidized particulate bed 20. At times, the outlets on each respective one of the injectors 356 may be positioned at the same or different elevations within the mechanically fluidized particulate bed 20.

The injectors 356 are formed using one or more materials providing satisfactory chemical/corrosion resistance and structural integrity at the operating pressures and temperatures of the mechanically fluidized particulate bed 20. For example, the injectors may be fabricated using a high temperature stainless steel or nickel alloy. For example, an INSULON® shaped-vacuum thermal barrier using a sealed vacuum chamber about the injector as provided by Concept Group Incorporated (West Berlin, N.J.). In some implementations the interior and/or exterior surfaces of the injector 356 may be coated, lined, or layered with a coating such as silicon, silicon carbide, graphite, silicon nitride, or quartz.

An outer tube member 386 surrounds at least the injector 356 and may optionally surround all or a portion of the one or more distribution headers 354 and/or all or a portion of the inner tube member 352. The inner tube member 352 and the outer tube member 386 do not contact each other except at the end of the outer tube member 386 in the mechanically fluidized particulate bed 20, thereby forming a close-ended void space 387 between the inner tube member 352 and the outer tube member 386. At times, the close-ended void space 387 contains an insulative vacuum. At other times, the close-ended void space 387 contains one or more insulative materials. The close-ended void space 387 advantageously insulates the inner tube member from the high temperature mechanically fluidized particulate bed 20 and optionally the elevated temperature upper chamber 33, thereby minimizing or preventing the thermal decomposition of the first gaseous chemical species prior to introduction to the mechanically fluidized particulate bed 20. In some implementations, the close-ended void space 387 extends beyond the one or more outlets 357 of each of the injectors 356.

In some instances, the injectors 356 sealingly attach or are physically coupled to the cover 310 to prevent the escape of gases from the mechanically fluidized particulate bed 20. The gas distribution system 350 can include one or more flexible connectors 330 (shown in FIG. 3A, omitted from FIG. 3B for clarity) to isolate the gas feed system 70 from the vibratory or oscillatory movement of the pan 12 during operation.

FIG. 3C depicts another gas distribution system 350, according to an illustrative embodiment. In FIG. 3C, the inner tube member 352 and the outer tube member 386 do not contact each other, thereby forming an open-ended void space 387 between the inner tube member 352 and the outer tube member 386. An inert fluid (i.e., liquid or gas) flows from an inert fluid reservoir 388 through the open-ended void space 387. The inert fluid passing through the open-ended void space 387 insulates the first gaseous chemical species in the fluid passage 353 from heating when the first gaseous chemical species passes through the inner tube member 352, the distribution header 354 and the injectors 356. The inert fluid exits the open-ended void space 387 and flows into the mechanically fluidized particulate bed 20.

FIG. 3D depicts another gas distribution system 350, according to an illustrative embodiment. In FIG. 3D, the inner tube member 352 and the outer tube member 386 do not contact each other, thereby forming an open-ended void space 387 between the inner tube member 352 and the outer tube member 386. A second outer tube member 392 is disposed about all or a portion of the outer tube member 386. The second outer tube member 392 and the outer tube member 386 contact each other at a location proximate the one or more outlets 357 on each of the injectors 356 to form a close-ended void space 394 that surrounds the open-ended void space 387 that surrounds the inner tube member 352, the distribution header 354, and the injectors 356.

In some instances, the close-ended void space 394 contains an insulative vacuum. In some instances, the close-ended void space 394 contains an insulative material. An inert fluid (i.e., liquid or gas) flows from an inert fluid reservoir 388 through the open-ended void space 387. In some implementations, the close-ended void space 394 extends beyond the one or more outlets 357 of each of the injectors 356. The insulative vacuum or insulative material in the close-ended void space 394, in conjunction with the inert fluid passing through the open-ended void space 387 insulates the first gaseous chemical species in the fluid passage 358 from heating when the first gaseous chemical species passes through the inner tube member 352, the distribution header 354 and the injectors 356. The inert fluid exits the open-ended void space 387 and flows into the mechanically fluidized particulate bed 20.

FIG. 3E depicts another illustrative gas distribution system 350, according to an embodiment. In some implementations, the gas distribution system 350 includes at least one inner tube member 352 that defines a fluid passage 353. The fluid passage 353 fluidly couples to one or more distribution headers 354. Gas flow 358a-358n from the one or more outlets 357 on each of the injectors 356 enters the mechanically fluidized particulate bed 20 at a location between the upper surface 12a of the major horizontal member 302 and the lower surface 312b of the cover 310. The injectors 356 can be disposed in any random or geometric pattern or configuration in the mechanically fluidized particulate bed 20. At times, the outlets on each respective one of the injectors 356 may be positioned at the same or different elevations within the mechanically fluidized particulate bed 20.

The outer tube member 386 surrounds at least the injector 356 and may optionally surround all or a portion of the one or more distribution headers 354 and/or all or a portion of the inner tube member 352. The inner tube member 352 and the outer tube member 386 do not contact each other except at the end of the outer tube member 386 in the mechanically fluidized particulate bed 20, thereby forming a close-ended void space 387 between the inner tube member 352 and the outer tube member 386. A fluid (i.e., liquid and/or gas) coolant is introduced via one or more inlets 396 to the close-ended loop. The coolant passes through the close-ended void and cools the injectors 356 and, optionally, the inner tube member 352 and/or the distribution header 354. The fluid coolant is removed from the close-ended void space via one or more fluid outlets 398.

The coolant flowing through the close-ended void space 387 advantageously insulates the inner tube member from the high temperature mechanically fluidized particulate bed 20 and optionally the elevated temperature upper chamber 33, thereby minimizing or preventing the thermal decomposition of the first gaseous chemical species prior to introduction to the mechanically fluidized particulate bed 20. Returning to FIG. 3A, the gas distribution system 350 can include any number of distribution headers 354 and any number of injectors 356 fluidly coupled to the distribution headers 354 and extending at least partially into the mechanically fluidized particulate bed 20. Each of the injectors 356 can include one or more outlets 357 through which the first gaseous chemical species is introduced to the mechanically fluidized particulate bed 20. In some instances, the injectors 356 are insulated to prevent the premature thermal decomposition of the first gaseous chemical species prior to discharge into the mechanically fluidized particulate bed 20. In some instances, one or more fluid coolants are passed across at least the injectors 356 to prevent the premature thermal decomposition of the first gaseous chemical species prior to discharge into the mechanically fluidized particulate bed 20. If the first gaseous chemical species prematurely decomposes in the injector 356, the second chemical species can deposit within, and ultimately foul the internal passages of some or all of the number of injectors 356.

At times, the injectors 356 are positioned to discharge the first gaseous chemical species and any diluent(s) at one or more central locations within the mechanically fluidized particulate bed 20 such that the first gaseous chemical species flows radially outward through the mechanically fluidized particulate bed 20. At times, the injectors 356 are positioned about the periphery of the cover 310 to discharge the first gaseous chemical species and any diluents at peripheral locations within the mechanically fluidized particulate bed 20 such that the first gaseous chemical species flows radially inward through the mechanically fluidized particulate bed 20. At times, the first gaseous chemical species can flow in a plug flow regime radially inward or radially outward through the mechanically fluidized particulate bed 20.

An optional inert gas system 370 can provide a flow of inert gas as a purge in the coated particle overflow conduit 132. Although not shown in FIG. 3A, the optional inert gas system can include an inert gas reservoir, fluid conduits, gas flow, pressure, and/or temperature monitor and control devices, The inert gas can include, but is not limited to one or more of the following: include at least one of: hydrogen, nitrogen, helium, or argon. The inert purge gas flows countercurrent to the coated particles 22 that are removed or separated from the mechanically fluidized particulate bed 20 and discharges into the mechanically fluidized particulate bed 20 via the particle overflow tube. The use of an inert purge gas beneficially limits the removal of small diameter coated particles from the mechanically fluidized particulate bed 20 and also reduces the quantity of first gaseous chemical species and any diluent(s) removed from the mechanically fluidized particulate bed 20 via the coated particle overflow conduit 132.

At times, the flow rate and/or velocity of the inert gas through the coated particle overflow conduit 132 can be altered, adjusted, or controlled, for example using control system 190, to control the size of the coated particles 22 removed from the mechanically fluidized particulate bed 20, or alternatively to control the size of coated particles 22 returned to the mechanically fluidized particulate bed 20 via entrainment in the inert gas flowing countercurrent in the coated particle overflow conduit 132. For example, the flow rate or velocity of the inert gas through the coated particle overflow conduit 132 may be altered, adjusted, or controlled, for example by the control system 190, such that coated particles 22 having a diameter of less than about 600 micrometers (μm); less than about 500 μm; less than about 300 μm; less than about 100 μm; less than about 50 μm; less than about 20 μm; less than about 10 μm; or less than about 5 μm are entrained in the inert gas and returned to the mechanically fluidized particulate bed 20 via the coated particle overflow conduit 132.

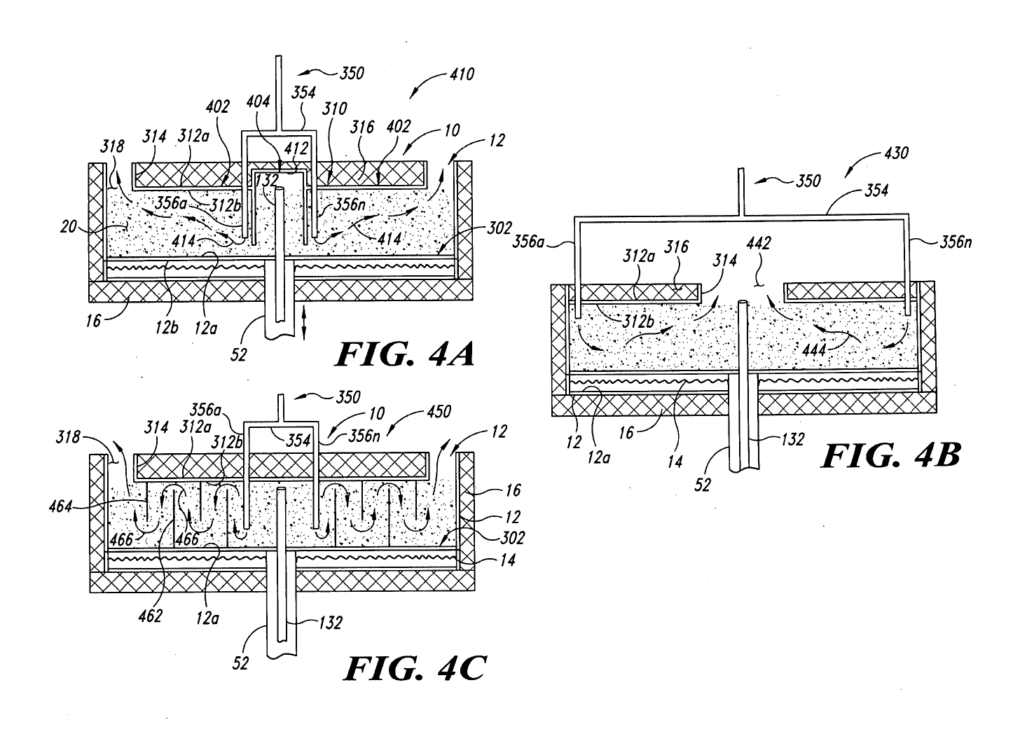

FIG. 4A shows an alternative cover 410 having a configuration useful with a mechanically fluidized bed reactor, according to one embodiment. For clarity, the gas distribution system 350 is depicted without outer tube member 386, however it should be understood that the gas distribution system 350 depicted in FIG. 4A may include any of the insulation or cooling systems depicted in FIGS. 3B-3E. The cover 410 includes a first portion 402 in which the lower surface 312b is positioned a first distance above the upper surface 12a of the major horizontal surface 302. The cover 410 also includes a second “top hat” portion 404 in which the lower surface 312b is positioned a second distance that is greater than the first distance above the upper surface 12a of the major horizontal surface 302. The second portion 404 is disposed about the coated particle overflow conduit 132. The second portion 404 of the cover 310 permits the mechanically fluidized particulate bed 20 to contact (e.g., lightly, firmly) the lower surface 312b of the first portion 402 of the cover 310 while still permitting the overflow of coated particles 22 into the coated particle overflow conduit 132.

The injectors 356a-356n discharge the first gaseous chemical species at one or more central locations in the mechanically fluidized particulate bed 20. The first gaseous chemical species and any diluent(s) follow a radially outward flow path 414 through the mechanically fluidized particulate bed 20. Exhaust gases, primarily any diluent(s) present in the gas feed and inert decomposition byproducts escape from the mechanically fluidized particulate bed 20 via the peripheral gap 318 between the cover 410 and the perimeter wall 12c. In at least some implementations, the velocity of the first gaseous chemical species and any diluent(s) through the mechanically fluidized particulate bed 20 establishes a substantially plug or transitional radially outward flow regime through the mechanically fluidized particulate bed 20.

FIG. 4B shows another alternative cover 430 having a configuration useful with a mechanically fluidized bed reactor, according to one embodiment. For clarity, the gas distribution system 350 is depicted without outer tube member 386, however it should be understood that the gas distribution system 350 depicted in FIG. 4B may include any of the insulation or cooling systems depicted in FIGS. 3B-3E. The cover 430 is disposed proximate or fixed to the perimeter wall 12c of the pan 12 and the upturned peripheral edge 314 of the cover 310 forms an aperture 442 above a portion of the mechanically fluidized particulate bed 20, for example above the central portion of the mechanically fluidized particulate bed 20 about the coated particle overflow conduit 132. In operation, the mechanically fluidized particulate bed 20 contacts the lower surface 312b of cover 430.

The injectors 356a-356n discharge the first gaseous chemical species at one or more peripheral locations in the mechanically fluidized particulate bed 20. The first gaseous chemical species and any diluent(s) follow radially inward flow path 444 through the mechanically fluidized particulate bed 20. Exhaust gases, primarily any diluent(s) present in the gas feed and inert decomposition byproducts escape from the mechanically fluidized particulate bed 20 via the aperture 442. In such an implementation, the volume formed by the aperture 442 area multiplied by the height 319b of the upturned peripheral edge 314 of the cover 310 may be equal to the displacement volume of the mechanically fluidized particulate bed 20. In at least some implementations, the velocity of the first gaseous chemical species and any diluent(s) through the mechanically fluidized particulate bed 20 establishes a substantially plug or transitional radially inward flow regime through the mechanically fluidized particulate bed 20.

By way of example, assuming the cover is proximate but not fixed to the peripheral wall, a mechanically fluidized particulate bed 20 diameter of 12 inches and an operating displacement of 0.1 inch, the total displacement volume of the mechanically fluidized particulate bed 20 is given by the following equation:

Volume=πr₍ₚₐₙ₎²×displacement=11.3 in³ (3)

Assuming a central aperture 452 diameter of 4 inches, the height 319b is determined using the following equation:

Height=Volume/πr₍ₐₚₑᵣₜᵤᵣₑ₎²)=0.9 in. (4)

FIG. 4C shows an alternative cover 450 having a configuration useful with a mechanically fluidized bed reactor, according to one embodiment. For clarity, the gas distribution system 350 is depicted without outer tube member 386, however it should be understood that the gas distribution system 350 depicted in FIG. 4C may include any of the insulation or cooling systems depicted in FIGS. 3B-3E. The cover 450 includes a number of concentric baffles 462 physically coupled to the upper surface 12a of the pan 12 and a number of concentric baffles 464 physically coupled to the lower surface 312b of the cover 310. At times, the lower concentric baffles 462 and the upper concentric baffles 464 may be configured concentric with the coated particle overflow conduit 132. At times, at least some of the concentric baffles 462 and at least some of the concentric baffles 464 may be wholly or partially constructed of silicon or high-purity silicon (e.g., >99% Si, >99.9% Si, or >99.9999% Si). At times, at least some of the concentric baffles 462 and at least some of the concentric baffles 464 may comprise silicon having a uniform thickness or a uniform density. Silicon on the concentric baffles 462 and concentric baffles 464 is present prior to the first use of the cover 310 and is not attributable to deposition of the second chemical species on the concentric baffles 462 and concentric baffles 464. Such baffles may be used in conjunction with the covers 310, 410, and 430 as depicted in FIGS. 3A, 4A, and 4B, respectively. In at least some implementations, the concentric baffles 462 and concentric baffles 464 are arranged in an alternating pattern to define a serpentine flow path through the mechanically fluidized particulate bed 20.

The injectors 356a-356n discharge the first gaseous chemical species at one or more central locations in the mechanically fluidized particulate bed 20. The first gaseous chemical species and any diluent(s) follow a radially outward serpentine flow path 466 around the concentric baffles 462 and concentric baffles 464 and through the mechanically fluidized particulate bed 20. Exhaust gases, primarily any diluent(s) present in the gas feed and inert decomposition byproducts escape from the mechanically fluidized particulate bed 20 via the peripheral gap 318 between the cover 450 and the perimeter wall 12c. In at least some implementations, the velocity of the first gaseous chemical species and any diluent(s) through the mechanically fluidized particulate bed 20 establishes a substantially plug or transitional serpentine, radially outward, flow regime through the mechanically fluidized particulate bed 20.

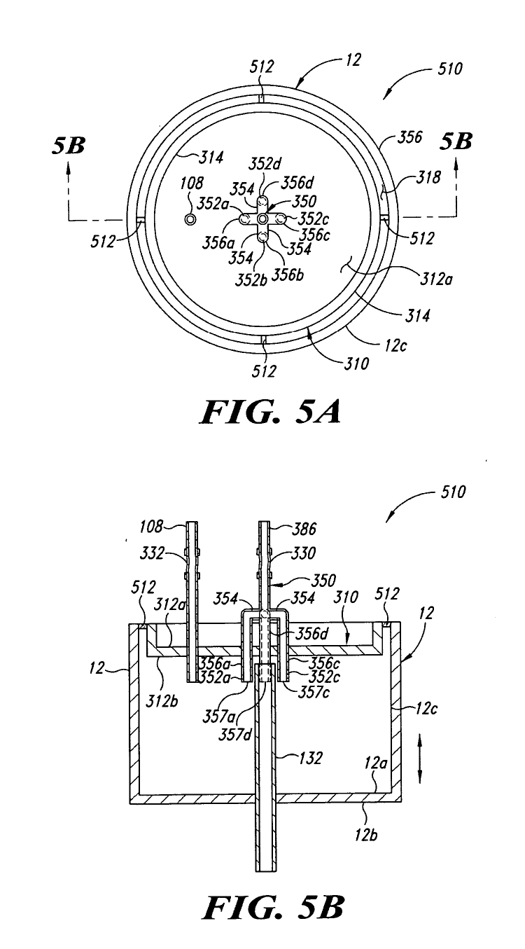

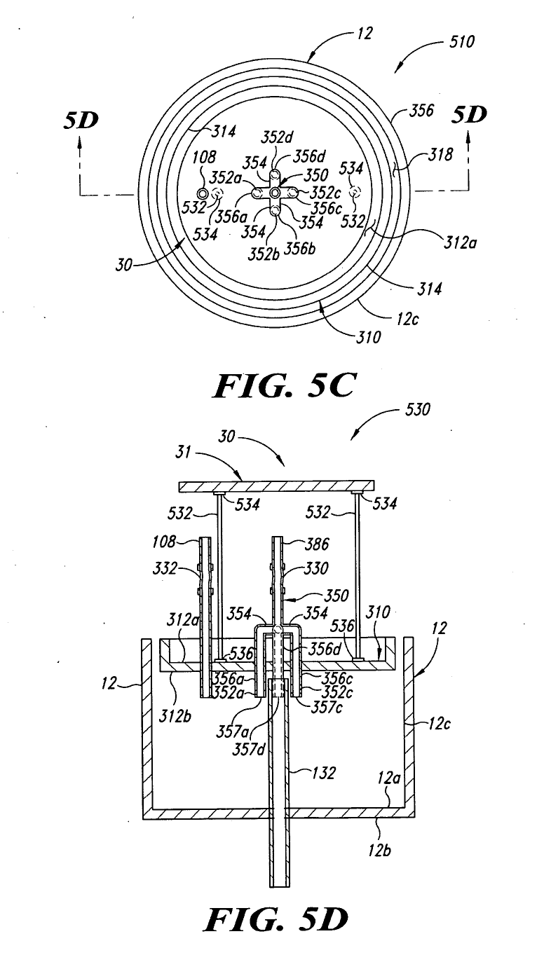

FIG. 5A and FIG. 5B show an illustrative cover arrangement 510 in which the cover 310 is physically affixed to the pan 12 via a number of attachment members 512a-512n (collectively, “attachment members 512”), according to an embodiment. The peripheral gap 318 separates the raised lip 314 (shaded) of the cover 310 from the perimeter wall 12c (shaded) of the pan 12. One or more attachment members 512 physically couple the cover 310 to the perimeter wall 12c. At times, the attachment members 512 may be non-detachably affixed to either the raised lip 314 of the cover 310 or the perimeter wall 12c, or both the raised lip 314 of the cover 310 and the perimeter wall 12c via one or more non-removable methods such as welding. At times, the attachment members 512 may be detachably affixed to either the raised lip 314 of the cover 310 or the perimeter wall 12c of the pan 12, or both the raised lip 314 of the cover 310 and the perimeter wall 12c of the pan 12 via one or more removable fasteners, for example one or more threaded fasteners and/or latches.

The attachment members 512 may include any rigid member capable of supporting the cover 310 and the associated fresh particulate feed hollow member 108 and the gas distribution system 350. In some instances, some or all of the attachment members 512 may include silicon or high-purity silicon (>99% Si, >99.9% Si, or >99.9999% Si) or graphite coated with silicon carbide. Since the cover 310 oscillates with the pan 12, flexible members 330 and 332 are disposed in the gas distribution header 354 and the hollow member 108, respectively.

FIG. 5C and FIG. 5D show an alternative illustrative cover arrangement 530 in which the cover 310 is physically affixed to the reactor vessel 31 via a number of attachment members 532a-532n (collectively, “attachment members 532”), according to an embodiment. In such implementations, the pan 12 retaining the mechanically fluidized particulate bed 20 oscillates while the cover 310 remains stationary. At times, the attachment members 532 may be permanently affixed to either the cover 310 or the reactor vessel 31, or both the cover 310 and the reactor vessel 31 via one or more permanent methods such as welding. At times, the attachment members 532 may be detachably affixed to either the cover 310 or the reactor vessel 31, or both the cover 310 and the reactor vessel 31 via one or more removable fasteners, for example one or more threaded fasteners and/or latches. Note that affixing the cover 310 to the reactor vessel 31 can eliminate the need for flexible connections 330 and 332.

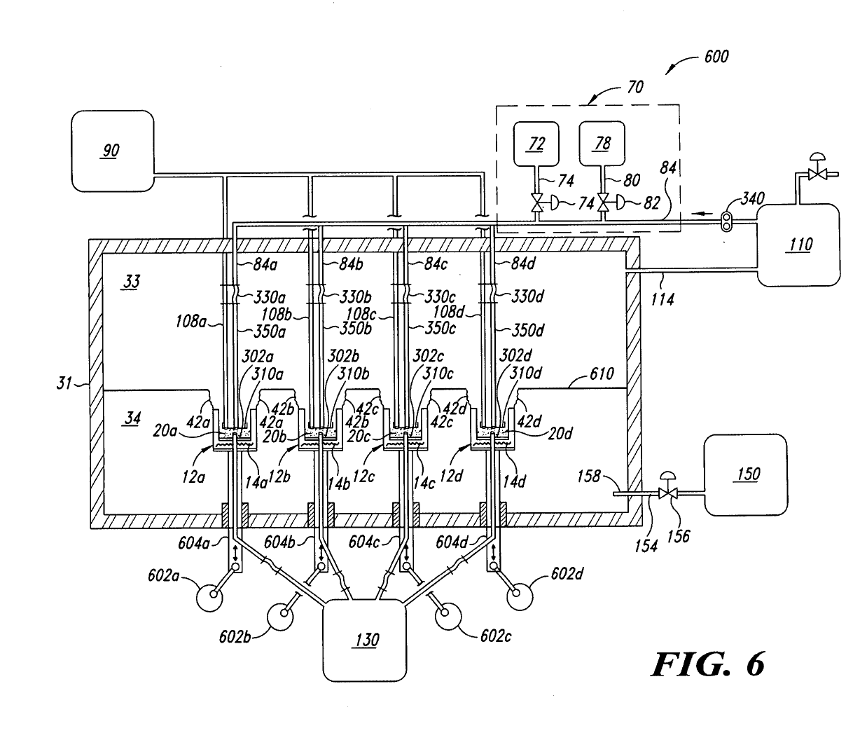

FIG. 6 shows another illustrative mechanically fluidized bed reactor 600 that includes plurality of pans 12a-12n (collectively, “pans 12”), according to an embodiment. For clarity, the gas distribution systems 350a-350n in FIG. 6 are depicted without outer tube member 386, however it should be understood that any or all of the gas distribution systems 350a-350n depicted in FIG. 6 may include any of the insulation or cooling systems depicted in FIGS. 3B-3E. Similar to the mechanically fluidized bed reactor depicted in FIG. 3A, the mechanically fluidized bed reactor 600 is apportioned by a divider plate 610 and a plurality of flexible members 42a-42n into an upper chamber 33 and a lower chamber 34. Each of the plurality of pans 12 is similar in design and function to the pan 12 described in detail with regard to FIG. 3A, and includes a major horizontal surface 302 having an upper surface 12a and a lower surface 12b and a perimeter wall 12c. Each of the pans 12 includes a respective flexible member 42a-42n that is physically coupled to a respective pan 12a-12n and to the divider plate 610. The flexible members 42 hermetically seal the upper chamber 33 from the lower chamber and expose the upper surface 12a of each of the pans 12 to the upper chamber 33 and the lower surface 12b of each of the pans 12 to the lower chamber 34.

Each of the pans 12 includes a respective cover 310a-310n. Each of the covers 310a-310n may be the same as or different from the other covers and may include any of the covers 310, 410, 430, and 450 described in detail with regard to FIGS. 3A, 4A, 4B, and 4C, respectively. Each of the plurality of pans 12a-12n includes a respective gas distribution system 350a-350n. The gas distribution system 350 in each pan may be the same (i.e., centrally located injectors 356 or peripherally located injectors 356) or different (i.e., a mixture of centrally located and peripherally located injectors 356). Although depicted as routed through the upper chamber 33, at times, some or all of the fluid conduits 84a-84n, flexible connections 330a-330n, and gas distribution systems 350a-350n may be routed from below the pans 12a-12n (i.e., through the lower chamber 34).

In some instances, each of the plurality of pans 12a-12n may be driven by a respective cam 602a-602n (collectively “cams 602”) and transmission member 604a-604n (collectively, “transmission members 604”). Each of the cams 602 may be driven by a separate driver or by one or more common drivers. At times, the control system 190 can oscillate or vibrate each of the plurality of pans 12a-12n in a first, synchronous, mode such that all of the plurality of pans 12 has a similar or identical displacement at any instant in time. At other times, the control system 190 can oscillate or vibrate each of the plurality of pans in a second, asynchronous, mode such that some or all of the plurality of pans 12 have different displacements. For example, the control system 190 may oscillate a first half of the plurality of pans such that the displacement of the first half of the pans is 0.1 inch vertical while the displacement of a second half of the pans 12 is at zero (“0”). Such an asynchronous operating mode advantageously minimizes the pressure fluctuation in the upper and lower chambers attributable to the oscillation or vibration of the plurality of the pans 12 (i.e., the volume of the upper chamber and the volume of the lower chamber 34 remain substantially constant throughout the oscillatory or vibratory cycling of the plurality of pans 12).

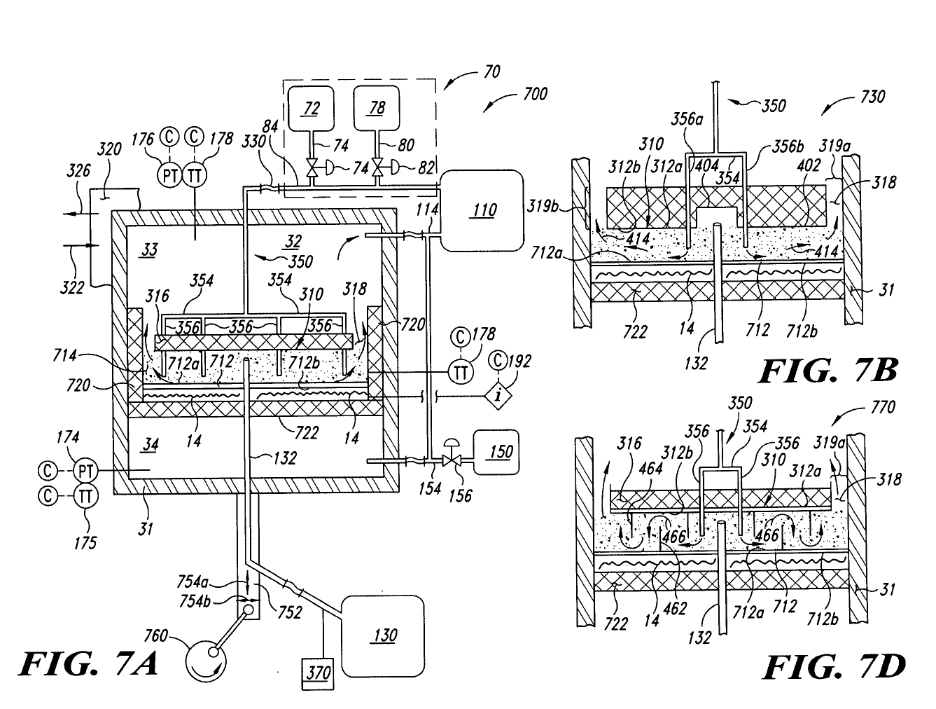

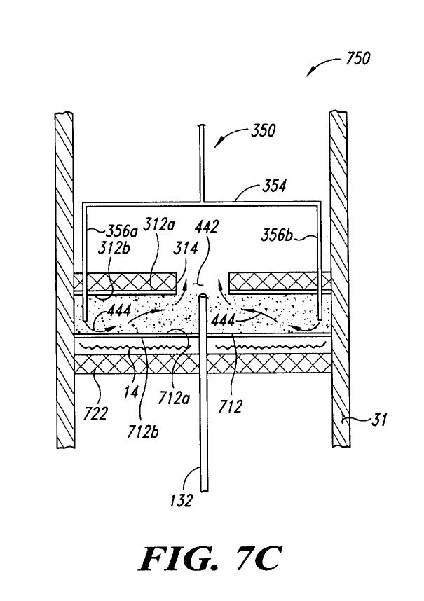

FIG. 7A shows an illustrative mechanically fluidized reactor system 700 in which a major horizontal surface 712 carrying the plurality of particulates extends completely across a cross section of the reactor vessel 31 and the entire vessel 31 is oscillated or, vibrated to provide the mechanically fluidized particulate bed 20, according to an embodiment. For clarity, the gas distribution system 350 is depicted without outer tube member 386, however it should be understood that the gas distribution system 350 depicted in FIG. 7A may include any of the insulation or cooling systems depicted in FIGS. 3B-3E. A major horizontal surface 712 extends across the cross section of the interior of the reactor vessel 31, forming the upper chamber 33 and the lower chamber 34. The major horizontal surface 712 includes an upper surface 712a and a lower surface 712b. A cover 310 is disposed a distance from the upper surface 712a of the major horizontal surface 712, forming a retention volume 714 therebetween. The retention volume 714 retains the mechanically fluidized particulate bed 20.

In some implementations, one or more insulative materials 720 may be disposed about the interior and/or exterior of the reactor vessel 31 in locations proximate those areas of the reactor maintained at elevated temperature. For example, one or more insulative materials 720 (e.g., cal-sil, fiberglass, mineral wool, or similar) may be disposed proximate an internal or external portion of the reactor wall 31 proximate the mechanically fluidized particulate bed 20 where a localized concentration of thermal energy can be expected. Where such insulative materials 720 are disposed proximate an internal surface of the reactor wall 31, all or a portion of the insulative materials 720 may be partially or completely covered and/or encapsulated in a non-permeable, non-thermally conductive, layer such as a blanket, rigid cover, semi-rigid cover, or flexible cover. In other implementations, one or more insulative materials 720 may be disposed internally within the reactor vessel 31 in locations proximate those areas of the reactor maintained at elevated temperature such as those proximate the mechanically fluidized particulate bed 20. One or more cooling features such as extended surface cooling fins, cooling coils, and/or a cooling jacket 320 through which a heat transfer fluid passes may be used to maintain the temperature in the upper chamber 33 below the thermal decomposition temperature of the first gaseous chemical species.

The portions of the major horizontal surface 712 contacting the mechanically fluidized particulate bed 20 are formed of an abrasion or erosion resistant material that is also resistant to chemical degradation by the first chemical species, the diluent(s), and the coated particles in the particulate bed 20 and that forms a barrier to the transmission of metal atoms in the pan assembly into the particulate bed. Use of a major horizontal surface 712 having appropriate physical and chemical resistance reduces the likelihood of contamination of the fluidized particulate bed 20 by contaminants released from the major horizontal surface 712. In some instances, the major horizontal surface 712 can comprise an alloy such as a graphite alloy, a nickel alloy, a stainless steel alloy, or combinations thereof. In some instances, the major horizontal surface 712 can comprise molybdenum or a molybdenum alloy, or a metal alloy of such materials that is coated with a barrier material such as graphite, silicon, quartz, silicon carbide, silicide, molybdenum disilicide, and silicon nitride.

At times, a layer or coating of resilient material that resists abrasion or erosion, reduces unwanted product buildup, or reduces the likelihood of contamination of the mechanically fluidized particulate bed 20 may be deposited on all or a portion of the major horizontal surface 712. In some instances, all or a portion of the major horizontal surface 712 may comprise silicon or high purity silicon (>99% Si, >99.9% Si, >99.9999% Si). It should be understood that the silicon comprising the major horizontal surface 712 is present prior to the first use of the major horizontal surface 712, in other words, the silicon comprising the major horizontal surface 712 is different from the non-volatile second chemical species created by the thermal decomposition of the first gaseous chemical species in the mechanically fluidized particulate bed 20.

In some instances, the layer or coating in all or a portion of the major horizontal surface 712 can include but is not limited to: a metal silicide layer, a graphite layer, a silicon layer, a quartz or fused quartz layer, a silicide layer, a silicon nitride layer, or a silicon carbide layer. In some instances, a metal silicide may be formed in situ by reaction of silane with iron, molybdenum, nickel, and other metals in the major horizontal surface 712. A silicon carbide layer, for example, is durable and reduces the tendency of metal ions such as nickel, chrome, and iron from the metal comprising the pan to migrate into, and potentially contaminate, the plurality of coated particles 22 in the major horizontal surface 712. In one example, the major horizontal surface 712 comprises a 316 stainless steel member with a silicon carbide layer deposited on at least a portion of the upper surface 712a in contact with the mechanically fluidized particulate bed 20. In another example, the major horizontal surface 712 comprises an Inconel member with a silicon layer deposited on at least a portion of the upper surface 712a in contact with the mechanically fluidized particulate bed 20. In yet another example, the major horizontal surface 712 comprises a molybdenum or molybdenum alloy member with a fused quartz layer deposited on at least a portion of the upper surface 712a in contact with the mechanically fluidized particulate bed 20.

At times, the liner or layer may be physically coupled to the major horizontal surface 712 using one or more mechanical fasteners, for example one or more threaded fasteners, bolts, nuts, or the like. At other times, the liner or layer may be physically coupled to the major horizontal surface 712 using one or more spring clips, clamps, or similar devices. At yet other times, the liner or layer may be physically coupled to the major horizontal surface 712 using one or more adhesives or similar bonding agents.

One or more thermal energy emitting devices 14 are disposed proximate the lower surface 712b of the major horizontal surface 712. An insulative layer 722 is disposed proximate the one or more thermal energy emitting devices 714 to reduce the heat radiated to the lower chamber 34. The insulative layer 714 may, for instance be a glass-ceramic material (e.g., Li₂O×Al₂O₃×nSiO₂-System or LAS System) similar that used in “glass top” stoves where the electrical heating elements are positioned beneath a glass-ceramic cooking surface. In some situations, the insulative layer 714 may include one or more rigid or semi-rigid refractory type materials such as calcium silicate. In some implementations, the insulative layer 714 may include one or more removable insulative blankets or similar devices.

In some instances, the cover 310 is smaller in diameter than the reactor vessel 31, thereby creating a peripheral gap 318 between an upturned peripheral edge 314 of the cover 310 and an interior wall surface of the reactor vessel 31. The peripheral gap 318 can have a height 319a and a width 319b that, along with the peripheral gap length, defines a peripheral volume about the cover 310. In at least some implementations, the peripheral volume about the cover 310 can be equal to or greater than the displacement volume of the mechanically fluidized particulate bed 20.

The first gaseous chemical species and any diluent(s) are introduced at any number of locations in the mechanically fluidized particulate bed 20 via the injectors 356. In operation, the first gaseous chemical species and the diluent(s) flow 714 through the mechanically fluidized particulate bed 20. The diluent(s), gaseous decomposition byproducts, and any undecomposed first gaseous chemical species exit the mechanically fluidized particulate bed 20 as an exhaust gas via the peripheral gap 318. The exhaust gas flows into the upper chamber 33.

The reactor vessel 31 is oscillated or vibrated using a mechanical, electrical, magnetic, or electromagnetic system capable of displacing the reactor vessel 31 at a desired oscillatory or vibratory frequency and oscillatory or vibratory displacement. In some implementations, a cam 760 causes a transmission member 752 to oscillate or vibrate the reactor vessel 31 along one or more axes of motion. For example, in some implementations, the transmission member 752 can oscillate the reactor vessel 31 along a single axis of motion 754a that is substantially perpendicular to the major horizontal surface 712. In another example, the transmission member 752 can oscillate or vibrate the reactor vessel 31 along an axis having components that lie along a first axis of motion that is substantially perpendicular to the major horizontal surface 712 and a second axis of motion 754b that is orthogonal to the first axis of motion 754a.

FIG. 7B shows an alternative cover 730 useful with the mechanically fluidized bed reactor 700 depicted in FIG. 7A, according to an embodiment. For clarity, the gas distribution system 350 is depicted without outer tube member 386, however it should be understood that the gas distribution system 350 depicted in FIG. 7B may include any of the insulation or cooling systems depicted in FIGS. 3B-3E. The cover 730 includes a first portion 402 in which the lower surface 312b is positioned a first distance above the upper surface 12a of the major horizontal surface 302. The cover 730 also includes a second “top hat” portion 404 in which the lower surface 312b is positioned a second distance that is greater than the first distance above the upper surface 12a of the major horizontal surface 302. The second portion 404 is disposed about and/or above the coated particle overflow conduit 132. The second portion 404 of the cover 310 permits the mechanically fluidized particulate bed 20 to contact (e.g., lightly, firmly) the lower surface 312b of the first portion 402 of the cover 310 while still permitting the overflow of coated particles 22 into the coated particle overflow conduit 132.

Although not shown in FIG. 7B, in some implementations, a purge gas supplied by the purge gas system 370 is passed through the coated particle overflow conduit 132. The countercurrent flow of purge gas through the coated particle overflow conduit 132 reduces the flow of the first gaseous chemical species through the coated particle overflow conduit 132, thereby improving the yield in the mechanically fluidized bed reactor 700.

The injectors 356a-356n discharge the first gaseous chemical species at one or more central locations in the mechanically fluidized particulate bed 20. The first gaseous chemical species and any diluent(s) follow a radially outward flow path 414 through the mechanically fluidized particulate bed 20. Exhaust gases, including any diluent(s) present in the gas feed, inert decomposition byproducts, and undecomposed first gaseous chemical species escape as an exhaust gas from the mechanically fluidized particulate bed 20 via the peripheral gap 318 between the cover 410 and the perimeter wall 12c. In at least some implementations, the velocity of the first gaseous chemical species and any diluent(s) through the mechanically fluidized particulate bed 20 establishes a substantially plug or transitional radially outward flow regime through the mechanically fluidized particulate bed 20.

FIG. 7C shows another alternative cover system 750 useful with the mechanically fluidized bed reactor 700 depicted in FIG. 7A, according to an embodiment. For clarity, the gas distribution system 350 is depicted without outer tube member 386, however it should be understood that the gas distribution system 350 depicted in FIG. 7C may include any of the insulation or cooling systems depicted in FIGS. 3B-3E. The cover 750 is disposed proximate the perimeter wall 12c of the reactor vessel 31 and the upturned peripheral edge 314 of the cover 310 forms an aperture 442 above a portion of the mechanically fluidized particulate bed 20. For example, an aperture 442 above the central portion of the mechanically fluidized particulate bed 20 about the coated particle overflow conduit 132. In operation, the mechanically fluidized particulate bed 20 contacts (e.g., lightly, firmly) the lower surface 312b of cover 750.

The injectors 356a-356n discharge the first gaseous chemical species at one or more peripheral locations in the mechanically fluidized particulate bed 20. The first gaseous chemical species and any diluent(s) follow radially inward flow path 444 through the mechanically fluidized particulate bed 20. Exhaust gases, including any diluent(s) present in the gas feed, inert decomposition byproducts, and undecomposed first gaseous chemical species escape from the mechanically fluidized particulate bed 20 as an exhaust gas via the aperture 442.

FIG. 7D shows another alternative cover system 770 useful with the mechanically fluidized bed reactor 700 depicted in FIG. 7A, according to an embodiment. For clarity, the gas distribution system 350 is depicted without outer tube member 386, however it should be understood that the gas distribution system 350 depicted in FIG. 7D may include any of the insulation or cooling systems depicted in FIGS. 3B-3E. The cover 770 includes a number of concentric baffles 462 physically coupled to the upper surface 12a of the pan 12 and a number of concentric baffles 464 physically coupled to the lower surface 312b of the cover 310. At times, the lower concentric baffles 462 and the upper concentric baffles 464 may be configured concentric with the coated particle overflow conduit 132. At times, at least some of the concentric baffles 462 and at least some of the concentric baffles 464 may be wholly or partially constructed of silicon or high-purity silicon (e.g., >99% Si, >99.9% Si, or >99.9999% Si). At times, at least some of the concentric baffles 462 and at least some of the concentric baffles 464 may comprise silicon having a uniform thickness or a uniform density. In at least some implementations, the concentric baffles 462 and concentric baffles 464 are arranged in an alternating pattern to define a serpentine flow path through the mechanically fluidized particulate bed 20.

The injectors 356a-356n discharge the first gaseous chemical species at one or more central locations in the mechanically fluidized particulate bed 20. The first gaseous chemical species and any diluent(s) follow a radially outward serpentine flow path 466 around the concentric baffles 462 and concentric baffles 464 and through the mechanically fluidized particulate bed 20. Exhaust gases, including diluent(s) present in the gas feed, inert decomposition byproducts, and undecomposed first gaseous chemical species escape from the mechanically fluidized particulate bed 20 as an exhaust gas via the peripheral gap 318 between the cover 450 and the perimeter wall 12c. In at least some implementations, the velocity of the first gaseous chemical species and any diluent(s) through the mechanically fluidized particulate bed 20 establish a substantially plug or transitional serpentine, radially outward, flow regime through the mechanically fluidized particulate bed 20.

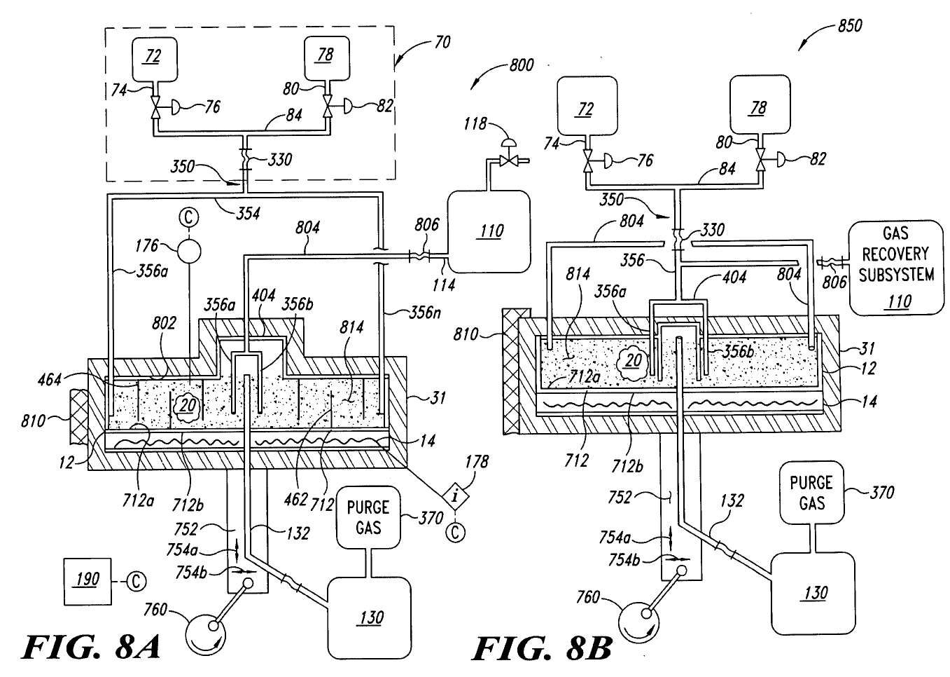

FIG. 8A shows yet another illustrative mechanically fluidized reactor system 800 having a serpentine flow pattern through the mechanically fluidized particulate bed 20 and in which a major horizontal surface 712 carrying the plurality of particulates extends across a cross section of the reactor vessel 31 and the entire vessel 31 is oscillated or vibrated to provide the mechanically fluidized particulate bed 20, according to an embodiment. For clarity, the gas distribution system 350 is depicted without outer tube member 386, however it should be understood that the gas distribution system 350 depicted in FIG. 8A may include any of the insulation or cooling systems depicted in FIGS. 3B-3E. In reactor system 800, a single chamber in the reactor vessel 30 holds the mechanically fluidized particulate bed 20 and no upper chamber or lower chamber exists. Advantageously, in the reactor system 800 many of the components such as the thermal energy emitting devices 14 are externally accessible, simplifying maintenance, repair, and replacement activities.

A major horizontal surface 712 extends across the cross section of the interior of the reactor vessel 30. The one or more thermal energy emitting devices 14 are positioned proximate the lower surface 712b of the major horizontal surface 712, between the major horizontal surface 712 and the reactor wall 31. The major horizontal surface 712 includes an upper surface 712a and a lower surface 712b. The interior of the reactor walls 31 and the major horizontal surface 712 form an enclosed retention volume 814. The retention volume 814 retains the mechanically fluidized particulate bed 20.

The injectors 356 introduce the first gaseous chemical species and any optional diluent(s) to the mechanically fluidized particulate bed 20 at any number of locations about the periphery of the mechanically fluidized particulate bed 20. In operation, the first gaseous chemical species and any diluent(s) flow through the mechanically fluidized particulate bed 20 into the raised second portion 404. Exhaust gas trapped in the second portion 404 flows via one or more fluid conduits 804 to the gas recovery system 110. In some instances, at least a portion of the one or more components (e.g., the first gaseous chemical species) can be separated from the exhaust gas and recycled to the reactor vessel 30. One or more expansion joints or isolators 806a-806b isolate the gas recovery system 110 from the oscillating reactor vessel 30. In some implementations, a purge gas supplied by the purge gas system 370 flow through the coated particle overflow conduit 132 and into the second portion 404.

The reactor vessel 30 is oscillated or vibrated using a mechanical, electrical, magnetic, or electromagnetic system capable of displacing the reactor vessel 30 at a desired oscillatory or vibratory frequency and displacement. In some implementations, a cam 760 causes a transmission member 752 to oscillate or vibrate the reactor vessel 30 along one or more axes of motion. For example, in some implementations, the transmission member 752 can oscillate the reactor vessel 30 along a single axis of motion 754a that is substantially perpendicular to the major horizontal surface 712. In another example, the transmission member 752 can oscillate or vibrate the reactor vessel 30 along an axis having components that lie along a first axis of motion that is substantially perpendicular to the major horizontal surface 712 and a second axis of motion 754b that is orthogonal to the first axis of motion 754a.

In some instances, insulative material 810 may be disposed about the exterior of the reactor vessel 30 in locations proximate those areas of the reactor maintained at elevated temperature, such as the external surfaces of the reactor vessel 30 proximate the mechanically fluidized particulate bed 20 or thermal energy emitting device 14. In other instances, insulative material may be disposed about the interior of the reactor vessel 30 in locations proximate those areas of the reactor maintained at elevated temperature, such as the external surfaces of the reactor vessel 30 proximate the mechanically fluidized particulate bed 20 or thermal energy emitting device 14.

FIG. 8B shows yet another illustrative mechanically fluidized reactor system 850 in which a major horizontal surface 712 carrying the plurality of particulates extends across a cross section of the reactor vessel 30 and the entire vessel 30 is oscillated or vibrated to provide the mechanically fluidized particulate bed 20, according to an embodiment. For clarity, the gas distribution system 350 is depicted without outer tube member 386, however it should be understood that the gas distribution system 350 depicted in FIG. 8B may include any of the insulation or cooling systems depicted in FIGS. 3B-3E. In reactor system 850, a single chamber in the reactor vessel 30 holds the mechanically fluidized particulate bed 20 and no upper chamber or lower chamber exists. Advantageously, in a reactor system 850 many of the components such as the thermal energy emitting devices 14 are externally accessible, simplifying maintenance activities.

A major horizontal surface 712 extends across the cross section of the interior of the reactor vessel 30. The one or more thermal energy emitting devices 14 are positioned proximate the lower surface 712b of the major horizontal surface 712, between the major horizontal surface 712 and the reactor wall 31. The major horizontal surface 712 includes an upper surface 712a and a lower surface 712b. The interior of the reactor walls 31 and the major horizontal surface 712 form an enclosed retention volume 814. The retention volume 814 retains the mechanically fluidized particulate bed 20.

The injectors 356 introduce the first gaseous chemical species and any diluent(s) to the mechanically fluidized particulate bed 20 at one or more central locations, for example in the second section 404. A cover 852 is disposed a distance from the coated particle overflow conduit 132 to prevent the direct flow of the first gaseous chemical species and any diluent(s) from the injectors 356 to the coated particle overflow conduit 132. Cover 852 also helps improve the utility and efficiency of the upwardly flowing countercurrent purge gas through the coated particle overflow conduit 132. In some instances, the injectors 356 extend into the mechanically fluidized particulate bed 20, below the open end of the coated particle overflow conduit 132. In some instances, the injectors 356 extend below the elevation of the downturned “sides” of the cover 852.

In some implementations the purge gas system 370 supplies an inert purge gas to the particle removal conduit 132. The purge gas flows countercurrent to the coated particles 22 and enters the mechanically fluidized particulate bed 20 via the particle removal conduit 132. Such countercurrent purge gas flow assists in reducing the entry of the first gaseous chemical species into the coated particle overflow conduit 132.

Such countercurrent purge gas also can be used to selectively separate coated particles 22 having one or more desirable properties (e.g., coated particle diameter) from the mechanically fluidized particulate bed 20. For example, increasing the flow of purge gas tends to increase countercurrent gas velocity within the coated particle overflow tube 132 which tends to return smaller diameter coated particles back to the mechanically fluidized particulate bed 20. Conversely, decreasing the flow of purge gas tends to decrease countercurrent gas velocity within the coated particle overflow tube 132 which tends to separate smaller diameter coated particles from the mechanically fluidized particulate bed 20.

In operation, the first gaseous chemical species and any diluent(s) flow through the mechanically fluidized particulate bed 20 to the one or more peripheral fluid conduits 804 that convey gases from the mechanically fluidized particulate bed 20 to the gas recovery system 110. One or more expansion joints or isolators 806a-806b isolate the gas recovery system 110 from the oscillating reactor vessel 30.

The reactor vessel 30 is oscillated or vibrated using a mechanical, electrical, magnetic, or electromagnetic system capable of displacing the reactor vessel 30 at a desired oscillatory or vibratory frequency and displacement. In some implementations, a cam 760 causes a transmission member 752 to oscillate or vibrate the reactor vessel 30 along one or more axes of motion. For example, in some implementations, the transmission member 752 can oscillate the reactor vessel 30 along a single axis of motion 754a that is substantially perpendicular to the major horizontal surface 712. In another example, the transmission member 752 can oscillate or vibrate the reactor vessel 30 along an axis having components that lie along a first axis of motion that is substantially perpendicular to the major horizontal surface 712 and a second axis of motion 754b that is orthogonal to the first axis of motion 754a.

In some instances, insulative material 810 may be disposed about the exterior of the reactor vessel 30 in locations proximate those areas of the reactor maintained at elevated temperature, such as the external surfaces of the reactor vessel 30 proximate the mechanically fluidized particulate bed 20 or thermal energy emitting device 14. In other instances, insulative material may be disposed about the interior of the reactor vessel 30 in locations proximate those areas of the reactor maintained at elevated temperature, such as the external surfaces of the reactor vessel 30 proximate the mechanically fluidized particulate bed 20 or thermal energy emitting device 14.

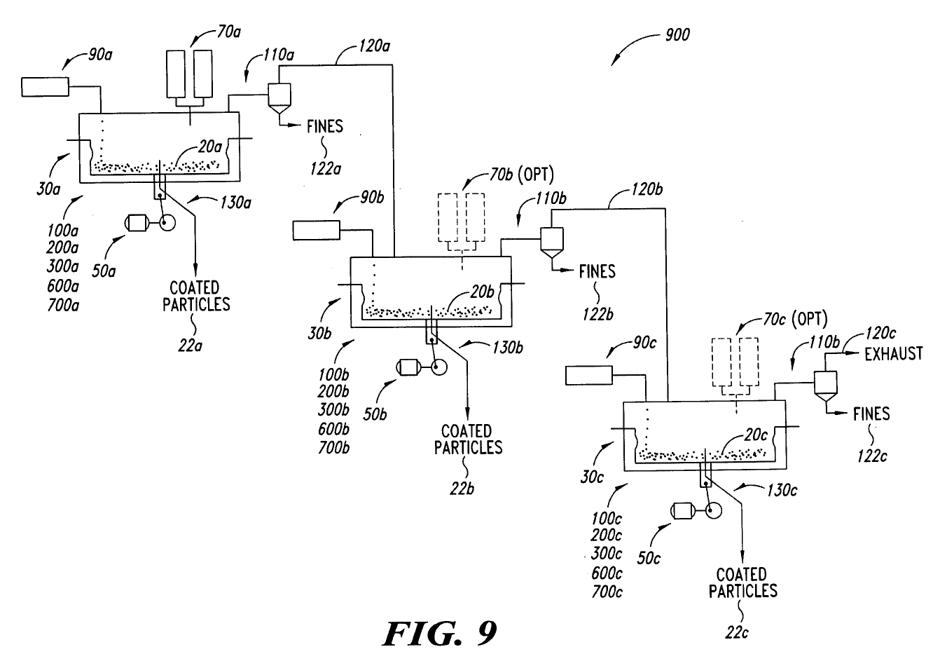

FIG. 9 shows a process 900 useful for the production of second chemical species coated particles, for example polysilicon coated particles, reaction vessels such as the illustrative mechanically fluidized bed reaction systems discussed in detail with regard to FIGS. 1, 2, 3A-3E, 4A-4C, 5A-5D, 6, 7A-7D and 8A-8B. In such an arrangement an exhaust 120a from the first mechanically fluidized bed reaction vessel may contain residual undecomposed first gaseous chemical species, one or more third gaseous chemical species byproducts, and one or more diluent(s). The exhaust 120a is introduced to the second mechanically fluidized bed reaction vessel where an additional portion of the residual first chemical species present in the exhaust 120a thermally decomposes. The exhaust 120b from the second reaction vessel includes residual undecomposed first gaseous chemical species, one or more third gaseous chemical species byproducts, and one or more diluent(s). The exhaust 120b is introduced to a third reaction vessel where an additional portion of the residual first chemical species present in the exhaust 120b further thermally decomposes. Advantageously, the use of such a serial process can provide an overall conversion of the first gaseous chemical species to the second chemical species in excess of 99%.

The first gaseous chemical species and any diluent(s) are added via the gas supply system 70a to the first reaction vessel. A portion of the first gaseous chemical species thermally decomposes within the mechanically fluidized particulate bed 20a in the first reaction vessel. Gas recovery system 110a collects exhaust gas containing undecomposed first gaseous chemical species, one or more third gaseous chemical species byproducts, and any diluent(s) from the first reaction vessel.

Coated particle collection system 130a removes at least a portion of the plurality of coated particles 22a present in the particulate bed 20a that meet one or more defined physical criteria (e.g., particle diameter, density). Product coated particles 22a are removed from the coated particle collection system 130a. In some implementations, coated particles 22a are continuously removed from the particulate bed 20a. If needed, fresh particles 92a may be added to the particulate bed 20a by the particulate supply system 90a.

In the first reaction vessel, the conversion of the first gaseous chemical species to the second chemical species can be greater than about 70%; greater than about 75%; greater than about 80%; greater than about 85%; or greater than about 90%. A portion of the undecomposed first gaseous chemical species, one or more third gaseous chemical species byproducts, and one or more diluent(s) removed from the first reaction vessel via the gas collection system 110a and directed to the second reaction vessel.

In the second reaction vessel, an optional second gas supply system 70b (shown dashed in FIG. 9) may be used to provide additional first gaseous chemical species and/or diluent(s) or a mixture of both the first gaseous chemical species and diluent(s). A portion of the residual first gaseous chemical species present in the exhaust 120a from the first reaction vessel is thermally decomposed within the mechanically fluidized particulate bed 20b. Gas recovery system 110b collects exhaust gas containing undecomposed first gaseous chemical species, one or more third gaseous chemical species byproducts, and any diluent(s) from the second reaction vessel.

Coated particle collection system 130b removes at least a portion of the plurality of coated particles 22b present in the particulate bed 20b that meet one or more defined physical criteria (e.g., particle diameter, density). Product coated particles 22b are removed from the coated particle collection system 130b. In some implementations, coated particles 22b are continuously removed from the particulate bed 20b. If needed, fresh particles 92b may be added to the particulate bed 20b by the particulate supply system 90b.

In the second reaction vessel, the conversion of the first gaseous chemical species to the second chemical species can be greater than about 70%; greater than about 75%; greater than about 80%; greater than about 85%; or greater than about 90%. The overall conversion through the first and second reaction vessels can be greater than about 90%; greater than about 92%; greater than about 94%; greater than about 96%; greater than about 98%; greater than about 99%. A portion of the undecomposed first gaseous chemical species, one or more third gaseous chemical species byproducts, and one or more diluent(s) removed from the second reaction vessel via the gas collection system 110b and directed to the third reaction vessel.

In the third reaction vessel, an optional second gas supply system 70c (shown dashed in FIG. 9) may be used to provide additional first gaseous chemical species and/or diluent(s) or a mixture of both the first gaseous chemical species and diluent(s). A portion of the residual first gaseous chemical species present in the exhaust 120b from the second reaction vessel is thermally decomposed within the mechanically fluidized particulate bed 20c. Gas recovery system 110c collects exhaust gas containing undecomposed first gaseous chemical species, one or more third gaseous chemical species byproducts, and any diluent(s) from the third reaction vessel.

Coated particle collection system 130c removes at least a portion of the plurality of coated particles 22c present in the particulate bed 20c that meet one or more defined physical criteria (e.g., particle diameter, density). Product coated particles 22c are removed from the coated particle collection system 130c. In some implementations, coated particles 22c are continuously removed from the particulate bed 20c. If needed, fresh particles 92c may be added to the particulate bed 20c by the particulate supply system 90c.

In the third reaction vessel, conversion of the first chemical species to the second chemical species can be greater than about 70%; greater than about 75%; greater than about 80%; greater than about 85%; or greater than about 90%. The overall conversion through the first, second, and third reaction vessels can be greater than about 94%; greater than about 96%; greater than about 98%; greater than about 99%; greater than about 99.5%; or greater than about 99.9%. Gas recovery system 110c collects exhaust gas containing undecomposed first gaseous chemical species, one or more third gaseous chemical species byproducts, and any diluent(s) from the third reaction vessel and treated, recycled, or discharged.

The systems and processes disclosed and discussed herein for the production of silicon have marked advantages over systems and processes currently employed. The systems and processes are suitable for the production of either semiconductor grade or solar grade silicon. The use of high purity silane as the first chemical species in the production process allows a high purity silicon to be produced more readily. The system advantageously maintains the silane at a temperature below the thermal decomposition temperature; for example below 400° C., until the silane enters the mechanically fluidized particulate bed. By maintaining temperatures outside of the mechanically fluidized particulate bed below the thermal decomposition temperature of silane, the overall conversion of silane to usable polysilicon deposited on the particles within the mechanically fluidized particulate bed is increased and parasitic conversion losses attributable to decomposition of silane and deposition of polysilicon on other surfaces within the reactor are minimized.

The mechanically fluidized bed systems and methods described herein greatly reduce or eliminate the formation of ultra-fine poly-powder (e.g., 0.1 to several microns in size) external to the mechanically fluidized particulate bed 20 since the temperature of the gas containing the first chemical species is maintained below the auto-decomposition temperature of the first chemical species. Additionally, the temperature within the chamber 32 is also maintained below the thermal decomposition temperature of the first chemical species further reducing the likelihood of auto-decomposition. Further, any small particles formed in the mechanically fluidized bed, by abrasion, physical damage or attrition for example, generally having a diameter significantly greater than 0.1 micron, but less than 250 microns are carried out of the chamber 32 with the exhaust gas. The diameter of the small particles so removed via the exhaust gas may be controlled by varying the width 319b of the opening 318 fluidly coupling the mechanically fluidized bed 20 with the upper chamber 33 as described herein. As a result, the formation of product particles having a desirable size distribution is more readily achieved

Silane also provides advantages over dichlorosilane, trichlorosilane, and tetrachlorosilane for use in making high purity polysilicon. Silane is much easier to purify and has fewer contaminants than dichlorosilane, trichlorosilane, or tetrachlorosilane. Because of the relatively low boiling point of silane, it can be readily purified which reduces the tendency to entrain contaminants during the purification process as occurs in the preparation and purification of dichlorosilane, trichlorosilane, or tetrachlorosilane. Further, certain processes for the production of trichlorosilane utilize carbon or graphite, which may carry along into the product or react with chlorosilanes to form carbon-containing compounds. Further, the silane-based decomposition process such as that described herein produces only a hydrogen by-product. The hydrogen byproduct may be directly recycled to the silane production process, reducing or eliminating the need for an off-gas treatment system. The elimination of off-gas treatment and the efficiencies of the mechanically fluidized bed process greatly reduce capital and operating cost to produce polysilicon. Capital and operating cost savings of 40% each are possible.

The above description of illustrated embodiments, including what is described in the Abstract, is not intended to be exhaustive or to limit the embodiments to the precise forms disclosed. Although specific embodiments and examples are described above for illustrative purposes, various equivalent modifications can be made without departing from the spirit and scope of the disclosure, as will be recognized by those skilled in the relevant art. The teachings provided above of the various embodiments can be applied to other systems, methods and/or processes for producing silicon, not only the exemplary systems, methods and devices generally described above.

For instance, the detailed description above has set forth various embodiments of the systems, processes, methods and/or devices via the use of block diagrams, schematics, flow charts and examples. Insofar as such block diagrams, schematics, flow charts and examples contain one or more functions and/or operations, it will be understood by those skilled in the art that each function and/or operation within such block diagrams, schematics, flowcharts or examples can be implemented, individually and/or collectively, by a wide range of system components, hardware, software, firmware, or virtually any combination thereof.

In certain embodiments, the systems used or devices produced may include fewer structures or components than in the particular embodiments described above. In other embodiments, the systems used or devices produced may include structures or components in addition to those described herein. In further embodiments, the systems used or devices produced may include structures or components that are arranged differently from those described herein. For example, in some embodiments, there may be additional heaters and/or mixers and/or separators in the system to provide effective control of temperature, pressure, or flow rate. Further, in implementation of procedures or methods described herein, there may be fewer operations, additional operations, or the operations may be performed in different order from those described herein. Removing, adding, or rearranging system or device components, or operational aspects of the processes or methods, would be well within the skill of one of ordinary skill in the relevant art in light of this disclosure.

The operation of methods and systems for making polysilicon described herein may be under the control of automated control subsystems. Such automated control subsystems may include one or more of appropriate sensors (e.g., flow sensors, pressure sensors, temperature sensors), actuators (e.g., motors, valves, solenoids, dampers), chemical analyzers and processor-based systems which execute instructions stored in processor-readable storage media to automatically control the various components and/or flow, pressure and/or temperature of materials based at least in part on data or information from the sensors, analyzers and/or user input.

Regarding control and operation of the systems and processes, or design of the systems and devices for making polysilicon, in certain embodiments the present subject matter may be implemented via Application Specific Integrated Circuits (ASICs). However, those skilled in the art will recognize that the embodiments disclosed herein, in whole or in part, can be equivalently implemented in standard integrated circuits, as one or more computer programs running on one or more computers (e.g., as one or more programs running on one or more computer systems), as one or more programs running on one or more controllers (e.g., microcontrollers) as one or more programs running on one or more processors (e.g., microprocessors), as firmware, or as virtually any combination thereof. Accordingly, designing the circuitry and/or writing the code for the software and or firmware would be well within the skill of one of ordinary skill in the art in light of this disclosure.

U.S. Provisional Patent Application No. 62/096,387, filed Dec. 23, 2014 is incorporated herein by reference in its entirety. The various embodiments described above can be combined to provide further embodiments. Aspects of the embodiments can be modified, if necessary to employ concepts of various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1.-9. (canceled)

10. A reactor system, comprising:
a housing having a chamber therein;
a pan received in the chamber of the housing, the pan having a major horizontal surface with a periphery and an upward extending peripheral wall that surrounds the periphery of the major horizontal surface that at least partially defines a retainment volume that at least partially temporarily retains a plurality of particulates, the peripheral which terminates in a peripheral edge;
a cover having an upper surface, a lower surface, and a peripheral edge, the cover disposed above the major horizontal surface of the pan, with the peripheral edge of the cover spaced inwardly of the peripheral wall of the pan with a peripheral gap between the peripheral edge of the cover and the peripheral wall of the pan that provides a fluidly communicative passage between the retainment volume of the pan and the chamber of the housing;
a transmission that, in operation, oscillates the pan to mechanically vibrate the plurality of particulates in the retainment volume to produce a mechanically vibrated particulate bed in the retainment volume;
a gas distribution header including at least one conduit having a fluid passage that extends therethrough, the fluid passage fluidly coupled to a proximal end of at least one injector having at least one outlet disposed at a distal end thereof, the passage which fluidly communicatively couples an external source of a first gaseous chemical species to the at least one outlet, the at least one outlet disposed in the retainment volume of the pan, the at least one injector penetrates and is sealingly coupled to the cover to provide a gas-tight seal therebetween, the at least one outlet, in operation, discharges the first gaseous chemical species at one or more locations in the mechanically vibrated particulate bed; and
a heater thermally coupled to the pan that, in operation, raises a temperature of the mechanically vibrated particulate bed above a thermal decomposition temperature of the first gaseous chemical species to thermally decompose at least a portion of the first gaseous chemical species present in the mechanically vibrated particulate bed to at least a non-volatile second chemical species that deposits on at least a portion of the particulates in the mechanically vibrated particulate bed to provide a plurality of coated particles, and a third gaseous chemical species, the peripheral gap which provides an exit for the third gaseous chemical species into the chamber of the housing from the mechanically vibrated particulate bed.

11. The reactor system of claim 10 wherein the cover is disposed parallel to the major horizontal surface of the pan.

12. The reactor system of claim 10 wherein the peripheral edge of the cover is upturned and extends a distance of about 0.1 inches to about 10 inches above the upper surface of the cover.

13. The reactor system of claim 10, further comprising:
a flexible member that separates the chamber in the housing into an upper chamber and a lower chamber, the flexible member having a first continuous edge and a second continuous edge disposed laterally across the flexible member from the first continuous edge, the first continuous edge of the flexible member physically couples to the housing, to form a gas-tight seal therebetween, and the second continuous edge of the flexible member physically couples to the pan to form a gas-tight seal therebetween such that, in operation:
the upper chamber includes at least a portion of the chamber inclusive of the retainment volume;
the lower chamber includes at least a portion of the chamber exclusive of the retainment volume; and
the flexible member forms a hermetic seal between the upper chamber and the lower chamber.

14. The reactor system of claim 13 wherein the at least one outlet of the at least one injector is positioned to discharge the first gaseous chemical species to at least one central location within the mechanically fluidized particulate bed.

15. The reactor system of claim 13 wherein the at least one outlet of the at least one injector comprises a plurality of outlets positioned to discharge the first gaseous chemical species in each of a plurality of locations within the mechanically fluidized particulate bed, and the gas distribution header comprises a thermally insulated feed tube that includes a thermally insulated fluid passage, the fluid passage coupled to the at least one injector, and the at least one injector is at least partially thermally insulated.

16. The reactor system of claim 13 wherein the peripheral gap has a width that, in operation, maintains a gas flow from the retainment volume through the peripheral gap to the upper chamber below a defined gas velocity, at or below which a preponderance of seed particles formed in-situ in the mechanically fluidized particulate bed are retained in the mechanically fluidized particulate bed.

17. The reactor system of claim 13 wherein the peripheral gap has a width that, in operation, maintains a gas flow through the peripheral gap below a defined gas velocity at which a preponderance of particles larger than 80 microns are retained in the mechanically fluidized particulate bed.

18. The reactor system of claim 13 wherein the peripheral gap has a width that, in operation, maintains a gas flow through the peripheral gap below a defined gas velocity at which a preponderance of particles larger than 10 microns are retained in the mechanically fluidized particulate bed.

19. The reactor system of claim 13 wherein the peripheral gap has a width of at least 0.0625 inches.

20.-23. (canceled)

24. The reactor system of claim 13 wherein the major horizontal surface of the pan is an integral, unitary, single piece silicon portion of a bottom of the pan, and not selectively removable therefrom or the major horizontal surface of the pan is a silicon insert selectively insertable into the bottom of the pan.

25.-29. (canceled)

30. The reactor system of claim 13, further comprising an insulative layer disposed in contact with at least a portion of at least one of: the peripheral wall of the pan or the flexible member, so that the at least one of the peripheral wall of thermal member is thermally isolated from the lower chamber, and wherein the insulative layer further comprises a gas impermeable layer physically isolating at least a portion of the insulative layer from at least one of: the upper chamber or the lower chamber.

31. (canceled)

32. The reactor system of claim 13, further comprising an insulative layer disposed about the heater such that the heater is thermally isolated from the lower chamber, and wherein the insulative layer further comprises a gas impermeable layer physically isolating at least a portion of the insulative layer disposed about the heater from at least one of the upper chamber or the lower chamber.

33. The reactor system of claim 13 wherein the upper chamber defines a first volume;
wherein a volumetric displacement caused by the oscillation of the pan defines a second volume; and
wherein a ratio of the defined first volume to the defined second volume is greater than about 5:1.

34. The reactor system of claim 33 wherein the ratio of the defined first volume to the defined second volume is greater than about 100:1.

35.-36. (canceled)

37. The reactor system of claim 13 wherein the controller, in operation, executes a machine-executable instruction set that further causes the controller to:
adjust at least one process condition to provide the plurality of coated particles meeting at least one defined criterion including at least one of: at least one chemical composition criterion or at least one physical property criterion, the at least one process condition including at least one of: an oscillatory frequency of the pan, an oscillatory displacement of the pan, a temperature of the mechanically fluidized particulate bed, a gas pressure in the upper chamber, a feed rate of the first gaseous chemical species to the mechanically fluidized particulate bed, a mole fraction of the first gaseous chemical species in the upper chamber, a removal rate of the third gaseous chemical species from the upper chamber, a volume of the mechanically fluidized particulate bed, or a depth of the mechanically fluidized particulate bed.

38.-42. (canceled)

43. The reactor system of claim 37 wherein the machine-executable instruction set that causes the controller to adjust at least one process condition to provide the plurality of coated particles having a minimum first dimension, further causes the controller to:
adjust the at least one process condition to provide the plurality of coated particles in which the particulate diameters form a Gaussian distribution.

44. (canceled)

45. The reactor system of claim 13 wherein the upper chamber of the housing defines a first volume, the mechanically fluidized particulate bed defines a third volume, and a ratio of the first volume to the third volume is greater than about 0.5:1.

46. The reactor system of claim 13 wherein the cover is physically affixed to the housing such that, in operation, the cover does not oscillate with the pan.

47. The reactor system of claim 46 wherein a volumetric displacement of the fluidized bed is caused by the oscillation of the pan and wherein a peripheral gap volume is greater than the volumetric displacement of the fluidized bed.

48. The reactor system of claim 13 wherein the cover is physically affixed to the pan such that, in operation, the cover oscillates with the pan.

49.-50. (canceled)

51. The reactor system of claim 13, further comprising:
a product removal tube penetrating and sealingly coupled to the major horizontal surface; and a number of injectors fluidly coupled to the gas distribution header, the injectors which each penetrates the cover in a respective location disposed radially about the product removal tube.

52. The reactor system of claim 51 wherein the cover is apportioned into a raised portion and a non-raised portion, the raised portion comprises a portion of the cover directly above and extending radially outward from the product removal tube a fixed radius such that the distance between a lower surface of the raised portion of the cover and the major horizontal surface is greater than the distance between the lower surface of the non-raised portion of the cover and the major horizontal surface.

53.-159. (canceled)
